(19) United States
(12) Patent Application Publication
(10) Pub. No.: US 2025/0192103 A1
(43) Pub. Date: Jun. 12, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Sam Vaziri, San Jose, CA (US); Isha Datye, Hsinchu (TW); Xinyu BAO, Fremont, CA (US)

(73) Assignee: Taiwan Semiconductor Manufacturing Company, Ltd., Hsinchu (TW)

(21) Appl. No.: 18/403,643

(22) Filed: Jan. 3, 2024

Related U.S. Application Data
(60) Provisional application No. 63/609,305, filed on Dec. 12, 2023.

(51) Int. Cl. H01L 25/065; H01L 23/00; H01L 25/00

(52) U.S. Cl. CPC H01L 25/0657; H01L 24/08; H01L 24/80; H01L 25/50; H01L 2224/08145; H01L 2224/80006; H01L 2224/80896; H01L 2225/06541; H01L 2225/06589

(57) ABSTRACT

A semiconductor device includes a semiconductor die. The semiconductor die includes a substrate including at least one active component, an interconnect disposed over and electrically coupled to the at least one active component, and at least one first thermal control element disposed inside the interconnect and thermally coupled to the at least one active component. The at least one active component is surrounded by the at least one first thermal control element in a vertical projection along a stacking direction of the substrate and the interconnect.

### CROSS-REFERENCE TO RELATED APPLICATION

This application claims the priority benefit of U.S. provisional application Ser. No. 63/609,305, filed on Dec. 12, 2023. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 17 are schematic cross-sectional views of various stages in a manufacturing method of a semiconductor device in accordance with some embodiments of the disclosure.

FIG. 18 through FIG. 36 are schematic cross-sectional views respectively showing a semiconductor device in accordance with alternative embodiments of the disclosure.

FIG. 37 and FIG. 38 are schematic plane views showing a positioning configuration of a hotspot and a thermal control element included in a semiconductor device in accordance with various embodiments of the disclosure.

FIG. 39 to FIG. 42 are schematic cross-sectional views of various stages in a manufacturing method of a semiconductor device in accordance with some embodiments of the disclosure.

FIG. 43 through FIG. 46 are schematic cross-sectional views respectively showing a semiconductor device in accordance with alternative embodiments of the disclosure.

FIG. 47 is a schematic cross-sectional view showing an application of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The specific embodiment(s) described herein is related to a semiconductor device (or a semiconductor package or structure) having a stacking structure of multi-tiers each including at least one semiconductor die or chip, and is not intended to limit the scope of the disclosure. Due to a thermal control element of thermal energy storage material being adopted in an interconnect of one or more tiers of the stacking structure, the thermal management of the semiconductor device is well-controlled. That is, a heat dissipation of a hotspot of the semiconductor device is greatly improved, thereby obtaining a better reliability of the semiconductor device. In embodiments of the disclosure, the thermal control element of thermal energy storage material may be disposed in the interconnect of one or more tiers of the stacking structure, where the thermal control element of thermal energy storage material may be in form of an array (with multiple pillars or columns) surrounding the hotspot, in form of a bulk or plate having an opening enclosing the hotspot, or in form of a continuous plate overlapping the hotspot. In embodiments of the disclosure, the thermal control element of thermal energy storage material may be formed to penetrate through one or more dielectric layers of the interconnect(s) of one or more tiers of the stacking structure.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

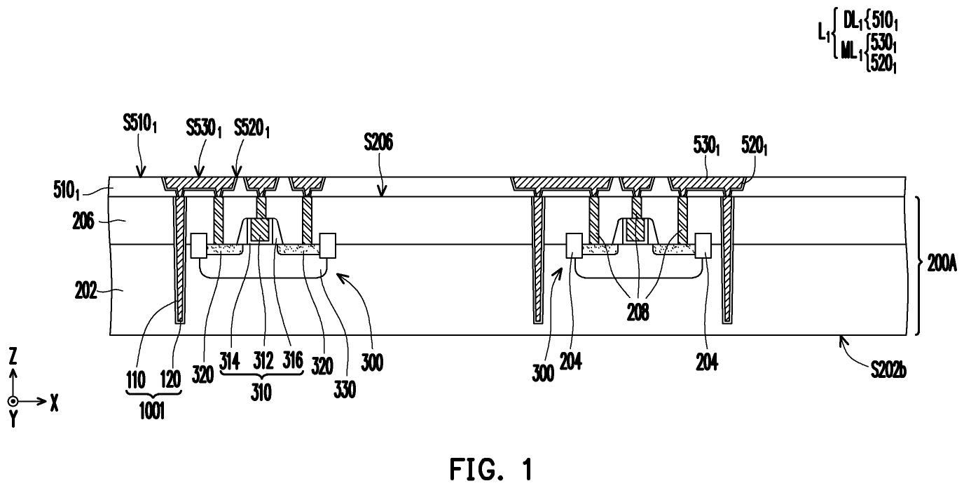

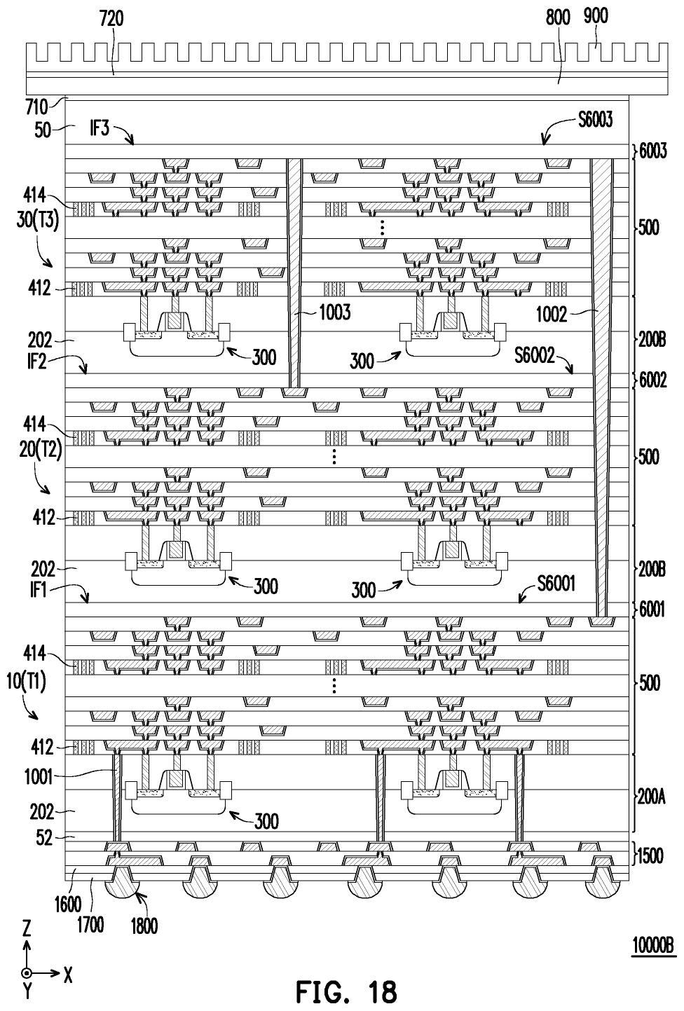

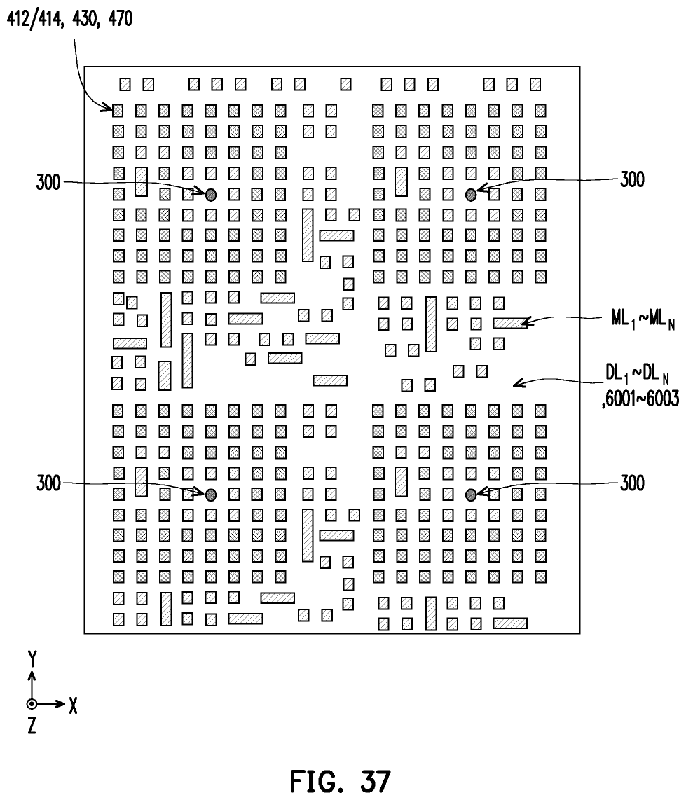

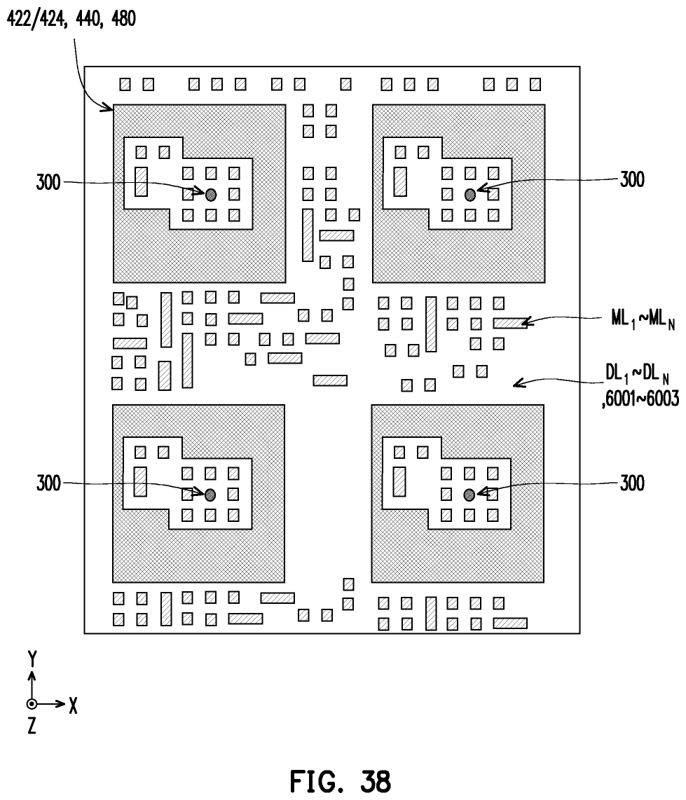

FIG. 1 to FIG. 17 are schematic cross-sectional views of various stages in a manufacturing method of a semiconductor device (e.g., 10000A) in accordance with some embodiments of the disclosure. FIG. 18 through FIG. 36 are schematic cross-sectional views respectively showing a semiconductor device (e.g., 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, or 10000T) in accordance with alternative embodiments of the disclosure. FIG. 37 and FIG. 38 are schematic plane views showing a positioning configuration of a hotspot (e.g., 300 or the like) and a thermal control element (e.g., 412, 414, 422, 424, 430, 440, 470, or 480) of thermal energy storage material included in a semiconductor device in accordance with various embodiments of the disclosure. The embodiments are intended to provide further explanations but are not used to limit the scope of the disclosure.

Referring to FIG. 1, in some embodiments, an initial structure is provided. For example, the initial structure includes a substrate 200A including a wide variety of components (also referred to as semiconductor components) formed in a semiconductor substrate 202 and a stacked structure disposed on the semiconductor substrate 202, as shown in FIG. 1. The components may include active components, passive components, or a combination thereof. The components may include integrated circuit (IC) devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure.

In some embodiments, the semiconductor substrate 202 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the semiconductor substrate 202 includes one or more doped regions or various types of doped regions, depending on the demand and/or product design requirements/layout. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The semiconductor substrate 202 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or gradient substrate may also be used. In some alternative embodiments, the semiconductor substrate 202 includes a semiconductor substrate made of other suitable elemental semiconductor, such as diamond or germanium; a suitable compound semiconductor, such as gallium arsenide, silicon carbide, gallium phosphide, indium phosphide, indium arsenide and indium antimonide, an alloy semiconductor such as SiGe, GaAsP, AlInAs, AlGaAs, GaInAs, GaInP and GaInAsP or combinations thereof. For example, the semiconductor substrate 202 is a silicon bulk substrate.

As shown in FIG. 1, the components (such as one or more transistors 300) may be formed in the semiconductor substrate 202. In some embodiments, a plurality of isolation structures 204 are formed in the semiconductor substrate 202 for separating the transistors 300. In certain embodiments, the isolation structures 204 are trench isolation structures. In other embodiments, the isolation structures 204 includes local oxidation of silicon (LOCOS) structures. In some embodiments, the insulator material of the isolation structures 204 includes silicon oxide, silicon nitride, silicon oxynitride, a spin-on dielectric material, or a low-k dielectric material. For example, the low-k dielectric material generally has a dielectric constant lower than 3.9. In one embodiment, the insulator material may be formed by chemical vapor deposition (CVD) such as high-density plasma CVD (HDP-CVD) and sub-atmospheric CVD (SACVD) or formed by spin-on. In certain embodiments, the components (such as the transistors 300) and the isolation structures 204 are formed in the substrate 200A during the front-end-of-line (FEOL) processes. In one embodiment, the transistors 300 are formed following the complementary MOS (CMOS) processes. The number and configurations of the components formed in the semiconductor substrate 202 should not be limited by the embodiments or drawings of this disclosure. That is, the number of the components may be more than two. It is understood that the number and configurations of the components may have different material or configurations depending on the demand and/or product design requirements/layout.

The transistors 300 independently may be a PMOS transistor. For example, the transistors 300 each include a gate structure 310 and source/drain regions 320 located at two opposite sides of the gate structure 310, where the gate structure 310 is formed on an n-well region 330, and the source/drain regions 320 are formed in the n-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of p-type dopant that are formed in the n-well region 330 by ion implantation. In an alternative embodiment, the source/drain regions 320 include epitaxial structures formed in and protruding from a surface of the semiconductor substrate 202 that are formed by epitaxial growth.

Alternatively, the transistors 300 independently may be a NMOS transistor. For example, the transistors 300 each include a gate structure 310 and source/drain regions 320 located at two opposite sides of the gate structure 310, where the gate structure 310 is formed on an p-well region 330, and the source/drain regions 320 are formed in the p-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of n-type dopant that are formed in the p-well region 330 by ion implantation. In an alternative embodiment, the source/drain regions 320 include epitaxial structures formed in and protruding from a surface of the semiconductor substrate 202 that are formed by epitaxial growth.

In a non-limiting example, all of the transistors 300 may have the same type. For example, all of the transistors 300 are NMOS transistors. For another example, the transistors 300 are PMOS transistors. The disclosure is not limited thereto. In another non-limiting example, one or some of the transistors 300 may have a type being different from the types of the rest of the transistors 300. For example, one or some of the transistors 300 are NMOS transistors, and the rest of the transistors 300 are PMOS transistors, or vice versa.

In some embodiments, some or all of the transistors 300 are or are part of a logic component(s) with or without interaction there-between. In addition, at least some of the transistors 300 are or are part of a memory component(s), such as a static random-access memory (SRAM), with or without interaction there-between, where the transistors 300 serving as logic components and the transistors 300 serving as memory components are electrically coupled and electrically communicated.

For illustrative purposes, the transistors 300 are illustrated in form of planar transistors, however the disclosure is not limited thereto. The transistors 300 independently may be a field-effect transistor (FET), such as a planar FET, a tunnel field-effect transistor (TFET), or a fin-type FET (FinFET); a gate all around (GAA) transistor; a nanosheet transistor; a nanowire transistor; the like; or combinations thereof, depending on the demand and/or product design requirements/layout. In accordance with some embodiments, the transistors 300 may be or include a portion of a planar FET and/or a TFET device, which may include a silicon body standing on a substrate, and a gate is standing on the silicon body (i.e., the channel region) providing control from a top side of the channel region. In accordance with some embodiments, the transistors 300 may be or include a portion of a finFET device, which may include a thin (vertical) fin of silicon body on a substrate, and a gate is wrapped around the fin (i.e., the channel region) providing control from three sides of the channel region. In accordance with some embodiments, the transistors 300 may be or include a portion of a nanostructure transistor device (such as a GAA transistor device, a nanosheet transistor or a nanowire transistor), which may include a gate structure wrapping around (e.g., engaging) the perimeter of one or more nanostructures (i.e., channel regions) for improved control of channel current flow.

As illustrated in FIG. 1, for example, the substrate 200A further includes a dielectric layer 206 stacked on the semiconductor substrate 202 and a plurality of contact plugs 208 penetrating through the dielectric layer 206 to electrically connect to the transistors 300. In certain embodiments, the dielectric layer 206 and the contact plugs 208 are also formed in the structure 200A during the FEOL processes. The dielectric layer 206 may laterally surround the gate structures 310 and cover the source/drain regions 320 for providing protections to the components formed in/on the semiconductor substrate 202. Some of the contact plugs 208 may penetrate through the dielectric layer 206 in order to establish electrical connection with the source/drain regions 320, while others of the contact plugs 208 (not shown) may partially penetrate through the dielectric layer 206 to establish electrical connection with the gate electrodes (e.g. the gate electrodes 312) of the gate structures 310, in order to provide terminals for electrical connections to later-formed components (e.g. an interconnect or interconnect structure) or external components.

The dielectric layer 206 may be referred to as an interlayer dielectric (ILD) layer, while the contact plugs 208 may be referred to as metal contacts or metallic contacts. For example, the contact plugs 208 electrically connected to the source/drain regions 320 are referred to as source/drain contacts, and the contact plugs 208 electrically connected to the gate electrodes 312 are referred to as gate contacts. In some embodiments, the contact plugs 208 may include copper (Cu), copper alloys, nickel (Ni), aluminum (Al), manganese (Mn), magnesium (Mg), silver (Ag), gold (Au), tungsten (W), a combination of thereof, or the like. The contact plugs 208 may be formed by, for example, plating such as electroplating or electroless plating, CVD such as plasma enhanced CVD (PECVD), atomic layer deposition (ALD), and physical vapor deposition (PVD), a combination thereof, or the like. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the dielectric layer 206 includes silicon oxide, silicon nitride, silicon carbide, silicon oxynitride, silicon carbonitride, silicon carbide oxynitride, spin-on glass (SOG), phosphosilicate glass (PSG), borosilicate glass (BSG), borophosphosilicate glass (BPSG), fluorinated silica glass (FSG), carbon doped silicon oxide (e.g., SiCOH), polyimide, and/or a combination thereof. In alternative embodiments, the dielectric layer 206 include low-k dielectric materials. For example, the low-k dielectric material generally has a dielectric constant lower than 3.9. Examples of low-k dielectric materials may include BLACK DIAMOND® (Applied Materials of Santa Clara, Calif.), Xerogel, Aerogel, amorphous fluorinated carbon, Parylene, benzocyclobutene (BCB), Flare, SILK® (Dow Chemical, Midland, Mich.), hydrogen silsesquioxane (HSQ) or fluorinated silicon oxide (SiOF), and/or a combination thereof. It is understood that the dielectric layer 206 may include one or more dielectric materials. For example, the dielectric layer 206 include a single-layer structure or a multilayer structure. In some embodiments, the dielectric layer 206 is formed to a suitable thickness by CVD such as flowable chemical vapor deposition (FCVD), HDP-CVD, and SACVD, spin-on, sputtering, or other suitable methods.

A seed layer (not shown) may be optionally formed between the dielectric layer 206 and the contact plugs 208. That is, for example, the seed layer covers a bottom surface and sidewalls of each of the contact plugs 208. In some embodiments, the seed layer is a metal layer, which may be a single layer or a composite layer comprising a plurality of sub-layers formed of different materials. In some embodiments, the seed layer includes copper layer and the seed layer includes a titanium layer and a copper layer over the titanium layer. The seed layer is formed using, for example, PVD or the like. In one embodiment, the seed layer may be omitted.

In addition, an additional barrier layer or adhesive layer (not shown) may be optionally formed between the contact plugs 208 and the dielectric layer 206. Owing to the additional barrier layer or adhesive layer, it is able to prevent the seed layer and/or the contact plugs 208 from diffusing to the underlying layers and/or the surrounding layers. The additional barrier layer or adhesive layer may include T₁, TiN, Ta, TaN, a combination thereof, a multilayer thereof, or the like, and may be formed using CVD, ALD, PVD, a combination thereof, or the like. In an alternative embodiment of which the seed layer is included, the additional barrier layer or adhesive layer is interposed between the dielectric layer 206 and the seed layer, and the seed layer is interposed between the contact plugs 208 and the additional barrier layer or adhesive layer. In one embodiment, the additional barrier layer or adhesive layer may be omitted.

As illustrated in FIG. 1, for example, the substrate 200A further includes a plurality of through vias 1001. In some embodiments, the through vias 1001 are formed to be laterally next to the transistors 300, vertically penetrate through the dielectric layer 206 and further extend into a position inside the semiconductor substrate 202. In some embodiments, the through vias 1001 each includes a liner 110 and a conductive via 120, where a bottom and a sidewall of the conductive via 120 are lined with the liner 110. That is, the conductive vias 120 of the through vias 1001 are separated from the semiconductor substrate 202 and the dielectric layer 206 through the respective liners 110. In some embodiments, the through vias 1001 may be tapered from the dielectric layer 206 to the semiconductor substrate 202. Alternatively, the through vias 1001 may have substantially vertical sidewalls. In a cross-sectional view along the direction Z, the shape of the through vias 1001 may depend on the demand and/or product design requirements/layout, and is not intended to be limited in the disclosure. On the other hand, in the top (plane) view on the X-Y plane, the shape of the through vias 1001 is circular shape. However, depending on the design requirements, and the shape of the through vias 1001 may be an oval shape, a rectangular shape, a polygonal shape, or combinations thereof; the disclosure is not limited thereto. In some embodiments, the through vias 1001 are not accessibly revealed by a rear surface S202b of the semiconductor substrate 202, and are accessibly revealed by a surface S206 of the dielectric layer 206. The number of the through vias 1001 is not limited in the disclosure, and may be selected and designated based on the demand and/or product design requirements/layout.

The conductive vias 120 may be formed of a conductive material, such as copper, tungsten, aluminum, silver, combinations thereof, or the like. The liners 110 may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the liners 110 and the semiconductor substrate 202 and between the liners 110 and the dielectric layer 206. In addition to or alternatively, the liners 110 may be omitted.

The liners 110, the conductive vias 120 and the optional dielectric liners may be formed by, but not limited to, forming a plurality of recesses in the dielectric layer 206 and the substrate 202; respectively depositing the optional dielectric material, the barrier material and the conductive material in the recesses; and removing excess materials on a plane where illustrated top openings of the recesses located at. For example, the recesses are lined with the optional dielectric liners so as to laterally separate the liners 110 lining the sidewalls and illustrated bottom surfaces of the conductive vias 120 from the semiconductor substrate 202 and the dielectric layer 206. The through vias 1001 are formed by using a via-first approach, in some embodiments. In such embodiments, the through vias 1001 are formed prior to the formation of an interconnect (e.g., 500). Alternatively, the through vias 1001 may be formed by using a via-last approach, where the through vias 1001 may be formed after the formation of an interconnect (e.g., 500).

In some embodiments, if considering a top or plane view (e.g., a X-Y plane) along a direction Z, the semiconductor substrate 202 is in a wafer or panel form. The semiconductor substrate 202 may be in a form of wafer-size having a diameter of about 4 inches or more. The semiconductor substrate 202 may be in a form of wafer-size having a diameter of about 6 inches or more. The semiconductor substrate 202 may be in a form of wafer-size having a diameter of about 8 inches or more. Or alternatively, the semiconductor substrate 202 may be in a form of wafer-size having a diameter of about 12 inches or more. The transistors 300 formed in the substrate 200A may be arranged in a form of an array along a direction X and a direction Y. The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction Z may be referred to as a stacking direction, and the X-Y plane defined by the direction X and the direction Y may be referred to as the plane view or top view.

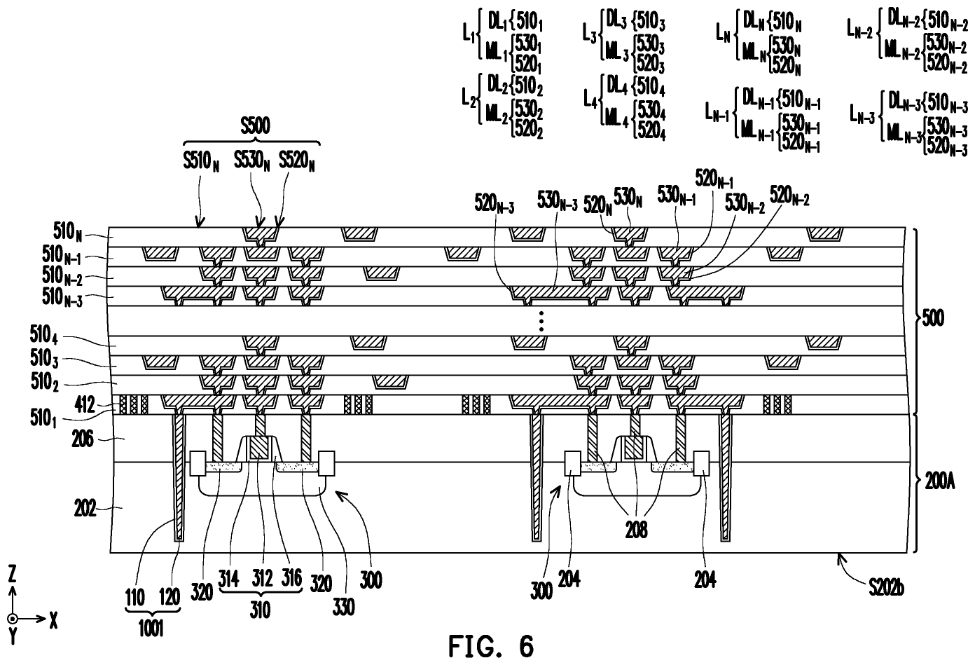

Continued on FIG. 1, in some embodiments, the stacked structure is formed on the substrate 200A. For example, the stacked structure includes an interconnect 500 (in FIG. 6) including a plurality of build-up layers (e.g., L₁, L₂, L₃, L₄ . . . , L_{N-3}, L_{N-2}, L_{N-1} and L_{N}) stacked thereon. In the disclosure, for illustrative purposes, the interconnect 500 includes a first portion including four build-up layers (e.g., L₁, L₂, L₃, L₄) and a second portion including N-4 build-up layers (e.g., . . . , L_{N-3}, L_{N-2}, L_{N-1} and L_{N}) stacked on and electrically connected thereto. However, the disclosure is not limited thereto, as an alternative, the first portion may include one, two, three, four, or more build-up layers and the second portion may include one, two, three, four, . . . , or more than N build-up layers (where N is greater than 1). The number of build-up layers included in the first portion of the interconnect 500 and the number of build-up layers included in the second portion of the interconnect 500 are selected and designed based on the demand and/or product design requirements/layout. In some embodiments, the first portion is referred to as local interconnection formed in a middle-end-of-line (MEOL) processes, and the second portion is referred to as global interconnection formed in a back-end-of-line (BEOL) fabrication process.

In some embodiments, the at least one build-up layer formed in the initial structure of FIG. 1 includes one build-up layer (e.g., a build-up layer L₁) as shown in FIG. 1 for illustrative purposes; however, the number of the at least one build-up layer formed in the initial structure of FIG. 1 may be two, three or more than three, depending on the demand and/or design requirements/layout. As shown in FIG. 1, in some embodiments, the build-up layer L₁ is disposed on (e.g., in physical contact with) and electrically coupled to the through vias 1001 and the components such as the transistors 300 through the contact plugs 208 for providing routing function thereto. The build-up layer L₁ may be referred to as a first build-up layer L₁ of the interconnect 500.

The formation of the build-up layer L₁ of the stacked structure may include, but not limited to, forming a blanket layer of a dielectric material (not shown) on the dielectric layer 206 over the semiconductor substrate 202 to cover up the through vias 1001 and the components such as the transistors 300; patterning the dielectric material blanket layer to form a dielectric layer 510₁, where a plurality of first openings (not label) penetrate through the dielectric layer 510₁; forming a seed layer 520₁ in the first openings; and forming a conductive material in the first opening over the seed layer 520₁ to form a conductive layer 530₁ over the seed layer 520₁ so to form a metallization layer ML₁ (may be referred to as a redistribution layer) in the first openings formed in the dielectric layer 510₁, thereby forming the build-up layer L₁. For example, as shown in FIG. 1, the metallization layer ML₁ of the build-up layer L₁ includes the seed layer 520₁ and the conductive layer 530₁ standing thereon and electrically connected thereto, and is laterally covered by a dielectric structure DL₁ of the build-up layer L₁, where the dielectric structure DL₁ includes the dielectric layer 510₁. As shown in FIG. 1, for example, the conductive layer 530₁ is electrically connected to the transistors 300 through the seed layer 520₁ and the conductive plugs 208, and is electrically connected to the through vias 1001 through the seed layer 520₁.

In some embodiments, the material of the dielectric layer 510₁ may be polyimide (PI), polybenzoxazole (PBO), benzocyclobutene (BCB), AlN, BN, diamond-like carbon, Al₂O₃, BeO, a nitride such as silicon nitride, an oxide such as silicon oxide, phosphosilicate glass (PSG), borosilicate glass (BSG), borophosphosilicate glass (BPSG), a combination thereof or the like, which may be patterned using a photolithography and/or etching process. The etching process may include a dry etching, a wet etching, or a combination thereof. After the etching process, a cleaning step may be optionally performed, for example, to clean and remove the residue generated from the etching process. In some embodiments, the dielectric material blanket layer is formed by suitable fabrication techniques such as spin-on coating, CVD (e.g., PECVD), or the like. For example, the material of the dielectric layer 510₁ is silicon oxide. The first openings formed in the dielectric layer 510₁ each may include a trench hole and a via hole underlying and spatially communicated to the trench hole. In some embodiments, the first openings each include a dual damascene structure. The formation of the first openings is not limited to the disclosure. The formation of first openings (with the dual damascene structure) can be formed by any suitable forming process, such as a via first approach or a trench first approach.

A lateral size of the trench holes may be greater than a lateral size of the via holes. In some embodiments, a sidewall of each of the via holes is a slant sidewall. In alternative embodiments, the sidewall of each of the via holes is a vertical sidewall. In some embodiments, a sidewall of each of the trench holes is a slant sidewall. In alternative embodiments, the sidewall of each of the trench holes is a vertical sidewall. The sidewall of one via hole and the sidewall of a respective one trench hole may be collectively referred to as a sidewall of one first opening formed in the dielectric layer 510₁. For illustrative purposes, the number of the first openings does not limit the disclosure, and may be designated and selected based on the demand and/or layout design requirements/layout. Portions of the metallization layer ML₁ formed in the trench holes may be referred to as conductive lines, conductive traces or conductive wires horizontally extended (e.g., extending in the direction X and/or the direction Y), and portions of the metallization layer ML₁ formed in the via holes may be referred to as conductive vias vertically extended (e.g., extending in the direction Z).

In other embodiments, the dielectric material blanket layer includes two-layer structure, where a first dielectric layer includes a silicon carbide (SiC) layer, a silicon nitride (Si₃N₄) layer, an aluminum oxide layer, or the like, and the second dielectric layer (stacking on the first dielectric layer) includes a silicon oxide layer (e.g., a silicon-rich oxide (SRO) layer), a silicon nitride layer, a silicon oxynitride layer, a spin-on dielectric layer, or a low-k dielectric layer. It should be noted that the low-k dielectric layer is generally made of dielectric materials having a dielectric constant lower than 3.9. In some alternative embodiments, the first dielectric layer and the second dielectric layer have different etching selectivities. In the case, the first dielectric layer may be referred to as an etching stop layer (ESL) to prevent the underlying elements (e.g., the contact plugs 208 and the dielectric layer 206) from damage caused by the over-etching, while the second dielectric layer may be referred to as an inter-metallic layer (IML). In such alternative embodiments, the first dielectric layer and the second dielectric layer are patterned through a set(s) of photolithography and etching processes. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. The first openings formed in the first dielectric layer and the second dielectric layer each may include a trench hole and a via hole underlying and spatially communicated to the trench hole. For example, the trench holes are formed in the second dielectric layer and extend from an illustrated top surface of the second dielectric layer to a position inside the second dielectric layer. For example, the via holes are formed in the second dielectric layer and the first dielectric layer and extend from the position inside the second dielectric layer to an illustrated bottom surface of the first dielectric layer. The position may be about ½ to about ⅓ of a thickness of the second dielectric layer; however, the disclosure is not limited thereto.

In some embodiments, the seed layer 520₁ and the conductive layer 530₁ are sequentially formed in the first openings by, but not limited to, conformally forming a blanket layer made of metal or metal alloy materials over the dielectric structure DL₁ and extending into the first openings, so to line the sidewalls of the first openings; filling the conductive material in the first openings; and removing excess amount of the blanket layer made of metal or metal alloy materials and the conductive material over the illustrated top surface of the dielectric layer 510₁, thereby the metallization layer ML₁ including the seed layer 520₁ and the conductive layer 530₁ is manufactured. The removal may be performed by a planarizing process such as a mechanical grinding, a chemical mechanical polishing (CMP), and/or an etching process. After the planarizing process, a cleaning process may be optionally performed, for example to clean and remove the residue generated from the planarizing process. However, the disclosure is not limited thereto, and the planarizing process may be performed through any other suitable method.

In some embodiments, the seed layer 520₁ is referred to as a metal layer, which can be a single layer or a composite layer including a plurality of sub-layers formed of different materials. In some embodiments, the seed layer 520₁ includes titanium, copper, molybdenum, tungsten, titanium nitride, titanium tungsten, combinations thereof, or the like. For example, the seed layer 520₁ may include a titanium layer and a copper layer over the titanium layer. The seed layer 520₁ may be formed using, for example, sputtering, PVD, or the like. The seed layer 520₁ may have a thickness (as measured in the direction Z) of about 1 nm to about 50 nm, although other suitable thickness may alternatively be utilized.

In some embodiments, a material of the conductive material includes a suitable conductive material, such as metal and/or metal alloy. For example, the conductive material can be Al, aluminum alloys, Cu, copper alloys, or combinations thereof (e.g., AlCu), the like, or combinations thereof. In some embodiments, the conductive material is formed by plating process or any other suitable method, which the plating process may include electroplating or electroless plating, or the like. In alternative embodiments, the conductive material may be formed by deposition. The disclosure is not limited thereto. In the case, an illustrated top surface (e.g., including a surface S530₁ and a surface S520₁) of the metallization layer ML₁ is substantially level with an illustrated top surface (e.g., including a surface S510₁) of the dielectric structure DL₁. That is, the illustrated top surface of the metallization layer ML₁ is substantially coplanar to the illustrated top surface of the dielectric structure DL₁.

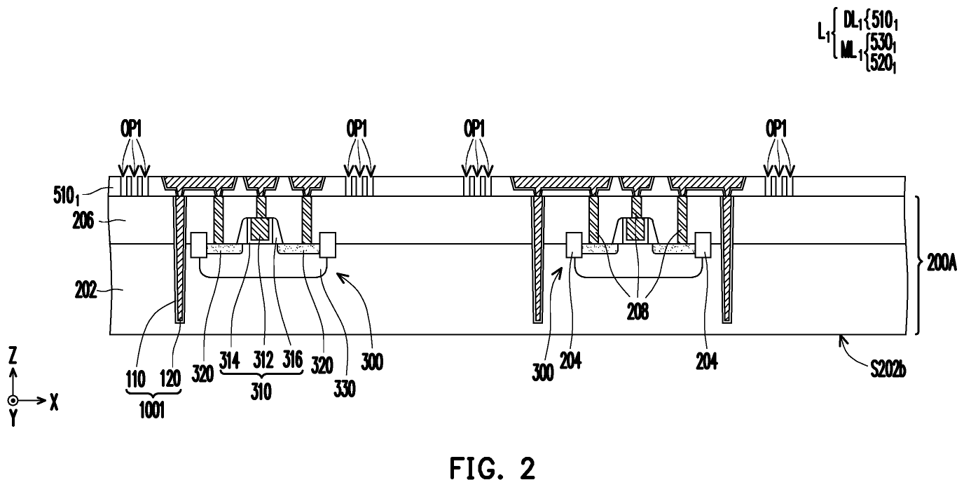

Referring to FIG. 2, in some embodiments, the dielectric layer 510₁ is patterned to form a plurality of openings OP1 penetrating through the dielectric layer 510₁, where the openings OP1 accessibly reveal the dielectric layer 206. In some embodiments, the openings OP1 have substantially vertical sidewalls, as shown in FIG. 2. Alternatively, the openings OP1 may be tapered from the surface S510₁ of the dielectric layer 510₁ to the substrate 200A. In a cross-sectional view along the direction Z, the shape of the openings OP1 may depend on the demand and/or product design requirements/layout, and is not intended to be limiting in the disclosure. On the other hand, in the top (plane) view on the X-Y plane, the shape of the openings OP1 is in a form of rectangular shape, see FIG. 37. However, depending on the demand and/or product design requirements/layout, and the shape of the opening OP1 may be in form of an oval shape, a circular shape, a polygonal shape, or combinations thereof; the disclosure is not limited thereto. Only twelve openings OP1 are shown in FIG. 2 for illustrative purposes, however the disclosure is not limited thereto. The number of the openings OP1 can be more than or less than twelve, which may be selected and/or designated depending on the demand and/or product design requirements/layout.

The patterning process may be performed by using a photolithography and/or etching process. The etching process may include a dry etching, a wet etching, or a combination thereof. After the etching process, a cleaning step may be optionally performed, for example to clean and remove the residue generated from the etching process.

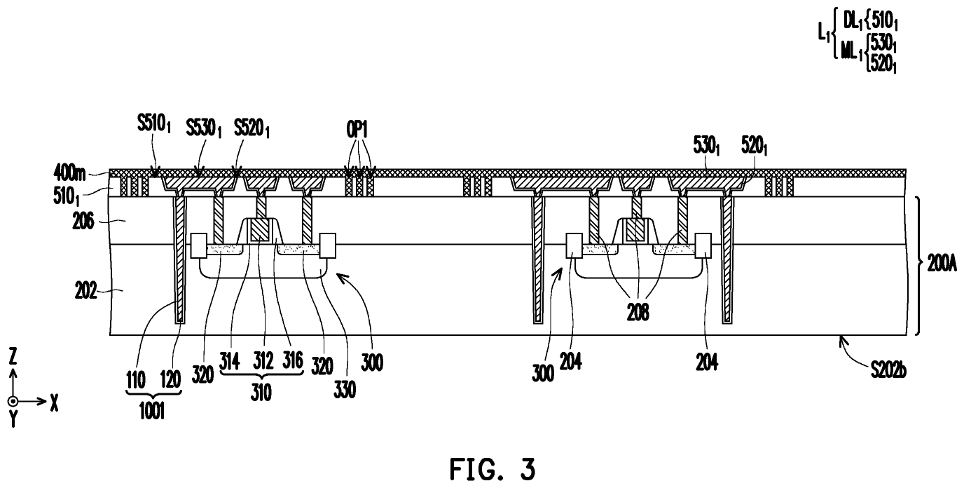

Referring to FIG. 3, in some embodiments, a thermal energy storage material 400m is deposited on the first build-up layer L₁ and further extend into the openings OP1. The openings OP1 are fully filled by the thermal energy storage material 400m, for example. As shown in FIG. 3, the thermal energy storage material 400m may be in (e.g., physical) contact with the dielectric layer 206 exposed by the openings OP1. The thermal energy storage material 400m may be formed by deposition (such as PVD or CVD) or the like. In a non-limiting example, the thermal energy storage material 400m includes a thermal (energy) storage solid-solid phase change material (PCM), which is configured to readily undergo a solid-solid martensitic transformation from one crystalline structure to another different crystalline structure during a change in temperature. In some embodiments, the solid-solid martensitic transformation from one crystalline structure to another different crystalline structure is reversible. In such case, the thermal energy storage material 400m is capable of storing the thermal energy (e.g., a heat generated by a hotspot such as the transistors 300) in form of mechanical deformation (e.g., from a first crystalline structure to a second different crystalline structure) and later release the thermal energy (e.g., heat) with a slower rate in form of mechanical deformation (e.g., from the second crystalline structure to the first different crystalline structure). Owing to such mechanism, the heat spikes in the semiconductor device of the disclosure can be alleviated. A material of the thermal energy storage material 400m may include germanium(Ge)-antimony(Sb)-tellurium(Te) (GST), vanadium dioxide (VO₂), titanium (III) oxide, metal alloys, any other suitable metal alloys (such as a nickel-tin-based system including NiTi, NiTiHf, NiCuTi, NiCuTiHf, or NiTiV; or the like), or the like. For example, the thermal energy storage material 400m includes a shape memory alloy (SMA) which is readily undergoing the solid-solid martensitic transformation. The disclosure is not specifically limited thereto. In some embodiments, a thermal conductivity of the thermal energy storage material 400m is greater than a thermal conductivity of the dielectric layer 510₁.

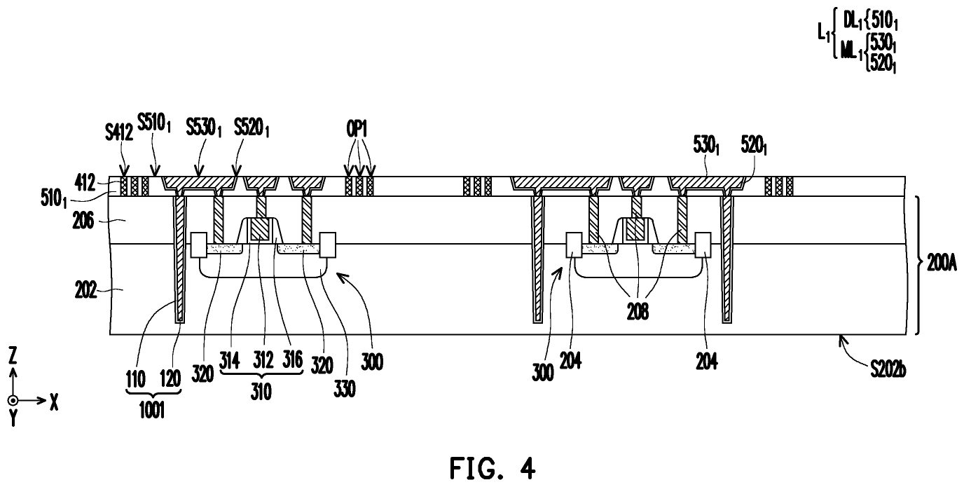

Referring to FIG. 4, in some embodiments, a planarization process is performed on the thermal energy storage material 400m to form a plurality of thermal control elements 412 in the openings OP1. For example, the thermal energy storage material 400m is planarized to remove the excess amount thereof located on the surface S510₁ of the dielectric layer 510₁ to form the thermal control elements 412 inside the opening OP1 and laterally next to the metallization layer ML₁ of the interconnect 500. In some embodiments, the thermal control elements 412 are laterally covered by (e.g., in physical contact with) the dielectric structure DL₁ of the interconnect 500. The thermal control elements 412 may be embedded in the first build-up layer L₁ of the interconnect 500. In some embodiments, a surface S412 of the thermal control elements 412 is substantially level with the surface S510₁ of the dielectric layer 510₁, the surface S520₁ of the seed layer 520₁ and the surface S530₁ of the conductive layer 530₁ of the interconnect 500. In other words, the surface S412 of the thermal control elements 412 is substantially coplanar to the surface S510₁ of the dielectric layer 510₁, the surface S520₁ of the seed layer 520₁ and the surface S530₁ of the conductive layer 530₁ of the interconnect 500. As shown in FIG. 4, the thermal control elements 412 may completely penetrate through the dielectric layer 510₁. For example, the thermal control elements 412 are in a multi-pillar-form or a multi-columnar form. In a non-limiting example, the multi-pillar-form or the multi-columnar form of the thermal control elements 412 is extended along the direction Z, where the thermal control elements 412 are separated from each other in the directions X and Y (e.g., in the XY plane), as shown in FIG. 4. In another non-limiting example, the multi-pillar-form or the multi-columnar form of the thermal control elements 412 is extended along the direction X or Y (e.g., in the XY plane), where the thermal control elements 412 are separated from each other in the direction Z, not shown.

In some embodiments, the thermal control elements 412 are referred to as thermal capacitors, thermal storage capacitors, thermal control components, thermal control modules, thermal management element, thermal management components, or thermal management modules. The thermal control elements 412 are formed in an arrangement of array form. For example, the thermal control elements 412 are arranged in the form of a matrix, such as a U×V array or a U×V array (U, V>0, U may or may not be equal to V) along the direction X and the direction Y, where the matrix have opening hole therein corresponding to a location of the hotspot (e.g., the transistors 300) inside the semiconductor device of the disclosure. Owing to the thermal control elements 412, the heat generated from the hotspot (e.g., the transistors 300) inside the semiconductor device of the disclosure can be drawn towards and stored inside the thermal control elements 412, which alleviate the heat spikes in the hotspot (e.g., the transistors 300) inside the semiconductor device of the disclosure, thereby improving the reliability of the semiconductor device of the disclosure. In some embodiments, the thermal control elements 412 are electrically isolated from the interconnect 500 and the transistors 300 and thermally coupled to the interconnect 500 and the transistors 300.

The planarization process may include a grinding process, a CMP process, an etching process, the like, or combinations thereof. During the planarization process, the dielectric layer 510₁, the seed layer 520₁ and/or the conductive layer 530₁ may also be planarized. After planarizing, a cleaning process may be optionally performed, for example to clean and remove the residue generated from the planarization process. However, the disclosure is not limited thereto, and the planarization process may be performed through any other suitable method.

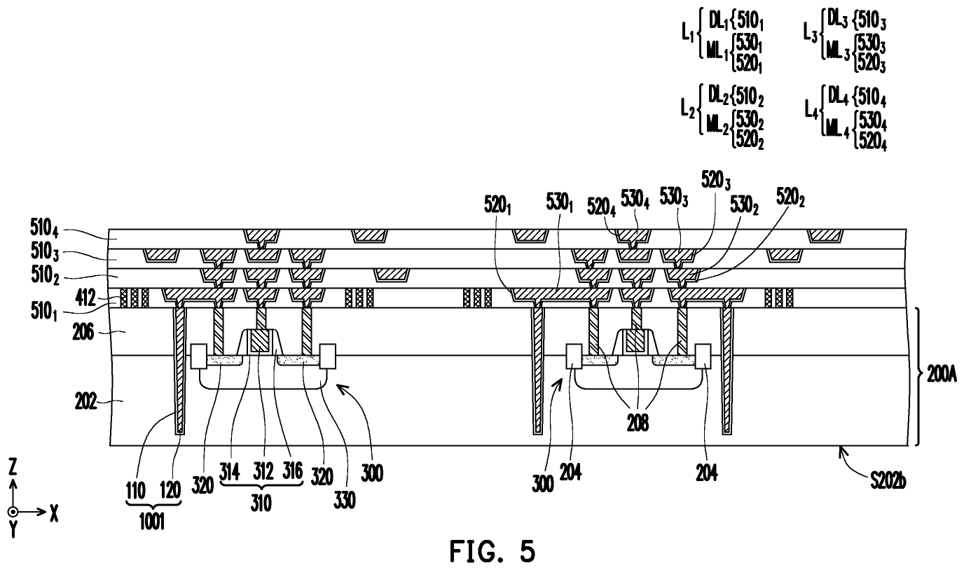

Referring to FIG. 5 and FIG. 6, in some embodiments, the rest of build-up layers (e.g., L₂, L₃, L₄ . . . , L_{N-3}, L_{N-2}, L_{N-1} and L_{N}) in included in the local interconnection and the global interconnection of the interconnect 500 are formed on the first build-up layer L₁ and the thermal control element 412. As shown in FIG. 5, in the local interconnection of the interconnect 500, the build-up layer L₂ (including a dielectric layer 510₂, a seed layer 520₂ and a conductive layer 530₂) is disposed on (e.g., in physical contact with) and electrically connected to the build-up layer L₁, and thus is electrically coupled to the through vias 1001 and the components (e.g., transistors 300) formed in the semiconductor substrate 202 through the contact plugs 208 and the build-up layer L₁ for providing routing function thereto; the build-up layer L₃ (including a dielectric layer 510₃, a seed layer 520₃ and a conductive layer 530₃) is disposed on (e.g., in physical contact with) and electrically connected to the build-up layer L₂, and thus is electrically coupled to the through vias 1001 and the components (e.g., transistors 300) formed in the semiconductor substrate 202 through the contact plugs 208 and the build-up layers L₁-L₂ for providing routing function thereto; and the build-up layer L₄ (including a dielectric layer 510₄, a seed layer 520₄ and a conductive layer 530₄) is disposed on (e.g., in physical contact with) and electrically connected to the build-up layer L₃, and thus is electrically coupled to the through vias 1001 and the components (e.g., transistors 300) formed in the semiconductor substrate 202 through the contact plugs 208 and the build-up layers L₁-L₃ for providing routing function thereto.

In such case, the build-up layer L₂ is referred to as a second build-up layer L₂ including a metallization layer ML₂ and a dielectric structure DL₂ laterally covering the metallization layer ML₂, where the metallization layer ML₂ (may be referred to as a redistribution layer) includes the seed layer 520₂ and the conductive layer 530₂, the dielectric structure DL₂ includes the dielectric layer 510₂. The build-up layer L₃ may be referred to as a third build-up layer L₃ including a metallization layer ML₃ and a dielectric structure DL₃ laterally covering the metallization layer ML₃, where the metallization layer ML₃ (may be referred to as a redistribution layer) includes the seed layer 520₃ and the conductive layer 530₃, the dielectric structure DL₃ includes the dielectric layer 510₃. The build-up layer L₄ may be referred to as a third build-up layer L₄ including a metallization layer ML₄ and a dielectric structure DL₄ laterally covering the metallization layer ML₄, where the metallization layer ML₄ (may be referred to as a redistribution layer) includes the seed layer 520₄ and the conductive layer 530₄, the dielectric structure DL₄ includes the dielectric layer 510₄.

As shown in FIG. 6, in the in the global interconnection of the interconnect 500, the build-up layer L_{N-3} (including a dielectric layer 510_{N-3}, a seed layer 520_{N-3} and a conductive layer 530_{N-3}) is disposed over and electrically coupled to the build-up layer L₄ (e.g., through the additional build-up layers formed there-between, if any), and thus is electrically coupled to the through vias 1001 and the components (e.g., transistors 300) formed in the semiconductor substrate 202 through the contact plugs 208, the build-up layers L₁ to L₄ and the additional build-up layers formed there-between (if any) for providing routing function thereto; the build-up layer L_{N-2} (including a dielectric layer 510_{N-2}, a seed layer 520_{N-2} and a conductive layer 530_{N-2}) is disposed on (e.g., in physical contact with) and electrically connected to the build-up layer L_{N-3}, and thus is electrically coupled to the through vias 1001 and the components (e.g., transistors 300) formed in the semiconductor substrate 202 through the contact plugs 208 and the build-up layers L₁ to L_{N-3} for providing routing function thereto; the build-up layer L_{N-1} (including a dielectric layer 510_{N-1}, a seed layer 520_{N-1} and a conductive layer 530_{N-1}) is disposed on (e.g., in physical contact with) and electrically connected to the build-up layer L_{N-2}, and thus is electrically coupled to the through vias 1001 and the components (e.g., transistors 300) formed in the semiconductor substrate 202 through the contact plugs 208 and the build-up layers L₁ to L_{N-2} for providing routing function thereto; and the build-up layer L_{N} (including a dielectric layer 510_{N}, a seed layer 520_{N} and a conductive layer 530_{N}) is disposed on (e.g., in physical contact with) and electrically connected to the build-up layer L_{N-1}, and thus is electrically coupled to the through vias 1001 and the components (e.g., transistors 300) formed in the semiconductor substrate 202 through the contact plugs 208 and the build-up layers L₁ to L_{N-1} for providing routing function thereto.

In such case, the build-up layer L_{N-3} may be referred to as a third build-up layer L_{N-3} including a metallization layer ML_{N-3} and a dielectric structure DL_{N-3} laterally covering the metallization layer ML_{N-3}, where the metallization layer ML_{N-3} (may be referred to as a redistribution layer) includes the seed layer 520_{N-3} and the conductive layer 530_{N-3}, the dielectric structure DL_{N-3} includes the dielectric layer 510_{N-3}. The build-up layer L_{N-2} may be referred to as a third build-up layer L_{N-2} including a metallization layer ML_{N-2} and a dielectric structure DL_{N-2} laterally covering the metallization layer ML_{N-2}, where the metallization layer ML_{N-2} (may be referred to as a redistribution layer) includes the seed layer 520_{N-2} and the conductive layer 530_{N-2}, the dielectric structure DL_{N-2} includes the dielectric layer 510_{N-2}. The build-up layer L_{N-1} may be referred to as a third build-up layer L_{N-1} including a metallization layer ML_{N-1} and a dielectric structure DL_{N-1} laterally covering the metallization layer ML_{N-1}, where the metallization layer ML_{N-1} (may be referred to as a redistribution layer) includes the seed layer 520_{N-1} and the conductive layer 530_{N-1}, the dielectric structure DL_{N-1} includes the dielectric layer 510_{N-1}. The build-up layer L_{N} may be referred to as a third build-up layer L_{N} including a metallization layer ML_{N} and a dielectric structure DL_{N} laterally covering the metallization layer ML_{N}, where the metallization layer ML_{N} (may be referred to as a redistribution layer) includes the seed layer 520_{N} and the conductive layer 530_{N}, the dielectric structure DL_{N} includes the dielectric layer 510_{N}.

Up to here, the interconnect 500 is manufactured. In some embodiments, the interconnect 500 is disposed over the substrate 200A, and the interconnect 500 is electrically coupled to the components formed in the substrate 200A. That is, the interconnect 500 provides the routing functions to the components formed in the substrate 200A. In some embodiments, at least some of the components formed in the substrate 200A are electrically communicated to one another by the interconnect 500. As shown in FIG. 6, the interconnect 500 may be overlaid over the substrate 200A. The metallization layers ML₁ to ML_{N} of the interconnect 500 may be collectively referred to as a routing structure of the interconnect 500. In some embodiments, line dimensions (e.g., thickness and width) of the metallization layers ML₁ to ML_{N} of the interconnect 500 are gradually increased along a direction from the substrate 200A to the interconnect 500.

The interconnect 500 may be referred to as an interconnect structure or an interconnection. The formation and material of the build-up layers L₂ through L_{N} are similar to or substantially identical to the forming process and the material of the build-up layer L₁ as described in FIG. 1, and thus are not repeated therein for simplicity. In one embodiment, the materials of the dielectric layers 510₁ to 510_{N} are the same to each other. Alternatively, the materials of the dielectric layers 510₁ to 510_{N} may be different to one another, in part or all. An illustrated top surface S500 (e.g., including a surface S510_{N} of the dielectric layer 510_{N}, a surface S520_{N} of the seed layer 520_{N} and a surface S530_{N} of the conductive layer 530_{N}) of the interconnect 500 may be level and may have a high degree of coplanarity, as shown in FIG. 6.

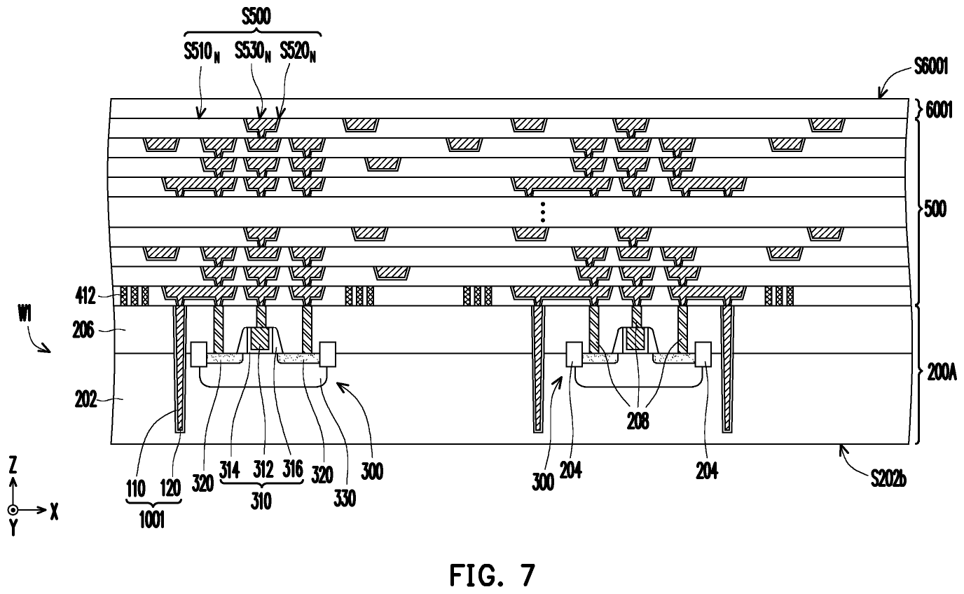

Referring to FIG. 7, in some embodiments, a dielectric layer 6001 is formed on the interconnect 500. For example, the dielectric layer 6001 is disposed on (e.g., in physical contact with) the illustrated top surface S500 (e.g., including S510_{N}, S520_{N} and S530_{N}) of the interconnect 500, where the interconnect 500 is disposed between the dielectric layer 6001 and the substrate 200A. The dielectric layer 6001 may be referred to as a bonding layer or a bonding dielectric layer. The dielectric layer 6001 may be a single layer or include a plurality of stacked dielectric sublayers. The dielectric layer 6001 may be formed by, but not limited to, conformally forming a blanket layer of the material used for forming the dielectric layer 6001 over the structure depicted in FIG. 6. In a non-limiting example, the material of the dielectric layer 6001 may include inorganic materials such as silicon oxide, silicon nitride, silicon oxynitride, silicon carbonitride or silicon oxy-carbonitride; other suitable dielectric layer; or a combination thereof. The dielectric layer 6001 may be formed by suitable fabrication techniques such as spin-on coating, CVD, ALD, PVD, or the like. An illustrated top surface S6001 of the dielectric layer 6001 may be level and may have a high degree of coplanarity, as shown in FIG. 7. Up to here, a circuit wafer W1 is manufactured, where the circuit tier W1 includes the substrate 200A (including a semiconductor substrate 202 formed with a plurality of transistors 300, a plurality of isolation structures 204, a dielectric layer 206, a plurality of contact plugs 208 and the through vias 1001), the interconnect 500 disposed on and electrically coupled to the substrate 200A, the thermal control elements 412 embedded in the interconnect 500, and the dielectric layer 6001 disposed on the interconnect 500.

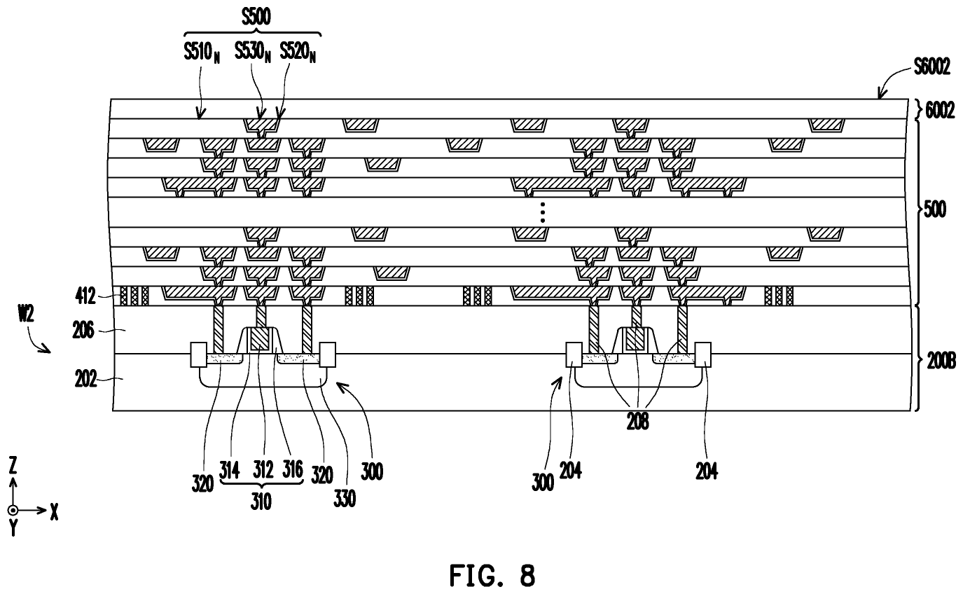

Referring to FIG. 8, in some embodiments, a circuit wafer W2 is provided. For example, the circuit wafer W2 includes a substrate 200B (including a semiconductor substrate 202 formed with a plurality of transistors 300, a plurality of isolation structures 204, a dielectric layer 206, a plurality of contact plugs 208), the interconnect 500 disposed on and electrically coupled to the substrate 200B, the thermal control elements 412 embedded in the interconnect 500, and a dielectric layer 6002 disposed on the interconnect 500. The details, formations and materials of the semiconductor substrate 202, the isolation structures 204, the dielectric layer 206, the contact plugs 208 included in the substrate 200B, the thermal control elements 412, the interconnect 500 and the dielectric layer 6002 of the circuit wafer W2 are similar to or substantially identical to the semiconductor substrate 202, the isolation structures 204, the dielectric layer 206, the contact plugs 208 included in the substrate 200A, the thermal control elements 412, the interconnect 500 and the dielectric layer 6001 of the circuit wafer W1 as described in FIG. 1 through FIG. 7, respectively; and thus are not repeated herein for brevity. An illustrated top surface S6002 of the dielectric layer 6002 may be level and may have a high degree of coplanarity, as shown in FIG. 8. The dielectric layer 6002 may be referred to as a bonding layer or a bonding dielectric layer.

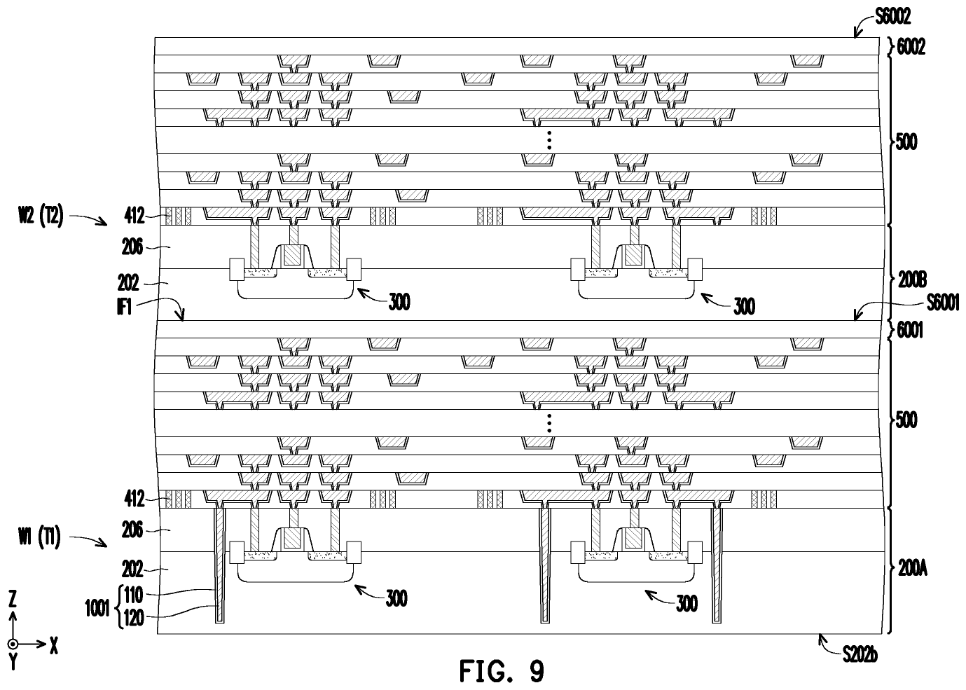

Referring to FIG. 9, in some embodiments, the circuit wafer W2 is placed over and bonded to the circuit wafer W1 by wafer-on-wafer (WoW) bonding. In some embodiments, the circuit wafer W2 is placed over the circuit wafer W1 for bonding by pick-and-place process. For example, the semiconductor substrate 202 of the circuit wafer W2 is placed on (e.g., in physical contact with) the surface S6001 of the dielectric layer 6001 of the circuit wafer W1, and the semiconductor substrate 202 of the circuit wafer W2 is bonded to the surface S6001 of the dielectric layer 6001 of the circuit wafer W1 by bonding process including a dielectric-to-dielectric bonding (such as a ‘oxide’-to-‘silicon’ bonding or a ‘nitride’-to-‘silicon’ bonding). In such embodiments, a bonding interface IF1 including a dielectric-to-dielectric bonding interface (such as a ‘oxide’-to-‘silicon’ bonding interface or a ‘nitride’-to-‘silicon’ bonding interface) exists between the circuit wafer W2 and the circuit wafer W1, and which is considered as a bonding interface of the circuit wafer W2 and the circuit wafer W1. After bonding, the circuit wafer W1 may be referred to as a first tier T1 of a stacking structure depicted in FIG. 9, and the circuit wafer W2 may be referred to as a second tier T2 of the stacking structure.

Referring to 10, a circuit wafer W3 is provided. For example, the circuit wafer W3 includes a substrate 200B (including a semiconductor substrate 202 formed with a plurality of transistors 300, a plurality of isolation structures 204, a dielectric layer 206, a plurality of contact plugs 208), the interconnect 500 disposed on and electrically coupled to the substrate 200B, and the thermal control elements 412 embedded in the interconnect 500. The details, formations and materials of the semiconductor substrate 202, the isolation structures 204, the dielectric layer 206, the contact plugs 208 included in the substrate 200B, the thermal control elements 412 and the interconnect 500 of the circuit wafer W3 are similar to or substantially identical to the semiconductor substrate 202, the isolation structures 204, the dielectric layer 206, the contact plugs 208 included in the substrate 200A, the thermal control elements 412 and the interconnect 500 of the circuit wafer W1 as described in FIG. 1 through FIG. 6, respectively; and thus are not repeated herein for brevity.

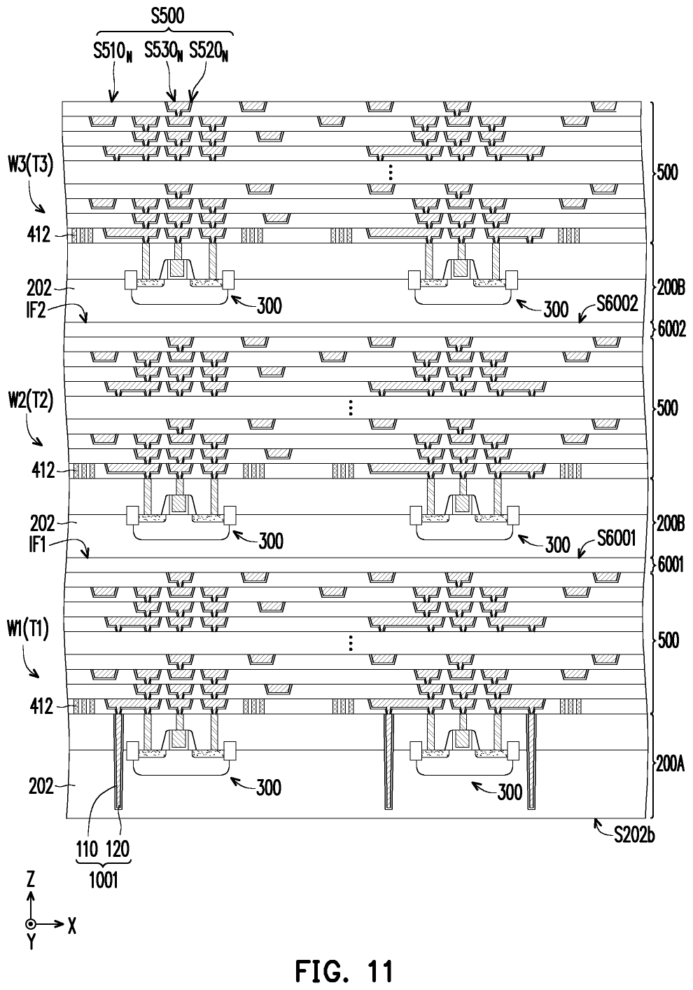

Referring to FIG. 11, in some embodiments, the circuit wafer W3 is placed over and bonded to the circuit wafer W2 by WoW bonding. In some embodiments, the circuit wafer W3 is placed over the circuit wafer W2 for bonding by pick-and-place process. For example, the semiconductor substrate 202 of the circuit wafer W3 is placed on (e.g., in physical contact with) the surface S6002 of the dielectric layer 6002 of the circuit wafer W2, and the semiconductor substrate 202 of the circuit wafer W3 is bonded to the surface S6002 of the dielectric layer 6002 of the circuit wafer W2 by bonding process including a dielectric-to-dielectric bonding (such as a ‘oxide’-to-‘silicon’ bonding or a ‘nitride’-to-‘silicon’ bonding). In such embodiments, a bonding interface IF2 including a dielectric-to-dielectric bonding interface (such as a ‘oxide’-to-‘silicon’ bonding interface or a ‘nitride’-to-‘silicon’ bonding interface) exists between the circuit wafer W3 and the circuit wafer W2, and which is considered as a bonding interface of the circuit wafer W3 and the circuit wafer W2. After bonding, the circuit wafer W3 may be referred to as a third tier T3 of the stacking structure depicted in FIG. 11.

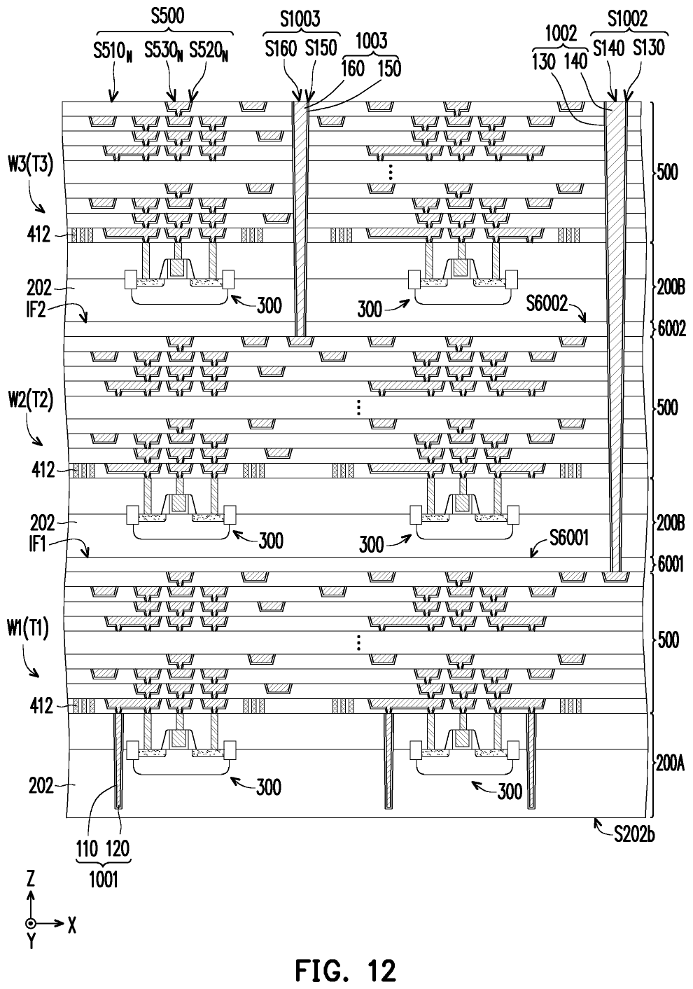

Referring to FIG. 12, in some embodiments, at least one through via 1002 (including a liner 130 and a conductive via 140) and at least one through via 1003 (including a liner 150 and a conductive via 160) are formed in the stacking structure depicted FIG. 11. As shown in FIG. 12 for illustrative purposes, the at least one through via 1002 may include one through via 1002 and the at least one through via 1003 may include one through via 1003, however the disclosure is not limited thereto. The number of each of the through via 1002 and the through via 1003 may be more than one, which can be selected and/or designated based on the demand and/or product design requirements/layout. The details, formation and material of the through vias 1002 and 1003 are similar to or substantially identical to the details (e.g., configuration such as shape), formation and material of the through vias 1001 as described in FIG. 1, and thus are not repeated therein. As shown in FIG. 12, a bottom of the conductive via 140 of the through vias 1002 is accessibly revealed by the liner 130, and a bottom of the conductive via 160 of the through vias 1003 is accessibly revealed by the liner 150, for example. Alternatively, the bottom and the sidewall of the conductive via 140 of the through vias 1002 is physically covered by the liner 130, and the bottom and the sidewall of the conductive via 160 of the through vias 1003 is physically covered by the liner 150. In some embodiments, as shown in FIG. 12, an illustrated top surface S1002 (e.g., including a surface S130 of the liner 130 and a surface S140 of the conductive via 140) of the through via 1002 and an illustrated top surface S1003 (e.g., including a surface S150 of the liner 150 and a surface S160 of the conductive via 160) of the through via 1003 are substantially level with the illustrated top surface S500 (e.g., including S510_{N}, S520_{N} and S530_{N}) of the interconnect 500. In other words, the illustrated top surface S1002 (e.g., including S130 and S140) of the through via 1002 and the illustrated top surface S1003 (e.g., including S150 and S160) of the through via 1003 are substantially coplanar to the illustrated top surface S500 (e.g., including S510_{N}, S520_{N} and S530_{N}) of the interconnect 500.

In a non-limiting example, the through via 1002 penetrates through the second tier T2 and the third tier T3 of the stacking structure and further extends into the first tier T1 so to electrically connect the first tier T1, the second tier T2 and the third tier T3 to each other through (e.g., physically) contacting the through via 1002 and the metal features (e.g., the metallization layers of the interconnects 500) of the first tier T1, the second tier T2 and the third tier T3. In such case, the through via 1003 penetrates through the third tier T3 of the stacking structure and further extends into the second tier T2 so to electrically connect the second tier T2 and the third tier T3 to each other through (e.g., physically) contacting the through via 1003 and the metal features (e.g., the metallization layers of the interconnects 500) of the second tier T2 and the third tier T3.

In another non-limiting example, the through via 1002 penetrates through the second tier T2 and the third tier T3 of the stacking structure and further extends into the first tier T1 so to electrically connect the first tier T1 and the third tier T3 to each other through (e.g., physically) contacting the through via 1002 and the metal features (e.g., the metallization layers of the interconnects 500) of the first tier T1 and the third tier T3. In such alternative case, the through via 1003 penetrates through the third tier T3 of the stacking structure and further extends into the second tier T2 so to electrically connect the second tier T2 and the third tier T3 to each other through (e.g., physically) contacting the through via 1003 and the metal features (e.g., the metallization layers of the interconnects 500) of the second tier T2 and the third tier T3 and further electrically connect the first tier T1 and the second tier T2 to each other through (e.g., physically) contacting the through via 1002 and the third tier T3.

In the embodiments of which multiple through vias 1002 are included, the through vias 1002 penetrate through the second tier T2 and the third tier T3 of the stacking structure and further extend into the first tier T1, where one or some of the through vias 1002 electrically connect the first tier T1, the second tier T2 and the third tier T3 to each other through (e.g., physically) contacting the one or some through vias 1002 and the metal features (e.g., the metallization layers of the interconnects 500) of the first tier T1, the second tier T2 and the third tier T3, and the rest of the through vias 1002 electrically connect the first tier T1 and the third tier T3 to each other through (e.g., physically) contacting the rest through via 1002 and the metal features (e.g., the metallization layers of the interconnects 500) of the first tier T1 and the third tier T3, with one or more through vias 1003 penetrate through the third tier T3 of the stacking structure and further extend into the second tier T2 so to electrically connect the second tier T2 and the third tier T3 to each other through (e.g., physically) contacting the one or more through via 1003 and the metal features (e.g., the metallization layers of the interconnects 500) of the second tier T2 and the third tier T3. In certain embodiments of which the electrical connection among the first tier T1, the second tier T2 and the third tier T3 is properly established by the through vias 1002, the through vias 1003 may be omitted.

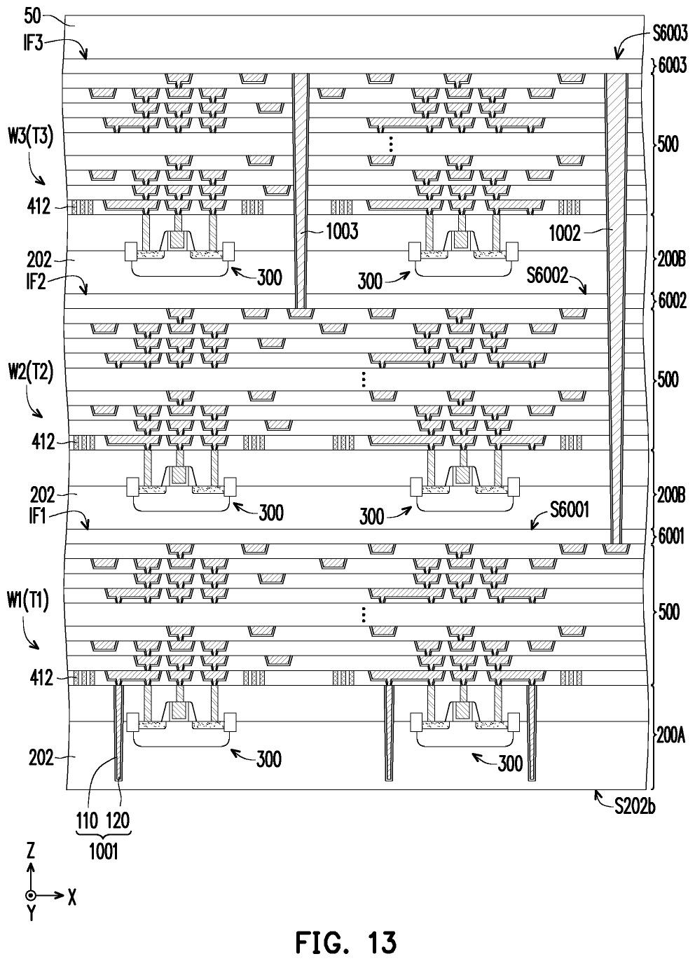

Referring to FIG. 12 and FIG. 13, in some embodiments, after forming the through vias 1002 and 1003, a dielectric layer 6003 is conformally formed on the illustrated top surface S1002 of the through via 1002, the illustrated top surface S1003 of the through via 1003 and the illustrated top surface S500 of the interconnect 500. The details, formations and materials of the dielectric layer 6003 are similar to or substantially identical to the dielectric layer 6001 of the circuit wafer W1 as described in FIG. 7; and thus, are not repeated herein for brevity. An illustrated top surface S6003 of the dielectric layer 6003 may be level and may have a high degree of coplanarity, as shown in FIG. 13. The dielectric layer 6003 may be referred to as a bonding layer or a bonding dielectric layer. In certain embodiments, the dielectric layer 6003 may be considered as a part of the circuit wafer W3.

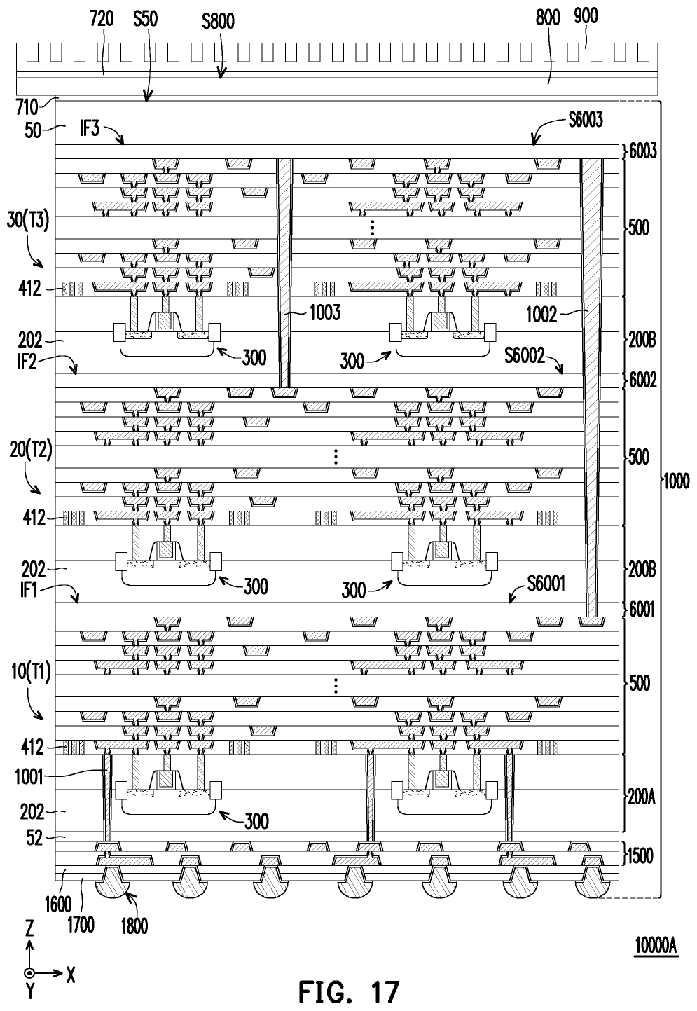

Continued on FIG. 13, for example, a carrier 50 is provided on and bonded to the dielectric layer 6003 by a WoW bonding process. The details of the carrier 50 may be similar to or substantially identical to the details of the semiconductor substrate 202 as described in FIG. 1, and thus are not repeated herein for brevity. For example, the carrier 50 is a silicon substrate being free of active components. In some embodiments, the carrier 50 is bonded to the dielectric layer 6003 by a bonding process including dielectric-to-dielectric bonding (such as a ‘oxide’-to-‘silicon’ bonding or a ‘nitride’-to-‘silicon’ bonding). In such embodiments, a bonding interface IF3 including a dielectric-to-dielectric bonding interface (such as a ‘oxide’-to-‘silicon’ bonding interface or a ‘nitride’-to-‘silicon’ bonding interface) exists between the circuit wafer W3 and the carrier 50, and which is considered as a bonding interface of the circuit wafer W3 and the carrier 50. After bonding, the carrier 50 may be referred to as a supporting substrate of the stacking structure including the tiers T1 to T3. In addition, due to the carrier is the silicon substrate, the carrier 50 may further be a heat dissipating element for the semiconductor device 10000A (in FIG. 17).

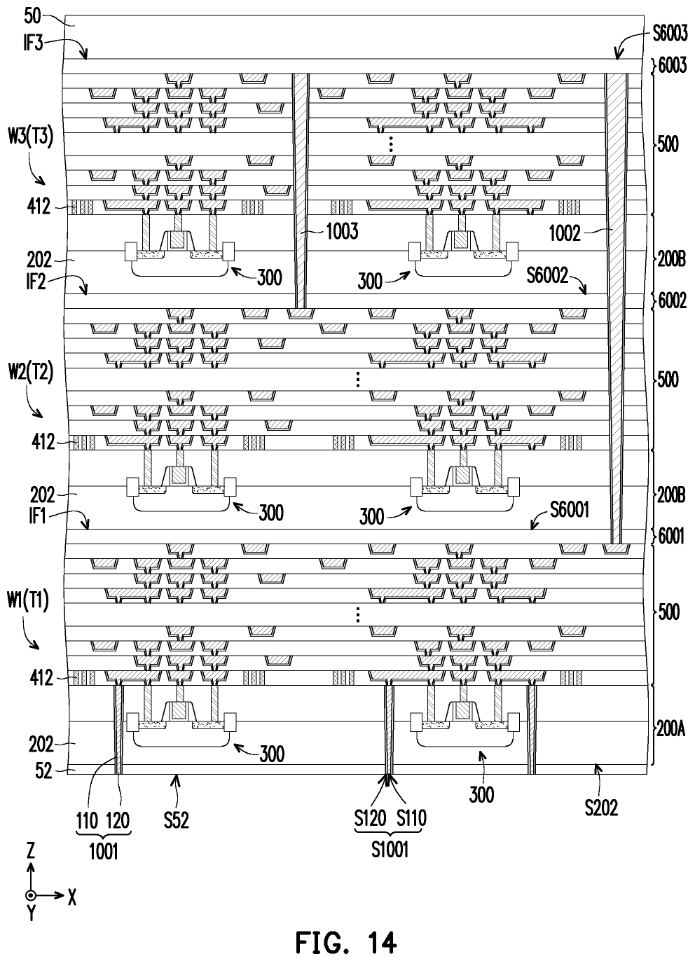

Referring to FIG. 13 and FIG. 14, in some embodiments, a planarization process is performed to the semiconductor substrate 202 of the circuit wafer W1 (in the first tier T1) so to thin down the semiconductor substrate 202 of the circuit wafer W1 and accessibly reveal the through vias 1001 therefrom. As shown in FIG. 14, a portion of the semiconductor substrate 202 and portions of liners 110 may be removed from the circuit wafer W1 of the stacking structure so to expose the conductive vias 120 therefrom. In some cases, during removing the portion of the semiconductor substrate 202 and the portions of liners 110 of the circuit wafer W1, portions of the conductive vias 120 of the circuit wafer W1 may also be slightly removed. Then, for example, a patterning process is performed on the semiconductor substrate 202 of the circuit wafer W1, where the semiconductor substrate 202 is further partially removed to form a semiconductor substrate 202 having a patterned bottom surface S202, such that a portion of each of the through vias 1001 (including a portion of each of the liners 110 and a portion of each of the conductive vias 120) protrude from the patterned bottom surface S202 of the semiconductor substrate 202. The patterning process may include an etching process (such as a wet each or a dry etch) or the like. The disclosure is not limited thereto.

As shown in FIG. 14, the liners 110 may cover the entire sidewalls of the conductive vias 120 and exposes the bottom of the conductive vias 120; however, the disclosure is not limited thereto. In one embodiment, the liners 110 may be cover only the sidewalls of the conductive vias 120 being embedded in the semiconductor substrate 202 having the patterned bottom surface S202. That is, for example, the liners 110, which are disposed on the sidewalls of the portions of the conductive vias 120 protruding from the patterned bottom surface S202 of the semiconductor substrate 202 after the planarization process, are removed during the patterning process. In one embodiment, the liners 110 may be cover the sidewalls and the bottoms of the conductive vias 120. That is, for example, the liners 110, which are disposed on the sidewalls and the bottoms of the portions of the conductive vias 120 protruding from the patterned bottom surface S202 of the semiconductor substrate 202 after the planarization process, are remained during the patterning process. The planarization process may include a grinding process, a CMP process, an etching process, combination thereof, or the like. The etching process may include a dry etching, a wet etching, or a combination thereof.

In some embodiments, a dielectric material (not shown) is formed over the patterned bottom surface S202 of the semiconductor substrate 202 of the circuit wafer W1. In some embodiments, the dielectric material is directly and conformally formed on the semiconductor substrate 202 and the through vias 1001 of the circuit wafer W1, where the semiconductor substrate 202 and the through vias 1001 of the circuit wafer W are covered by and in physical contact with the dielectric material. In some embodiments, the dielectric material may be formed as a blanket layer of dielectric material. In some embodiments, the dielectric material may be a polymer layer which made of PI, PBO, BCB, or any other suitable polymer-based dielectric material. In some embodiments, the dielectric material may be Ajinomoto Buildup Film (ABF), Solder Resist (SR) film, or the like. In some embodiments, the dielectric material may be formed by a suitable fabrication technique such as spin-coating, lamination, deposition, or the like. Thereafter, another planarization process is performed on the dielectric material to form a dielectric layer 52 laterally covering the through vias 1001 protruding out of the semiconductor substrate 202 of the circuit wafer W1, where the dielectric layer 52 accessibly exposes surfaces S1001 (including a surface S110 of the liners 110 and a surface S120 of the conductive vias 120) of the through vias 1001. In some embodiments, during the another planarization process, the dielectric material laterally located next to the protruded portions of the through vias 1001 over the patterned bottom surface S202 of the semiconductor substrate 202 are remained, while the rest of the dielectric material are removed; and the remained dielectric material constitutes the dielectric layer 52.

In some embodiments, the another planarization process may include a grinding process, a CMP process, an etching process, combination thereof, or the like. The etching process may include a dry etching, a wet etching, or a combination thereof. As shown in FIG. 14, a surface S52 of the dielectric layer 52 is substantially level with the surfaces S1001 of the through vias 1001, for example. That is, the surface S52 of the dielectric layer 52 is substantially coplanar to the surfaces S1001 of the through vias 1001. In some embodiments, after each of the planarization processes, a cleaning step may be optionally performed to clean and remove the residue generated from the planarization process. However, the disclosure is not limited thereto, and the each of the planarization processes may be performed through any other suitable method.

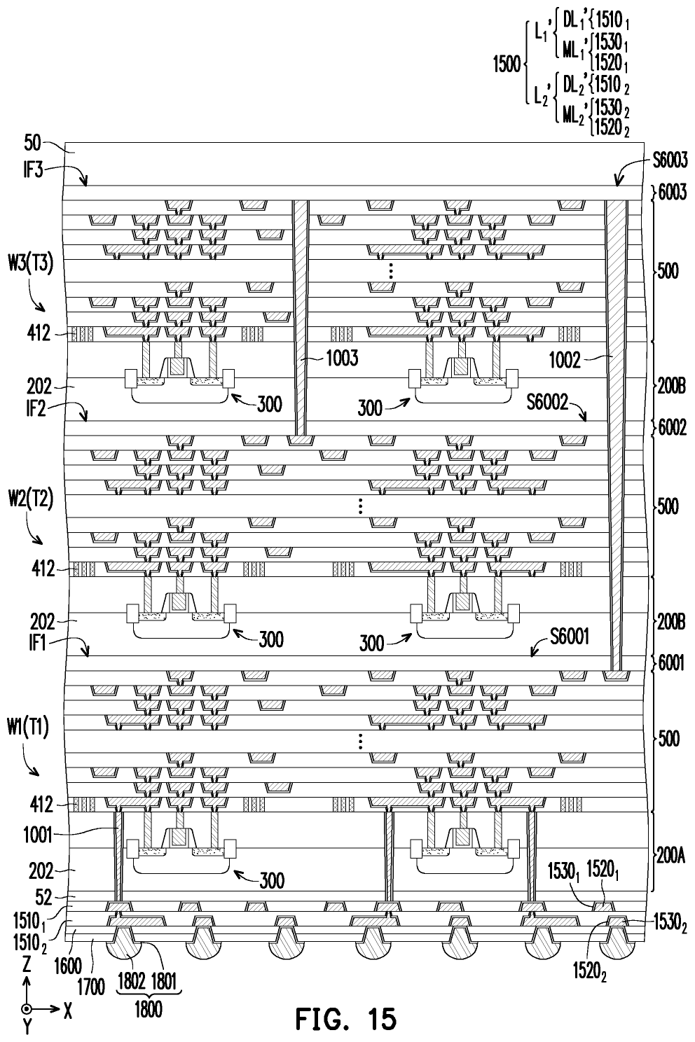

Referring to FIG. 15, in some embodiments, a redistribution circuit structure 1500 is formed over the circuit wafer W1, where the redistribution circuit structure 1500 is electrically coupled to the through vias 1001. As shown in FIG. 15 for illustrated purposes, the redistribution circuit structure 1500 includes only two build-up layers (e.g., L₁′ and L₂′), however the disclosure is not limited thereto. The number of the build-up layer included in the redistribution circuit structure 1500 may be one, two, or more, depending on the demand and/or product design requirements/layout. The build-up layer L₁′ may include a dielectric layer 15101, a seed layer 15201 and a conductive layer 15301, and the build-up layer L₂′ may include a dielectric layer 1510₂, a seed layer 1520₂ and a conductive layer 1530₂, as shown in FIG. 15. The details, formation and material of the dielectric layer 15101, the seed layer 15201 and the conductive layer 15301 included in the build-up layer L₁′ and the details, formation and material of the dielectric layer 1510₂, the seed layer 1520₂ and the conductive layer 1530₂ included in the build-up layer L₂′ are similar to the details, formation and material of the dielectric layer 510₁, the seed layer 520₁ and the conductive layer 530₁ included in the build-up layer L₁ as described in FIG. 1, and thus are not repeated herein.

The dielectric layer 15101 may be referred to as a dielectric structure DL₁′ of the build-up layer L₁′, and the seed layer 15201 and the conductive layer 15301 may be referred to as a metallization layer ML₁′ (or a redistribution layer) of the build-up layer L₁′. On the other hand, the dielectric layer 1510₂ may be referred to as a dielectric structure DL₂′ of the build-up layer L₂′, and the seed layer 1520₂ and the conductive layer 1530₂ may be referred to as a metallization layer ML₂′ (or a redistribution layer) of the build-up layer L₂′. The metallization layers ML₁′ and ML₂′ may be collectively referred to as a routing structure of the redistribution circuit structure 1500. In some embodiments, line dimensions (e.g., thickness and width) of the metallization layers ML₁′ and ML₂′ of the redistribution circuit structure 1500 are gradually increased along a direction from the circuit wafer W1 to the metallization layer ML₂′.

For example, the build-up layer L₁′ is disposed on the surface S52 of the dielectric layer 52 and electrically connected to the through vias 1001 by direct contact, so to be electrically coupled to components (such as transistors 300) included in the circuit wafers W1, W2 and W3(e.g., further through the interconnects 500 and/or the through vias 1002, 1003). In such case, the build-up layer L₂′ is disposed on the build-up layer L₁′ and electrically connected to the through vias 1001 through the build-up layer L₁′, so to be electrically coupled to components (such as transistors 300) included in the circuit wafers W1, W2 and W3 (e.g., further through the interconnects 500 and/or the through vias 1002, 1003). That is, the redistribution circuit structure 1500 provides the routing functions to the components (such as transistors 300) included in the circuit wafers W1, W2 and W3.

Continued on FIG. 15, in some embodiments, after forming the redistribution circuit structure 1500, a dielectric layer 1600, a dielectric layer 1700 and a plurality of conductive terminals 1800 are sequentially formed over the redistribution circuit structure 1500, where the conductive terminals 1800 are disposed over and electrically coupled to the redistribution circuit structure 1500. As shown in FIG. 15, the dielectric layer 1600 may be formed on the redistribution circuit structure 1500, and a plurality of second openings (not labeled) formed in and penetrating through the dielectric layer 1600 may accessibly reveal some of the redistribution circuit structure 1500 (e.g., the metallization layer ML₂′). The dielectric layer 1600 may be referred to as a passivation layer. In such cases, the dielectric layer 1700 is formed on the dielectric layer 1600, and a plurality of third openings (not labeled) formed in and penetrating through the dielectric layer 1700 accessibly reveal some of the redistribution circuit structure 1500 (e.g., the metallization layer ML₂′) accessibly revealed by the dielectric layer 1600. The dielectric layer 1700 may be referred to as a post-passivation layer. The dielectric layer 1600 may be or include a silicon oxide layer, a silicon nitride layer, a silicon oxy-nitride layer or a dielectric layer formed by other suitable dielectric materials, and may be formed by deposition, such as CVD (e.g., PECVD) or the like. The disclosure is not limited thereto. The dielectric layer 1700 may be or include a PI layer, a PBO layer, or a dielectric layer formed by other suitable polymers, and may be formed by spin-coating or deposition.

In alternative embodiments, the dielectric layer 1600 may be omitted. In addition to or alternatively, the dielectric layer 1700 may be omitted. The disclosure is not limited thereto.

In some embodiments, the conductive terminals 1800 each may include an under-ball metallurgy (UBM) pattern 1800u and a conductive element 1800c disposed thereon and electrically coupled thereto. As shown in FIG. 15, the conductive elements 1800c of the conductive terminals 1800 are electrically coupled to the redistribution circuit structure 1500 (e.g., the metallization layer ML₂′ accessibly revealed by the dielectric layers 1600 and 1700) through the UBM patterns 1800u of the conductive terminals 1800, for example. In the cases, the conductive terminals 1800 penetrate through the dielectric layer 1600 and the dielectric layer 1700 to electrically couple to the redistribution circuit structure 1500.

Each of the UBM patterns 1800u, for example, includes a metal layer, which may include a single layer or a composite layer comprising a plurality of sub-layers formed of different materials. The material of the UBM patterns 1800u may include copper, nickel, titanium, molybdenum, tungsten, titanium nitride, titanium tungsten, or alloys thereof or the like, and may be formed by an electroplating process, for example. For example, the UBM patterns 1800u each includes titanium layer and a copper layer over the titanium layer. In some embodiments, the UBM patterns 1800u are formed using, for example, sputtering, PVD, or the like. The shape and number of the UBM patterns 1800u are not limited in the disclosure. Each of the conductive elements 1800c, for example, includes micro-bumps, metal pillars, controlled collapse chip connection (C4) bumps (for example, which may have, but not limited to, a size of about 80 m), a ball grid array (BGA) bumps (for example, which may have, but not limited to, a size of about 400 m), electroless nickel-immersion gold technique (ENIG) formed bumps, electroless nickel-electroless palladium-immersion gold technique (ENEPIG) formed bumps, or the like. The disclosure is not limited thereto. The shape and number of the conductive terminals 1800 are not limited in the disclosure.

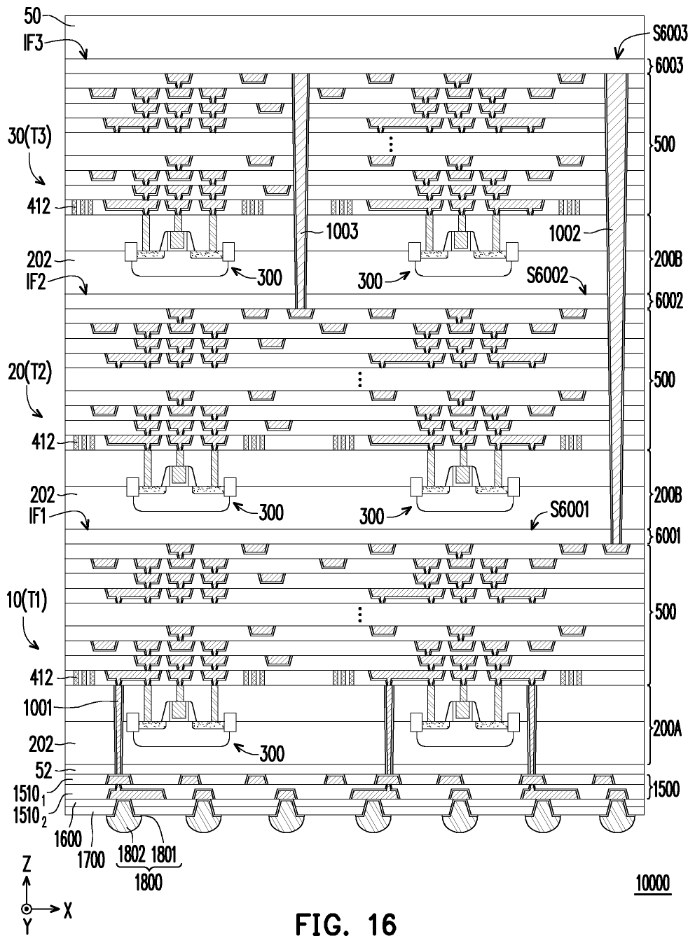

Referring to FIG. 16, in some embodiments, after forming the conductive terminals 1800, a dicing (singulation) process is performed to cut through the dielectric layer 1600, the dielectric layer 1700, the stacking structure (including the circuit wafers W1-W3) and the carrier 50 to form a plurality of stacking units 1000. In FIG. 16, only one stacking unit 1000 is shown for illustrative purposes and simplicity. The stacking units 1000 each may include the carrier 50, a semiconductor die 30 (e.g., a resultant from cutting through the circuit wafer W3) in the third tier T3 disposed over and thermally coupled to the carrier 50, a semiconductor die 20 (e.g., a resultant from cutting through the circuit wafer W2) in the second tier T2 disposed over and electrically coupled to the semiconductor die 30 in the third tier T3, a semiconductor die 10 (e.g., a resultant from cutting through the circuit wafer W1) in the first tier T1 disposed over and electrically coupled to the semiconductor die 20 in the second tier T2, the redistribution circuit structure 1500 disposed on and electrically coupled to the semiconductor die 10 in the first tier T1, the dielectric layer 1600 disposed on the redistribution circuit structure 1500, the dielectric layer 1700 disposed on the dielectric layer 1600, and the conductive terminals 1800 disposed over and electrically coupled to the redistribution circuit structure 1500 through the dielectric layers 1600 and 1700. For example, in the stacking unit 1000, a sidewall of the carrier 50, a sidewall of the semiconductor die 30, a sidewall of the semiconductor die 20, a sidewall of the semiconductor die 10, a sidewall of the redistribution circuit structure 1500, a sidewall of the dielectric layer 1600, and a sidewall of the dielectric layer 1700 are aligned to each other. That is, the sidewall of the carrier 50, the sidewall of the semiconductor die 30, the sidewall of the semiconductor die 20, the sidewall of the semiconductor die 10, the sidewall of the redistribution circuit structure 1500, the sidewall of the dielectric layer 1600, and the sidewall of the dielectric layer 1700 are together constitute a sidewall of the stacking unit 1000, as shown in FIG. 16. In one embodiment, the dicing (singulation) process is a wafer dicing process including mechanical blade sawing or laser cutting. The disclosure is not limited thereto.

In some embodiments, some of the conductive terminals 1800 are electrically coupled to the semiconductor die 10 through the redistribution circuit structure 1500 and the through vias 1001, some of the conductive terminals 1800 are electrically coupled to the semiconductor die 20 through the redistribution circuit structure 1500, the through vias 1001, the semiconductor die 10 and the through vias 1002, and some of the conductive terminals 1800 are electrically coupled to the semiconductor die 30 through the redistribution circuit structure 1500, the through vias 1001, the semiconductor die 10 and the through vias 1002. The disclosure is not limited thereto. In alternative embodiments, some of the conductive terminals 1800 are electrically coupled to the semiconductor die 10 through the redistribution circuit structure 1500 and the through vias 1001, some of the conductive terminals 1800 are electrically coupled to the semiconductor die 30 through the redistribution circuit structure 1500, the through vias 1001, the semiconductor die 10 and the through vias 1002, and some of the conductive terminals 1800 are electrically coupled to the semiconductor die 20 through the redistribution circuit structure 1500, the through vias 1001, the semiconductor die 10, the through vias 1002, the semiconductor die 130 and the through vias 1003.

Referring to FIG. 17, in some embodiments, a heat dissipating module is provided and coupled to the stacking unit 1000 to form the semiconductor device 10000A. In a non-limiting example, the heat dissipating module includes a lid 800 and a heat sink 900. As shown in FIG. 17, the lid 800 is disposed on (e.g., adhered to) the carrier 50 (e.g., at a surface S50 thereof) through a thermal adhesive 710 there-between, and the heat sink 900 is disposed on (e.g., adhered to) the lid 800 (e.g., at a surface S800 thereof) through a thermal adhesive 720 there-between, for example. That is, the lid 800 is thermally coupled to the stacking unit 1000 through the thermal adhesive 710, and the heat sink 900 is thermally coupled to the stacking unit 1000 through the thermal adhesive 720, the lid 800 and the thermal adhesive 710. Owing to the heat dissipating module (e.g., 800 and/or 900), the thermal dissipation of the semiconductor device 10000A is further improved. However, the disclosure is not limited thereto. In another non-limiting example, the heat dissipating module may include a lid 800 or a heat sink 900, only. In the embodiments of which the lid 800 is omitted, the heat sink 900 is thermally coupled to the stacking unit 1000 through the thermal adhesive 720 or 710. Or alternatively, the heat dissipating module can be omitted completely from the semiconductor device 10000A, if the thermal dissipation of the semiconductor device 10000A is well-controlled through the thermal control elements (e.g., 412) embedded therein.

For example, the thermal adhesives 710, 720 are independently made of a thermally conductive material or any material which is capable of transferring heat. The thermal adhesives 710, 720 independently may be any suitable adhesive, glue, epoxy, underfill, die attach film (DAF), thermal interface material (TIM), or the like. For example, the lid 800 and the heat sink 900 are independently made of a material having high thermal conductivity between about 200 W/(m·K) to about 400 W/(m·K) or more. The lid 800 and the heat sink 900 independently may be formed from a material with high thermal conductivity, such as steel, stainless steel, copper, the like, combinations thereof, or any material having good thermal conductivity for heat spreading mechanism. In some embodiments, the lid 800 and the heat sink 900 are independently coated with another metal. The lid 800 and the heat sink 900 independently may be a single contiguous material or may include multiple pieces having the same or different materials. The heat dissipating module in FIG. 17 is given for illustrative purposes, the lid 800 may be provided in any suitable form (e.g., a plate-form), while the heat sink 900 may be provided in any suitable form (a fin-form, etc.). The disclosure is not limited thereto.

In some embodiments, the semiconductor device 10000A include the thermal control elements (e.g., 412) in the local interconnect (formed in MEOL) of the interconnect (e.g., 500) included in each of the semiconductor dies (e.g., 10, 20, and/or 30), as shown in FIG. 17. However, the disclosure is not limited thereto. In alternative embodiments, one or more thermal control elements (e.g., 414) are further formed in the global interconnect (formed in BEOL) of the interconnect (e.g., 500) included in each of the semiconductor dies (e.g., 10, 20, and/or 30), see the semiconductor device 10000B of FIG. 18. The formation and material of the thermal control elements 414 are similar to or substantially identical to the formation and material of the thermal control elements 412 as previously discussed in conjunction with FIG. 37; and thus, are not repeated herein for brevity. In some embodiments, the thermal control elements 414 are electrically isolated from the interconnect 500 and the transistors 300 and thermally coupled to the interconnect 500 and the transistors 300.

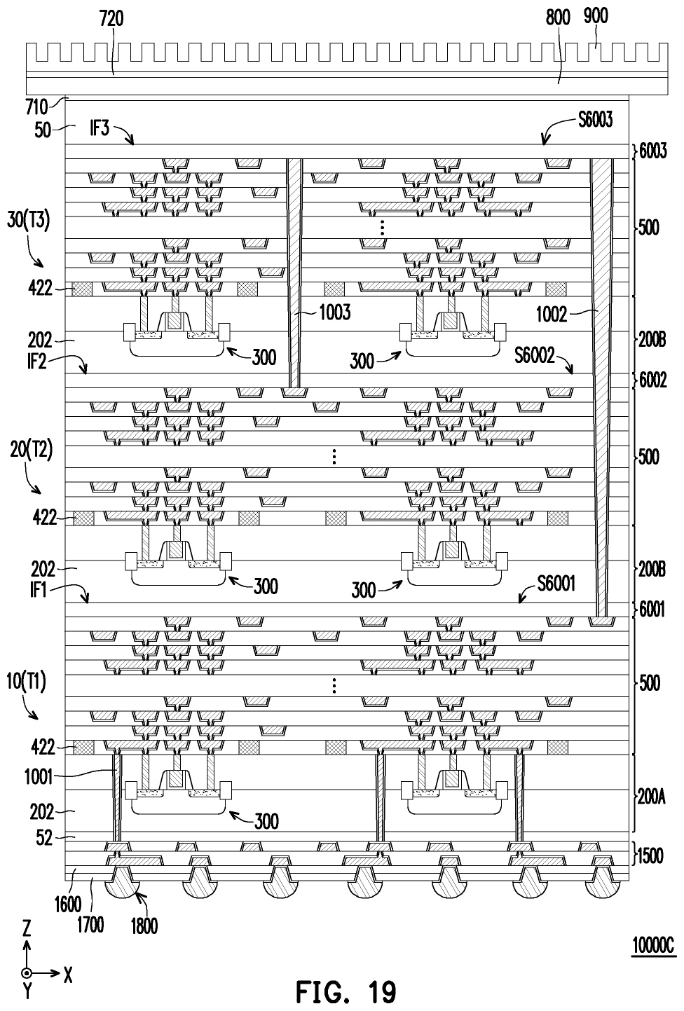

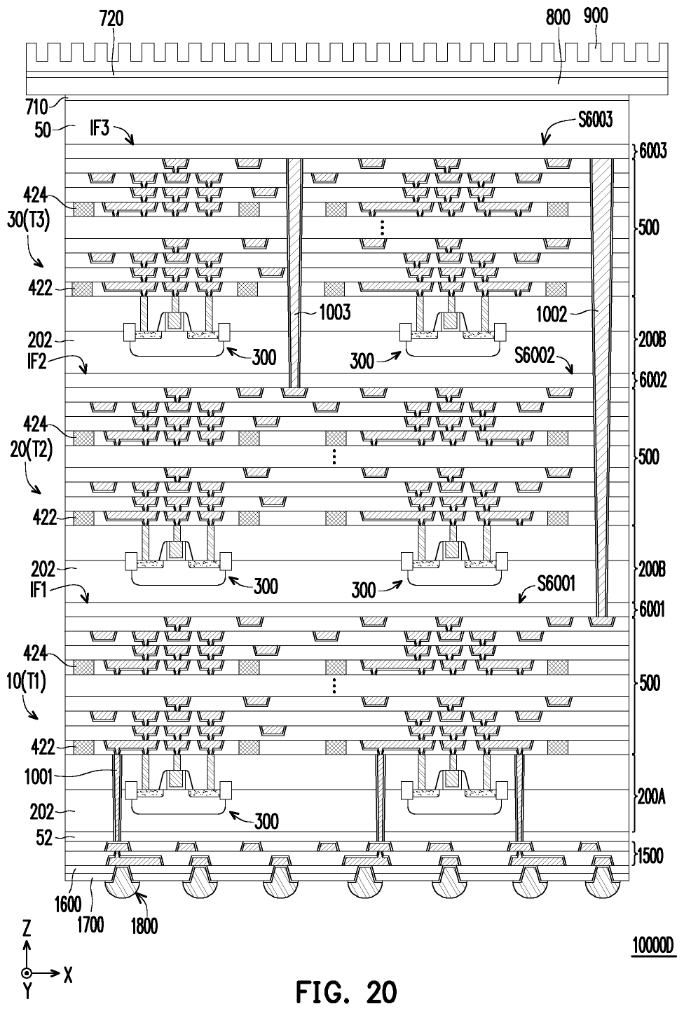

In some embodiments, the thermal control elements (e.g., 412) in the local interconnect (formed in MEOL) of the interconnect (e.g., 500) included in each of the semiconductor dies (e.g., 10, 20, and/or 30) are in a multi-pillar-form or a multi-columnar form, which are further arranged into a matrix, see FIGS. 17-18 in conjunction with FIG. 37. However, the disclosure is not limited thereto. In alternative embodiments, a plurality of thermal control elements (e.g., 422) may be adopted in the local interconnect (formed in MEOL) of the interconnect (e.g., 500) included in each of the semiconductor dies (e.g., 10, 20, and/or 30), see the semiconductor device 10000C of FIG. 19. In such case, the thermal control elements 422 are in a bulk or plate form having an opening enclosing the hotspot (e.g., 300), as shown in FIG. 38. As shown in FIG. 19, the semiconductor device 10000C include the thermal control elements (e.g., 422) in the local interconnect (formed in MEOL) of the interconnect (e.g., 500) included in each of the semiconductor dies (e.g., 10, 20, and/or 30). However, the disclosure is not limited thereto. In alternative embodiments, one or more thermal control elements (e.g., 424) are further formed in the global interconnect (formed in BEOL) of the interconnect (e.g., 500) included in each of the semiconductor dies (e.g., 10, 20, and/or 30), see the semiconductor device 10000D of FIG. 20. The formation and material of each of the thermal control elements 422 and 424 are similar to or substantially identical to the formation and material of each of the thermal control elements 412 and 414 as previously discussed in conjunction with FIG. 38, respectively; and thus, are not repeated herein for brevity. In some embodiments, the thermal control elements 422, 424 are electrically isolated from the interconnect 500 and the transistors 300 and thermally coupled to the interconnect 500 and the transistors 300.

In further alternative embodiments, a semiconductor device of the disclosure may adopt thermal control elements 412 and 422, 412 and 424, 414 and 422, or 414 and 424. The disclosure is not limited thereto.

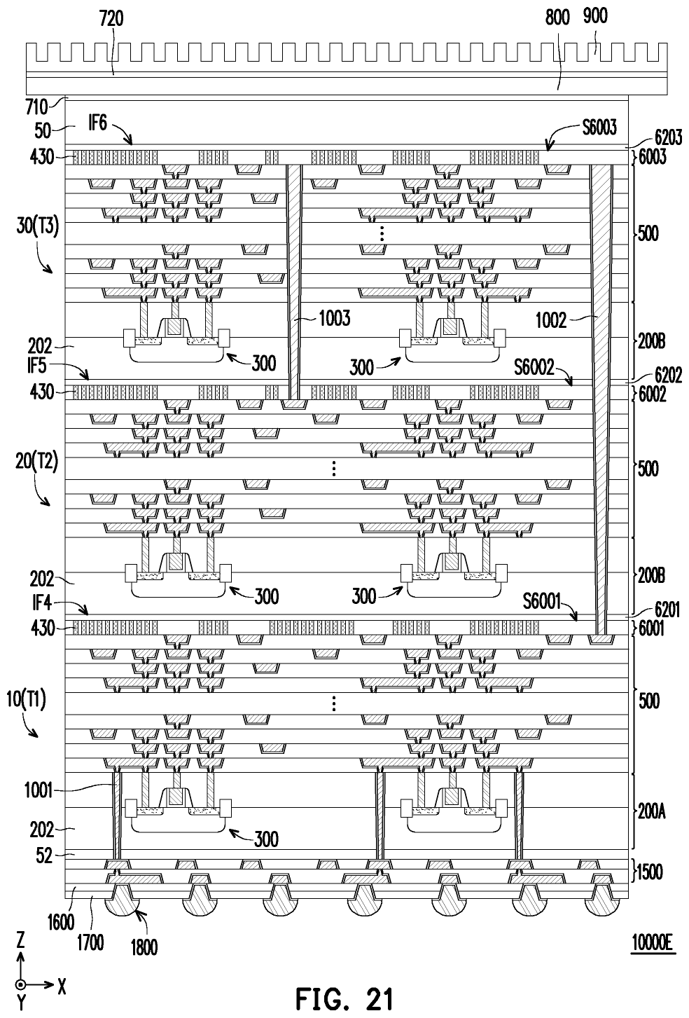

In some embodiments, a plurality of thermal control elements 430 are adopted to substitute the thermal control elements 412, 414, 422, and 424, see the semiconductor device 10000E of FIG. 21. In such case, after the formations of the dielectric layers 6001, 6002 and 6003, the thermal control elements 430 are formed in the dielectric layers 6001, 6002 and 6003, where the thermal control elements 430 are laterally covered by the respective one of the dielectric layers 6001, 6002 and 6003. Thereafter, a bonding layer 6201 is formed on the dielectric layer 6001 and the thermal control element 430 formed therein so to bond with the semiconductor substrate 202 of the second tier T2 by a bonding interface IF4, a bonding layer 6202 is formed on the dielectric layer 6002 and the thermal control element 430 formed therein so to bond with the semiconductor substrate 202 of the third tier T3 by a bonding interface IF5, and a bonding layer 6203 is formed on the dielectric layer 6003 and the thermal control element 430 formed therein so to bond with the carrier 50 by a bonding interface IF6. The bonding interface IF4, IF5 and IF6 independently includes a dielectric-to-dielectric bonding interface (such as a ‘oxide’-to-‘silicon’ bonding interface or a ‘nitride’-to-‘silicon’ bonding interface). The formation and material of the thermal control elements 430 are similar to or substantially identical to the formation and material of the thermal control elements 412 as previously discussed in conjunction with FIG. 37, and the formation and material of the bonding layers 6201-6203 are similar to or substantially identical to the formation and material of the dielectric layers 6001-6003 as previously discussed; and thus, are not repeated herein for brevity. In the embodiments of which the thermal control elements 430 are implemented, with the presence(s) of bonding layers 6201-6203, the bonding process can be more reliable due to the uniformity at the bonding surfaces. In some embodiments, the thermal control elements 430 are electrically isolated from the interconnect 500 and the transistors 300 and thermally coupled to the interconnect 500 (e.g., the metallization layer MLN is not in contact with the thermal control elements 430) and the transistors 300.

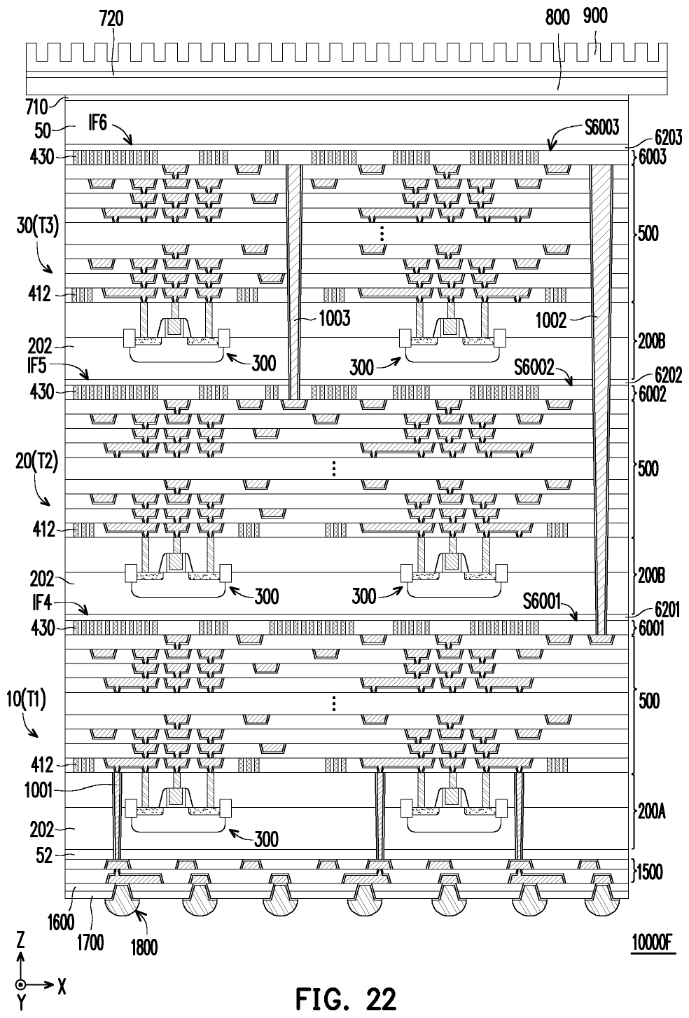

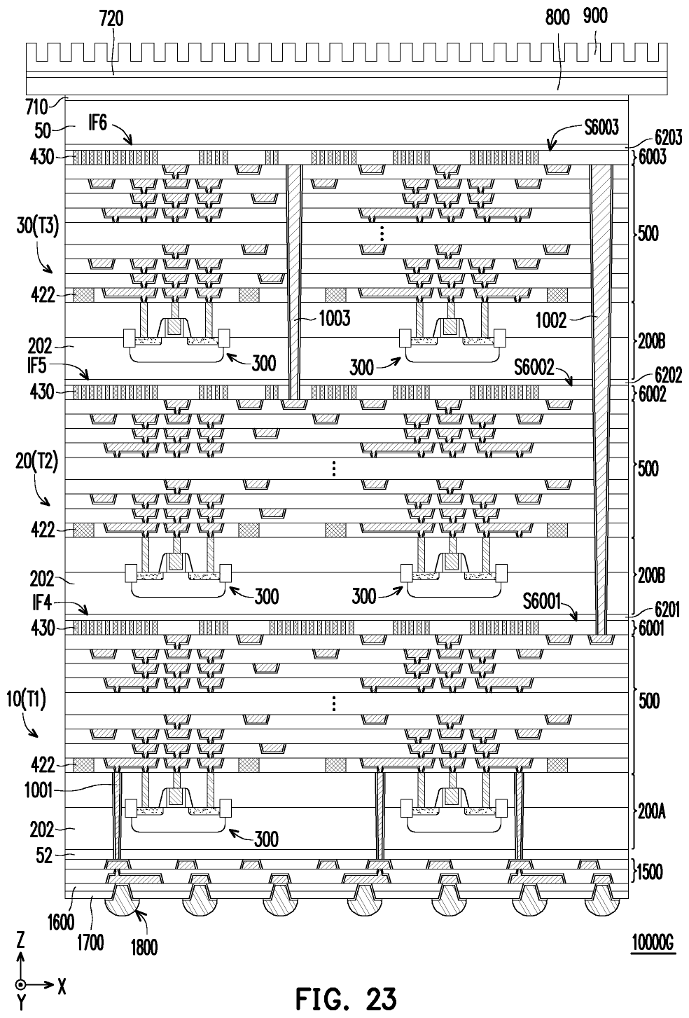

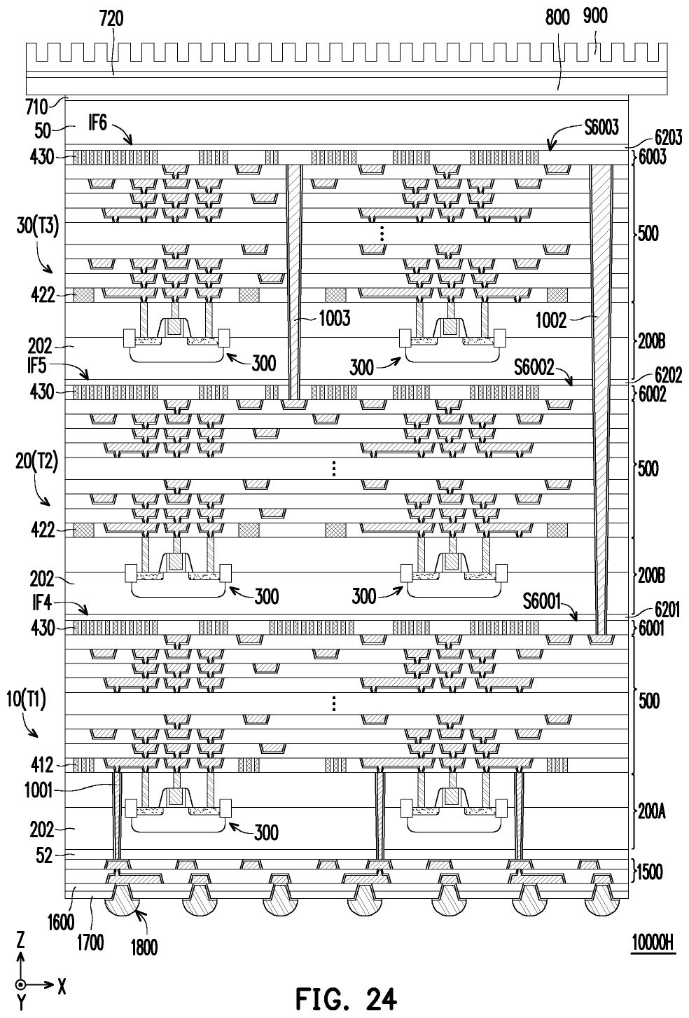

In further alternative embodiments, the thermal control elements 430 may be further adopted in addition to the thermal control elements 412 (see the semiconductor device 10000F of FIG. 22), in addition to the thermal control elements 412 and 414 (not shown), in addition to the thermal control elements 422 (see the semiconductor device 10000G of FIG. 23), in addition to the thermal control elements 422, 424 (not shown), in addition to the thermal control elements 412, 422 (see the semiconductor device 10000H of FIG. 24), in addition to the thermal control elements 412, 424 (not shown), in addition to the thermal control elements 414, 422 (not shown), in addition to the thermal control elements 414, 424 (not shown), in addition to the thermal control elements 412, 414, 422 (not shown), in addition to the thermal control elements 412, 414, 424 (not shown), in addition to the thermal control elements 412, 422, 424 (not shown), or in addition to the thermal control elements 414, 422, 424 (not shown).

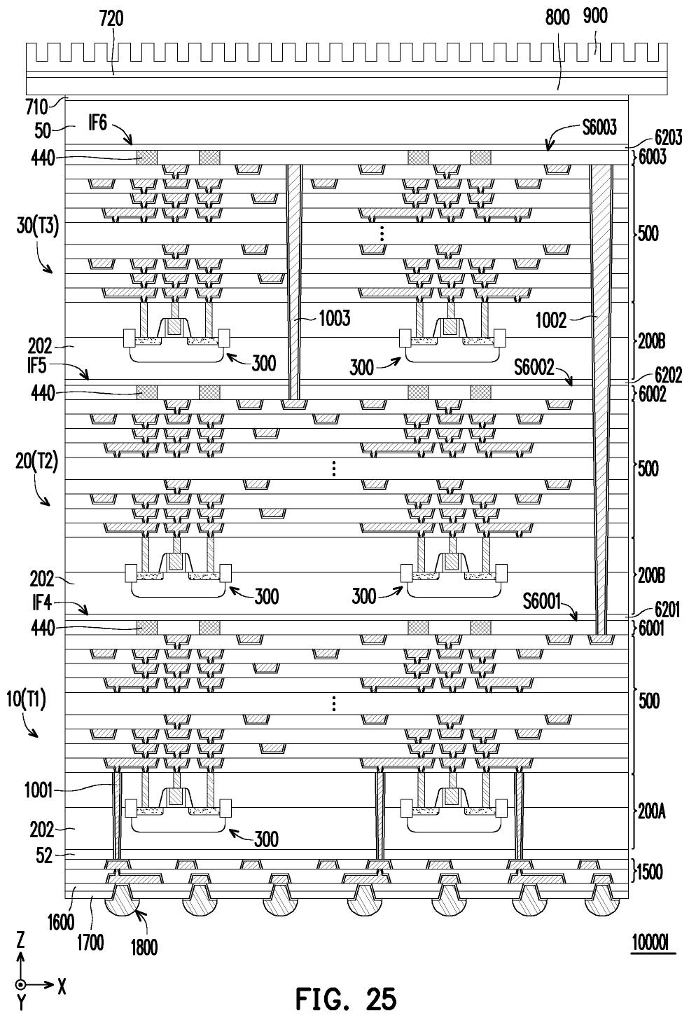

In some embodiments, a plurality of thermal control elements 440 are adopted to substitute the thermal control elements 412, 414, 422, and 424, see the semiconductor device 10000I of FIG. 25. In such case, after the formations of the dielectric layers 6001, 6002 and 6003, the thermal control elements 440 are formed in the dielectric layers 6001, 6002 and 6003, where the thermal control elements 440 are laterally covered by the respective one of the dielectric layers 6001, 6002 and 6003. Thereafter, a bonding layer 6201 is formed on the dielectric layer 6001 and the thermal control element 440 formed therein so to bond with the semiconductor substrate 202 of the second tier T2 by a bonding interface IF4, a bonding layer 6202 is formed on the dielectric layer 6002 and the thermal control element 440 formed therein so to bond with the semiconductor substrate 202 of the third tier T3 by a bonding interface IF5, and a bonding layer 6203 is formed on the dielectric layer 6003 and the thermal control element 440 formed therein so to bond with the carrier 50 by a bonding interface IF6. The bonding interface IF4, IF5 and IF6 independently includes a dielectric-to-dielectric bonding interface (such as a ‘oxide’-to-‘silicon’ bonding interface or a ‘nitride’-to-‘silicon’ bonding interface). The formation and material of the thermal control elements 440 are similar to or substantially identical to the formation and material of the thermal control elements 422 as previously discussed in conjunction with FIG. 38, and the formation and material of the bonding layers 6201-6203 are similar to or substantially identical to the formation and material of the dielectric layers 6001-6003 as previously discussed; and thus, are not repeated herein for brevity. In the embodiments of which the thermal control elements 440 are implemented, with the presence(s) of bonding layers 6201-6203, the bonding process can be more reliable due to the uniformity at the bonding surfaces. In some embodiments, the thermal control elements 440 are electrically isolated from the interconnect 500 and the transistors 300 and thermally coupled to the interconnect 500 (e.g., the metallization layer ML_{N} is not in contact with the thermal control elements 440) and the transistors 300.

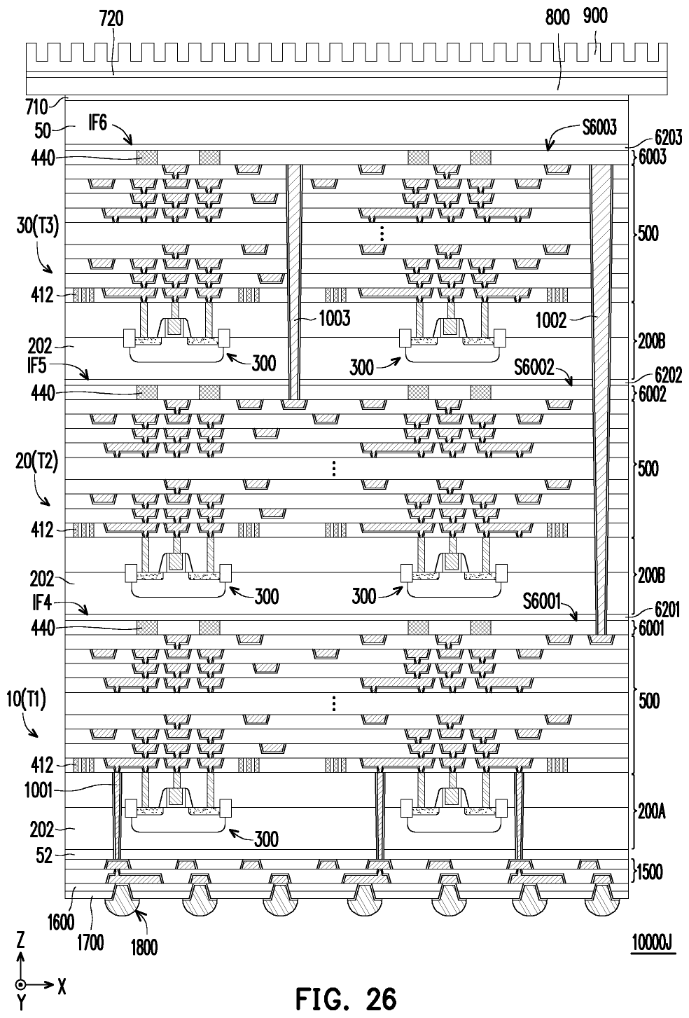

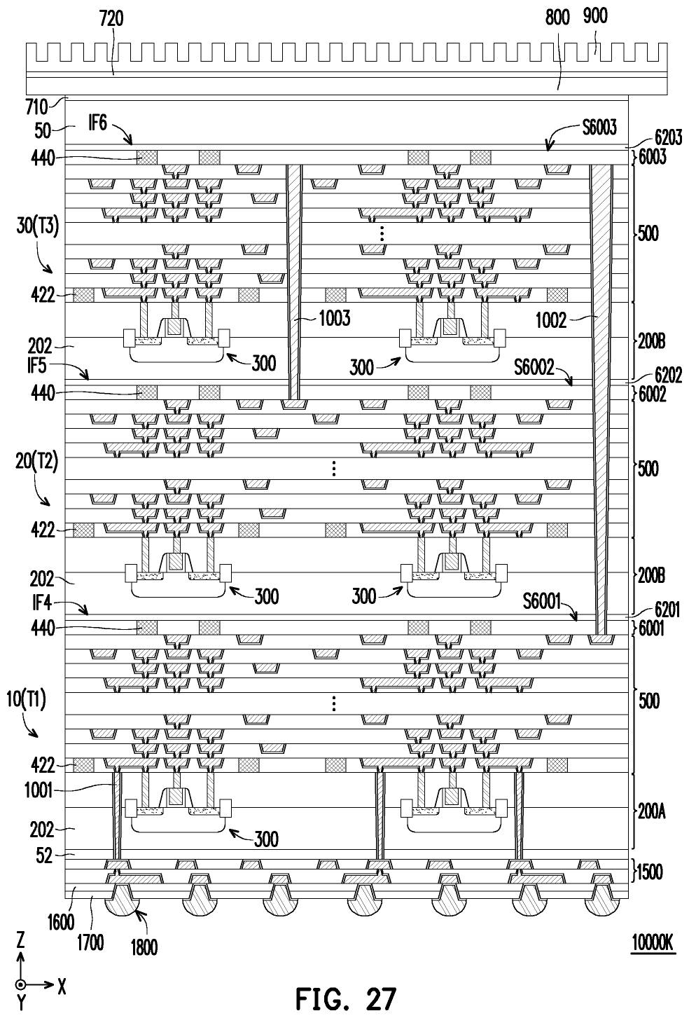

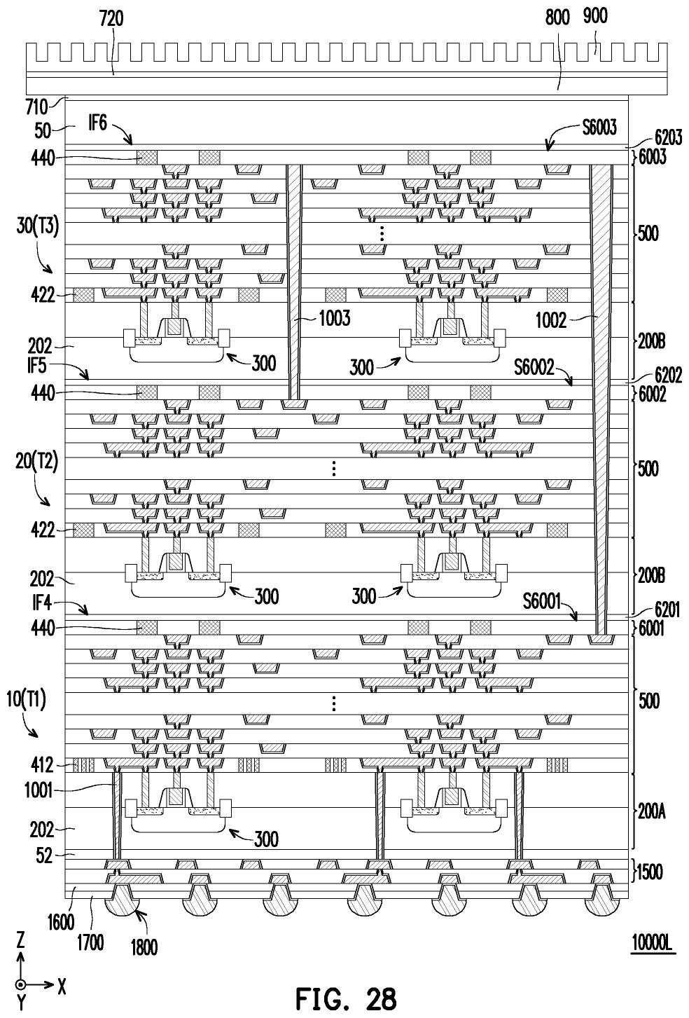

In further alternative embodiments, the thermal control elements 440 may be further adopted in addition to the thermal control elements 412 (see the semiconductor device 10000J of FIG. 26), in addition to the thermal control elements 412 and 414 (not shown), in addition to the thermal control elements 422 (see the semiconductor device 10000K of FIG. 27), in addition to the thermal control elements 422, 424 (not shown), in addition to the thermal control elements 412, 422 (see the semiconductor device 10000L of FIG. 28), in addition to the thermal control elements 412, 424 (not shown), in addition to the thermal control elements 414, 422 (not shown), in addition to the thermal control elements 414, 424 (not shown), in addition to the thermal control elements 412, 414, 422 (not shown), in addition to the thermal control elements 412, 414, 424 (not shown), in addition to the thermal control elements 412, 422, 424 (not shown), or in addition to the thermal control elements 414, 422, 424 (not shown).

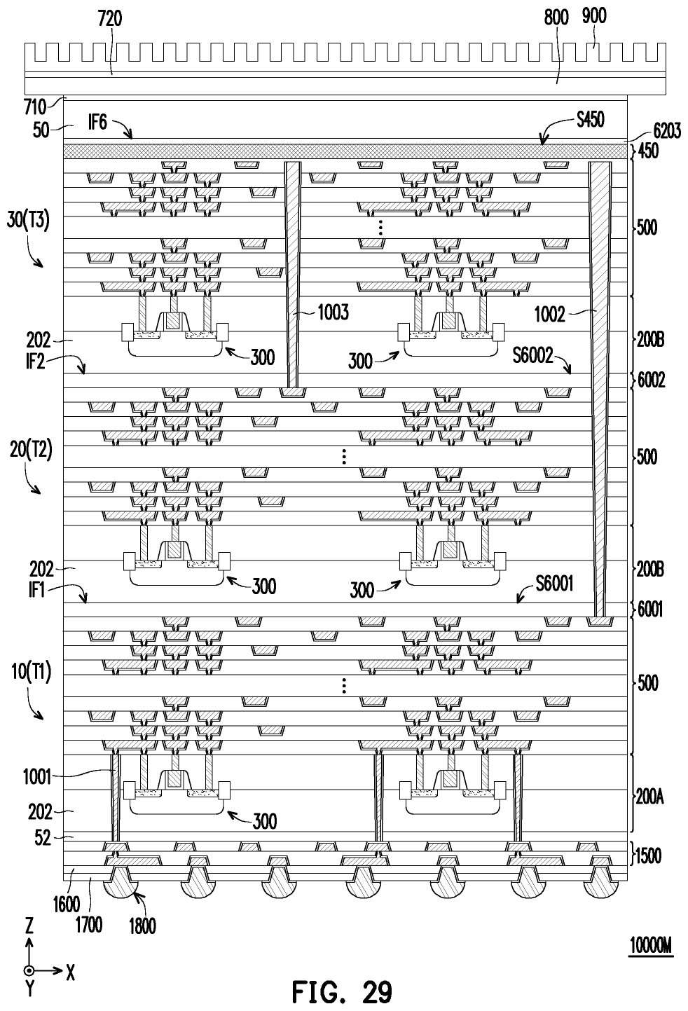

In some embodiments, one or more thermal control elements 450 are adopted to substitute the thermal control elements 412, 414, 422, and 424. In the embodiments of one or more thermal control elements 450 are implemented, the thermal control elements 450 are configured to respectively replace one or more dielectric layers 6001-6003. In such case, the thermal control elements 450 are in form of a continuous plate overlapping the hotspot (e.g., 300). For example, in the semiconductor device 10000M of FIG. 29, one thermal control element 450 is disposed on the illustrated top surface S500 of the interconnect 500 of the third tier T3 to replace the dielectric layer 6003. In such case, after the formations of the thermal control element 450, the bonding layer 6203 is formed on the thermal control elements 450 so to facilitate the following bonding process between the third tier T3 (e.g., the semiconductor die 30) and the carrier 50 with the bonding interface IF6. However, the disclosure is not limited thereto, alternatively, if only one thermal control element 450 is adopted, then any one of the dielectric layers 6001, 6002 and/or 6003 may be replaced. The number of the thermal control element 450 is not limited in the embodiments of the disclosure discussed above, which may be selected and designated based on the demand and/or product design requirements/layout to replace one, some or all of the dielectric layers 6001, 6002 and/or 6003, with forming respective one bonding layer(s) (e.g., 6201, 6202 and/or 620) thereon for facilitating the following bonding process between different tiers (e.g., T1-T3) or between the carrier (50) and the outermost tier (e.g., T3). The formation and material of the thermal control elements 450 are similar to or substantially identical to the formation and material of the thermal control elements 412 as previously discussed, and the formation and material of the bonding layers (e.g., 6201-6203) are similar to or substantially identical to the formation and material of the dielectric layers 6001-6003 as previously discussed; and thus, are not repeated herein for brevity. In the embodiments of which the thermal control elements 450 are implemented, with the presence(s) of bonding layers (e.g., 6201-6203), the bonding process can be more reliable due to the uniformity at the bonding surfaces. In some embodiments, the thermal control elements 450 are electrically isolated from the interconnect 500 and the transistors 300 and thermally coupled to the interconnect 500 (e.g., the metallization layer ML_{N} is not in contact with the thermal control elements 450) and the transistors 300.

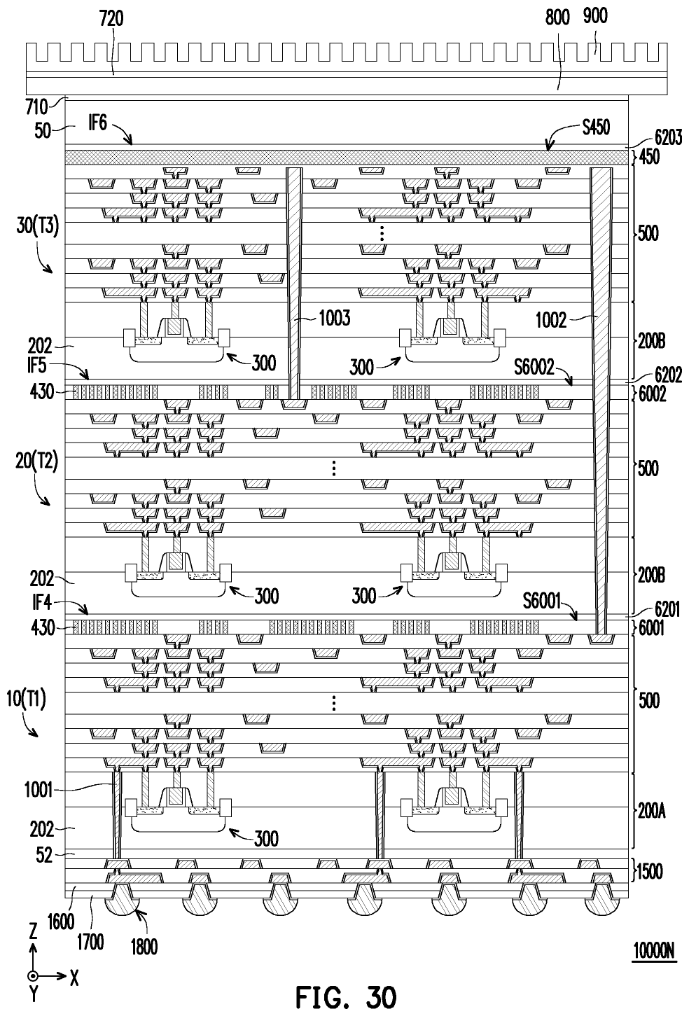

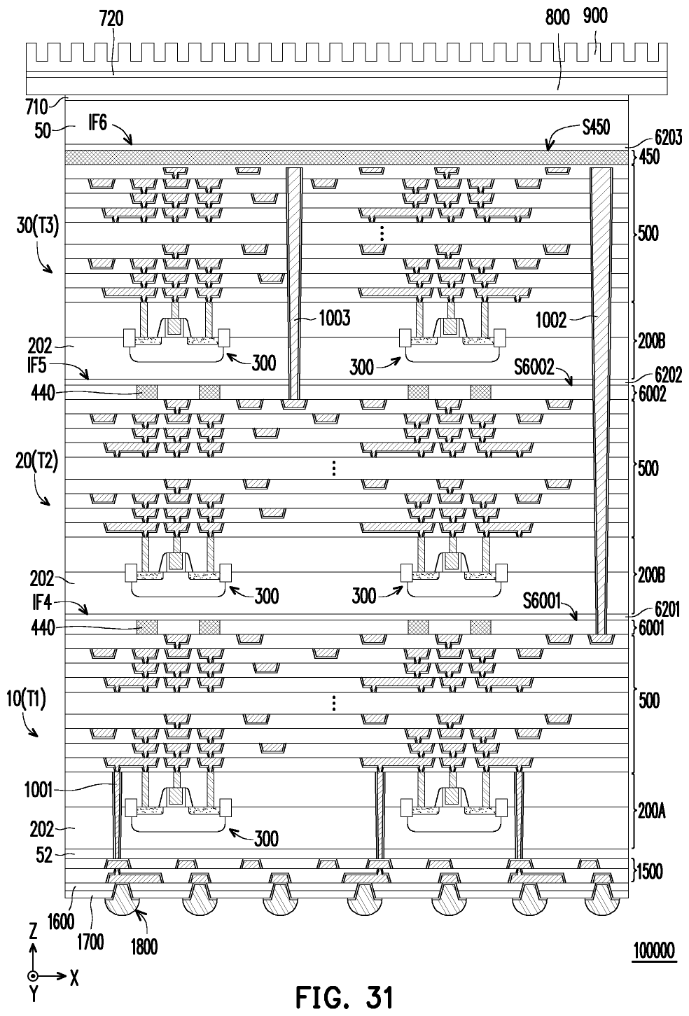

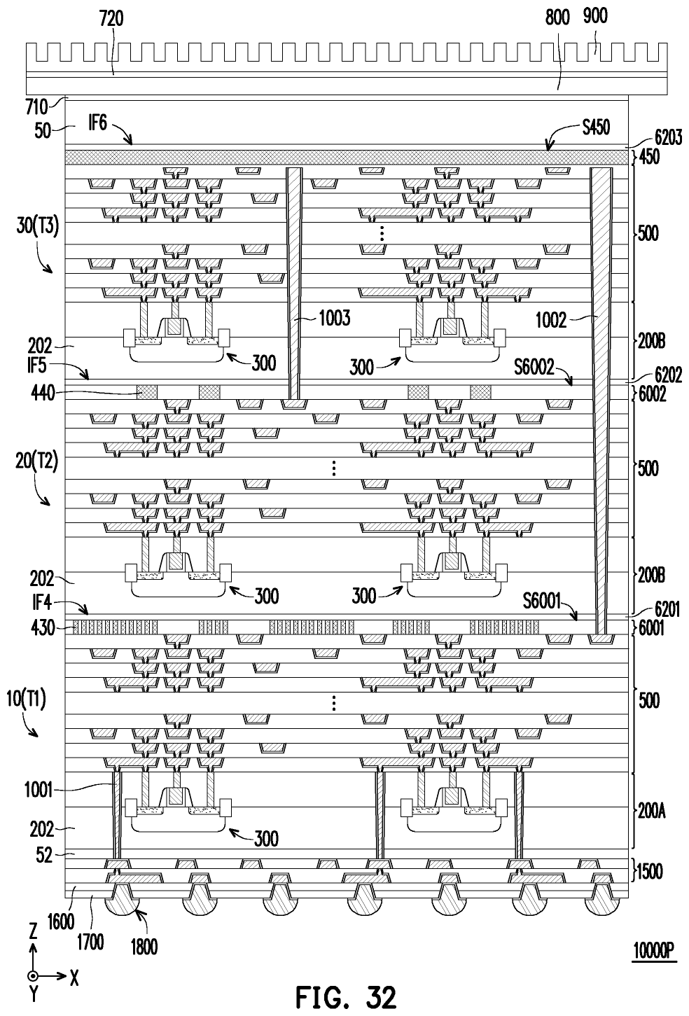

In alternative embodiments, in addition to the thermal control elements 412, 414, 422, and/or 424, at least one thermal control element 450 is further adopted in a semiconductor device of the disclosure. In further alternative embodiments, at least one thermal control element 450 may be further adopted in addition to the thermal control elements 430 without at least one of the thermal control elements 412, 414, 422, and/or 424 (see the semiconductor device 10000N of FIG. 30) or with at least one of the thermal control elements 412, 414, 422, and/or 424 (not shown), in addition to the thermal control elements 440 without at least one of the thermal control elements 412, 414, 422, and/or 424 (see the semiconductor device 100000 of FIG. 31) or with at least one of the thermal control elements 412, 414, 422, and/or 424 (not shown), or in addition to the thermal control elements 430 and 440 without at least one of the thermal control elements 412, 414, 422, and/or 424 (see the semiconductor device 10000P of FIG. 32) or with at least one of the thermal control elements 412, 414, 422, and/or 424 (not shown).

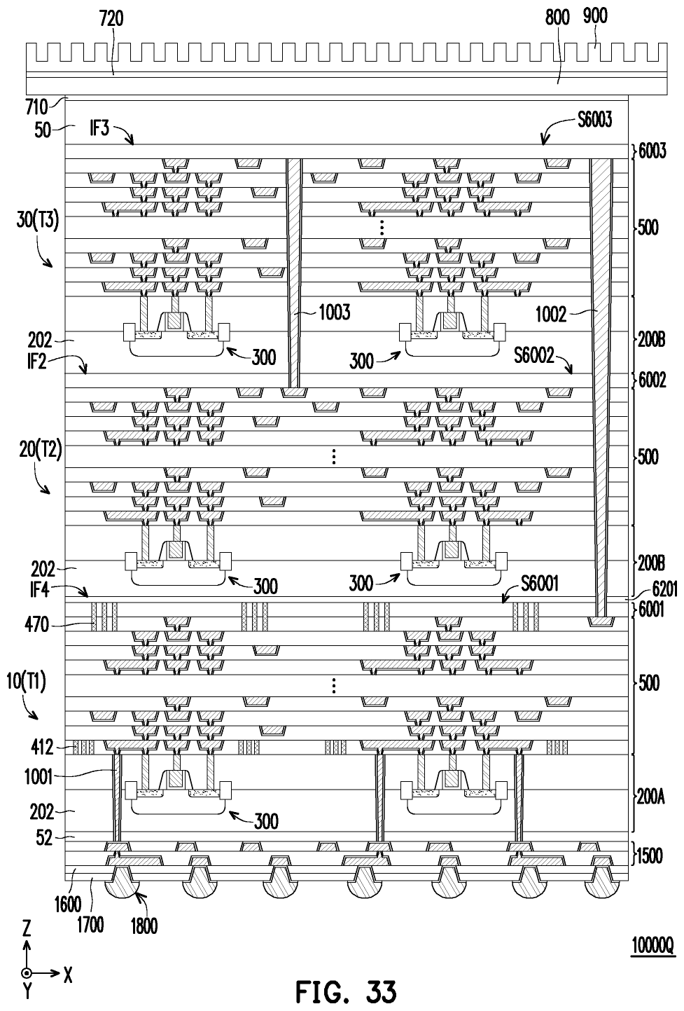

A plurality of thermal control elements 470 may be adopted in the semiconductor device of the disclosure, with or without in addition to the thermal control elements 412, 414, 422, 424, 430, 440, and/or 450. In some embodiments, the thermal control elements 470 are formed in the global interconnect (formed in BEOL) of an interconnect (e.g., 500) included in at least one semiconductor dies (e.g., 10, 20, and/or 30) and penetrating through at least two dielectric layers (e.g., 6001 and at least one of 510₁ to 510_{N} in a first tier T1, 6002 and at least one of 510₁ to 510_{N} in a second tier T2, and/or 6003 and at least one of 510₁ to 510_{N} in a third tier T3). The thermal control elements 470 are in a multi-pillar-form or a multi-columnar form, which are further arranged into a matrix, for example, as shown in FIGS. 33-34 and FIG. 37. After the formation of one of the dielectric layers 6001, 6002 and 6003, the thermal control elements 470 are formed in the respective one of the dielectric layers 6001, 6002 and 6003 and at least one dielectric layer(s) underlying thereto, the thermal control elements 470 are laterally covered by the respective one of the dielectric layers 6001, 6002 and 6003 and the at least one dielectric layer(s) underlying thereto. Thereafter, a bonding layer (e.g., 6201, 6202, and/or 6203) is formed on the respective one of the dielectric layers 6001, 6002 and 6003 and the thermal control element 470 so to bond with the semiconductor substrate 202 of the overlying tiers or the carrier 50 overlying thereto by a bonding interface (e.g., IF4, IF5 and/or IF6). The formation and material of the thermal control elements 470 are similar to or substantially identical to the formation and material of the thermal control elements 412 as previously discussed in conjunction with FIG. 37, and the formation and material of the bonding layers 6201-6203 are similar to or substantially identical to the formation and material of the dielectric layers 6001-6003 as previously discussed; and thus, are not repeated herein for brevity. In the embodiments of which the thermal control elements 470 are implemented, with the presence(s) of bonding layers 6201-6203, the bonding process can be more reliable due to the uniformity at the bonding surfaces. In some embodiments, the thermal control elements 470 are electrically isolated from the interconnect 500 and the transistors 300 and thermally coupled to the interconnect 500 and the transistors 300.

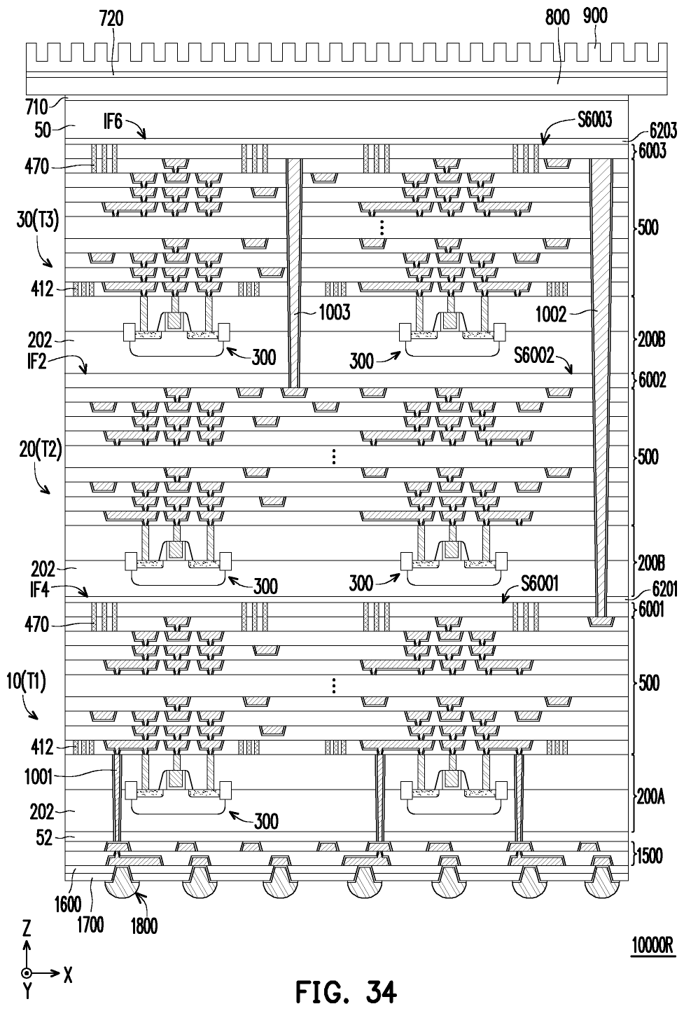

In a non-limiting example, the thermal control elements 470 are formed in the first tier T1 with the thermal control elements 412, see the semiconductor device 10000Q of FIG. 33. In another non-limiting example, the thermal control elements 470 are formed in the first tier T1 and the third tier T3 with the thermal control elements 412, see the semiconductor device 10000R of FIG. 34. However, the disclosure is not limited thereto, alternatively, the thermal control elements 470 may be formed in the first tier T1, the second tier T2 and/or the third tier T3 in addition to the thermal control elements 412 and 414, in addition to the thermal control elements 412 and 422, in addition to the thermal control elements 412 and 424, in addition to the thermal control elements 412, 414 and 422, in addition to the thermal control elements 412, 414 and 424, in addition to the thermal control elements 412, 414, 422 and 424, in addition to the thermal control elements 414, in addition to the thermal control elements 414 and 422, in addition to the thermal control elements 414 and 424, in addition to the thermal control elements 414, 422 and 424, in addition to the thermal control elements 422, in addition to the thermal control elements 422 and 424, or in addition to the thermal control elements 424. Or, the thermal control elements 470 may be formed in the first tier T1, the second tier T2 and/or the third tier T3 without the thermal control elements 412, 414, 422 and 424.

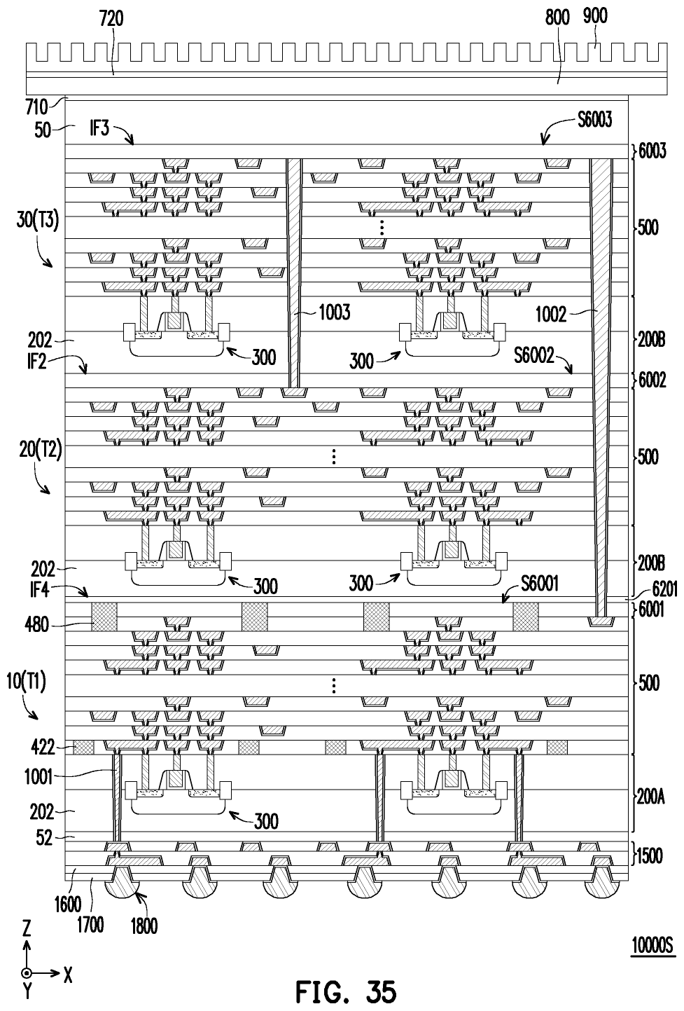

A plurality of thermal control elements 480 may be adopted in the semiconductor device of the disclosure, with or without in addition to the thermal control elements 412, 414, 422, 424, 430, 440, and/or 450. In some embodiments, the thermal control elements 480 are formed in the global interconnect (formed in BEOL) of an interconnect (e.g., 500) included in at least one semiconductor dies (e.g., 10, 20, and/or 30) and penetrating through at least two dielectric layers (e.g., 6001 and at least one of 510₁ to 510_{N} in a first tier T1, 6002 and at least one of 510₁ to 510_{N} in a second tier T2, and/or 6003 and at least one of 510₁ to 510_{N} in a third tier T3). The thermal control elements 480 are in form of a continuous plate overlapping the hotspot (e.g., 300), for example, as shown in FIGS. 35-36 and FIG. 38. After the formation of one of the dielectric layers 6001, 6002 and 6003, the thermal control elements 480 are formed in the respective one of the dielectric layers 6001, 6002 and 6003 and at least one dielectric layer(s) underlying thereto, the thermal control elements 480 are laterally covered by the respective one of the dielectric layers 6001, 6002 and 6003 and the at least one dielectric layer(s) underlying thereto. Thereafter, a bonding layer (e.g., 6201, 6202, and/or 6203) is formed on the respective one of the dielectric layers 6001, 6002 and 6003 and the thermal control element 480 so to bond with the semiconductor substrate 202 of the overlying tiers or the carrier 50 overlying thereto by a bonding interface (e.g., IF4, IF5 and/or IF6). The formation and material of the thermal control elements 480 are similar to or substantially identical to the formation and material of the thermal control elements 422 as previously discussed in conjunction with FIG. 38, and the formation and material of the bonding layers 6201-6203 are similar to or substantially identical to the formation and material of the dielectric layers 6001-6003 as previously discussed; and thus, are not repeated herein for brevity. In the embodiments of which the thermal control elements 480 are implemented, with the presence(s) of bonding layers 6201-6203, the bonding process can be more reliable due to the uniformity at the bonding surfaces. In some embodiments, the thermal control elements 480 are electrically isolated from the interconnect 500 and the transistors 300 and thermally coupled to the interconnect 500 and the transistors 300.

In alternative embodiments, some of the thermal control elements 470 may be replaced with the thermal control elements 480, or vice versa; therefore, the thermal control elements 470 and 480 can be co-existed in a single semiconductor device of the disclosure. In the above embodiments, for the semiconductor dies 10, 20 and 30, only one build-up layer (e.g., L₁) of the local interconnect included in each interconnect (e.g., 500) being with the thermal control elements 412/424 embedded therein and/or only one build-up layer (e.g., L_{N-3}) of the global interconnect included in each interconnect (e.g., 500) being with the thermal control elements 414/424 embedded therein are shown for illustrative purposes and simplicity, however the disclosure is not limited thereto. Alternatively, for the semiconductor dies 10, 20 and 30, one, more than one or all of the build-up layers of the local interconnect included in the interconnect (e.g., 500) may be with the thermal control elements 412/422 embedded therein; and/or, one, more than one or all of the build-up layers of the global interconnect included in the interconnect (e.g., 500) may be with the thermal control elements 414/424 embedded therein. In alternative embodiments, the thermal control elements 430 may be only formed in one or some of the dielectric layers 6001, 6002 and 6003, the disclosure is not limited thereto. In alternative embodiments, the thermal control elements 440 may be only formed in one or some of the dielectric layers 6001, 6002 and 6003, the disclosure is not limited thereto. The disclosure is not limited thereto.

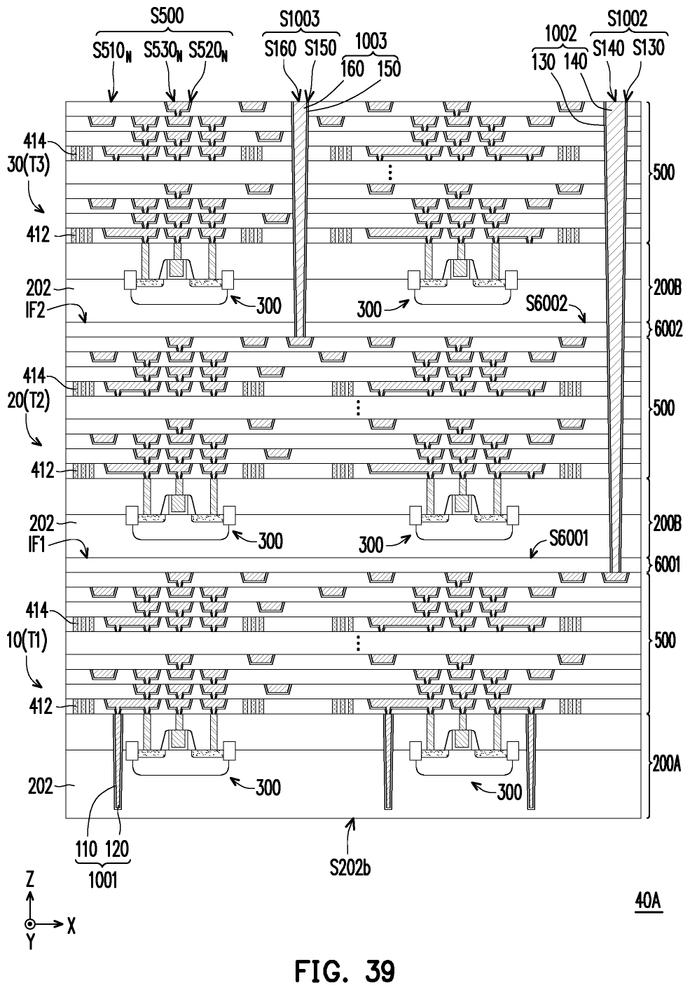

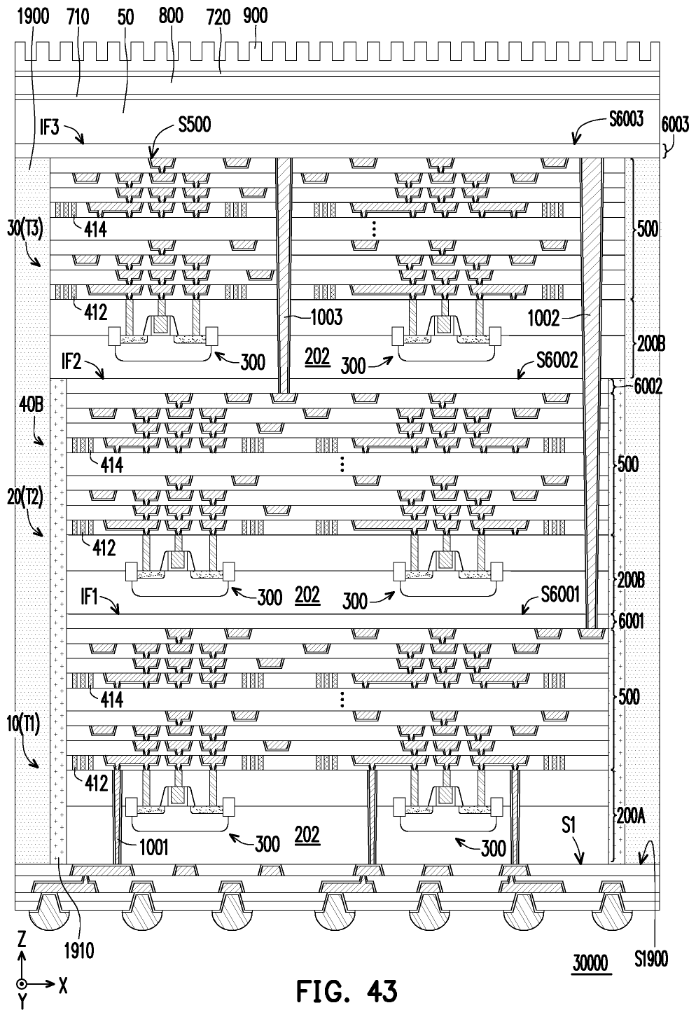

FIG. 39 to FIG. 42 are schematic cross-sectional views of various stages in a manufacturing method of a semiconductor device (e.g., 20000) in accordance with some embodiments of the disclosure. FIG. 43 through FIG. 46 are schematic cross-sectional views respectively showing a semiconductor device (e.g., 30000, 40000, 50000, or 60000) in accordance with alternative embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 39, in some embodiments, a dicing (singulation) process is performed on the structure depicted in FIG. 12 so to form a plurality of stacking units 40A, following the process as described in FIG. 12. In FIG. 39, only one stacking unit 40A is shown for illustrative purposes and simplicity. The stacking units 40A each may include a semiconductor die 30 (e.g., a resultant from cutting through the circuit wafer W3) in the third tier T3, a semiconductor die 20 (e.g., a resultant from cutting through the circuit wafer W2) in the second tier T2 disposed over and electrically coupled to the semiconductor die 30 in the third tier T3, and a semiconductor die 10 (e.g., a resultant from cutting through the circuit wafer W1) in the first tier T1 disposed over and electrically coupled to the semiconductor die 20 in the second tier T2. For example, in the stacking unit 40A, a sidewall of the semiconductor die 30, a sidewall of the semiconductor die 20, and a sidewall of the semiconductor die 10 are aligned to each other. That is, the sidewall of the semiconductor die 30, the sidewall of the semiconductor die 20, and the sidewall of the semiconductor die 10 are together constitute a sidewall of the stacking unit 40A, as shown in FIG. 39. In one embodiment, the dicing (singulation) process is a wafer dicing process including mechanical blade sawing or laser cutting. The disclosure is not limited thereto.

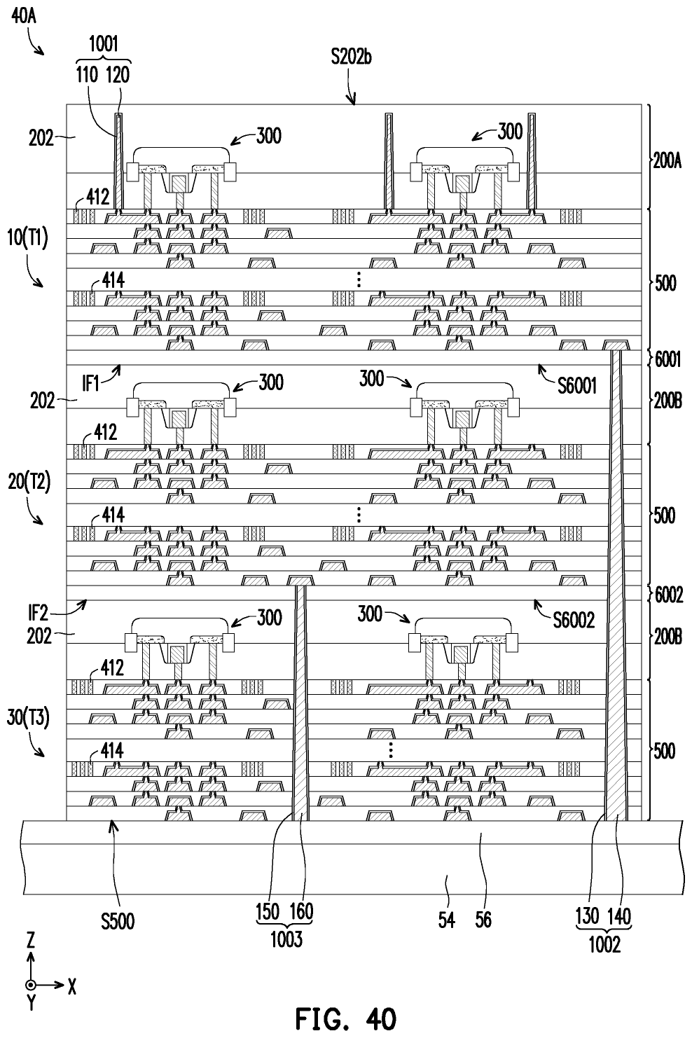

Referring to FIG. 40, in some embodiments, in some embodiments, a carrier substrate 54 is provided, and a release layer 56 is formed on the carrier substrate 54. The carrier substrate 54 may be a glass carrier substrate, a ceramic carrier substrate, or the like. The carrier substrate 54 may be a wafer, such that multiple packages can be formed on the carrier substrate 54 simultaneously. The release layer 56 may be formed of a polymer-based material, which may be removed along with the carrier substrate 54 from the overlying structures that will be formed in subsequent steps. In some embodiments, the release layer 56 is an epoxy-based thermal-release material, which loses its adhesive property when heated, such as a light-to-heat-conversion (LTHC) release coating. In other embodiments, the release layer 56 may be an ultra-violet (UV) glue, which loses its adhesive property when exposed to UV lights. The release layer 56 may be dispensed as a liquid and cured, may be a laminate film laminated onto the carrier substrate 54, or may be the like. The top surface of the release layer 56 may be leveled.

In some embodiments, at least one stacking unit 40A is picked and placed on the release layer 56 and over the carrier substrate 54. As shown in FIG. 40, only one stacking unit 40A is presented as the at least one stacking unit 40A for illustrative purposes, however, it should be noted that the number of the at least one stacking unit 40A may be one, two, three, or more than three, the disclosure is not limited thereto. For example, the illustrated top surface S500 of the interconnect 500 included in the third tier T3 is placed on (e.g., in physical contact with) the release layer 56. As shown in FIG. 40, the surface S202b of the semiconductor substrate 202 included in the first tier T1 may face upwards.

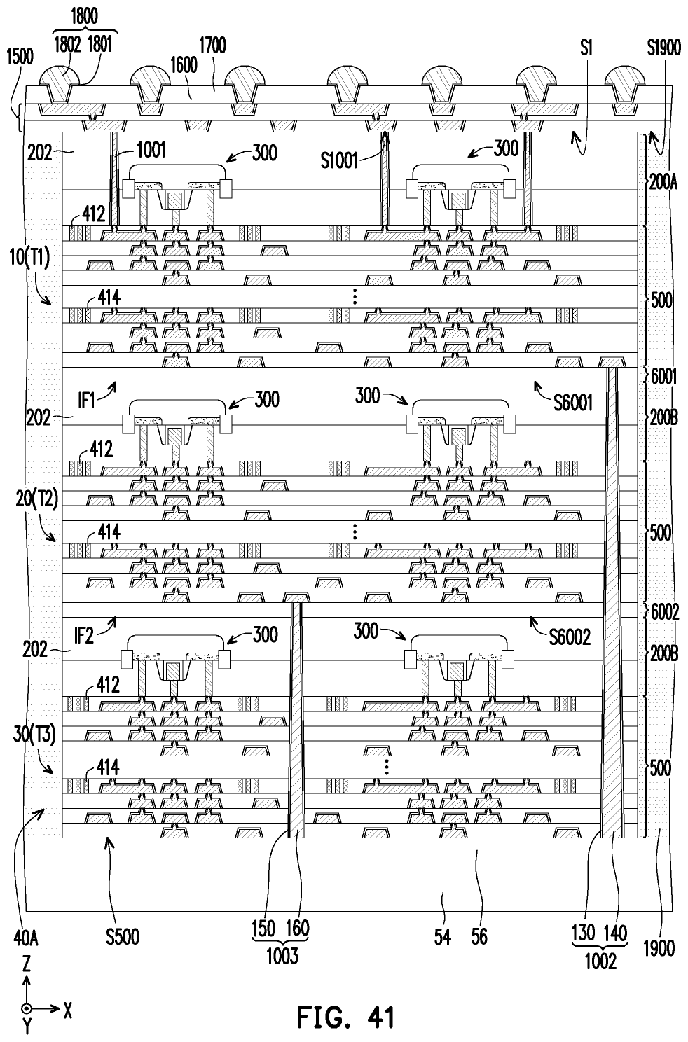

Referring to FIG. 41, in some embodiments, the stacking unit 40A is encapsulated in an insulating material. In some embodiments, an insulating encapsulation material (not shown) is formed on the stacking unit 40A and the release layer 56 over the carrier substrate 54, where the stacking unit 40A and the release layer 56 exposed by the stacking unit 40A are completely covered by the insulating encapsulation material. The insulating encapsulation material may be made of a dielectric material (such as an oxide (e.g., silicon oxide), a nitride (e.g., silicon nitride), tetra-ethyl-ortho-silicate (TEOS), or the like) or any suitable insulating materials for gap fill, and may be formed by deposition (such as a CVD process). Alternatively, the insulating encapsulation material may be a molding compound, a molding underfill, a resin (such as epoxy-based resin), or the like, which may be formed by a molding process. The molding process may include a compression molding process or a transfer molding process. The insulating encapsulation material may include polymers (such as epoxy resins, phenolic resins, silicon-containing resins, or other suitable resins) or other suitable materials. Alternatively, the insulating encapsulation material may include an acceptable insulating encapsulation material. In some embodiments, the insulating encapsulation material further includes inorganic filler or inorganic compound (e.g., silica, clay, and so on) which can be added therein to optimize coefficient of thermal expansion (CTE) of the insulating encapsulation material. The disclosure is not limited thereto.

After forming the insulating encapsulation material, a planarization process is performed on the insulating encapsulation material to form an insulating encapsulation 1900 exposing the stacking unit 40A. For example, a portion of the insulating encapsulation material is removed to form the insulating encapsulation 1900 having an illustrated top surface S1900, where the illustrated top surface S1900 of the insulating encapsulation 1900 accessibly reveals the first tier T1 (e.g., a surface Si of the semiconductor substrate 202 and the surface S1001 of the through vias 1001 exposed by the surface Si, included in the first tier T1 of the semiconductor die 10). For example, the illustrated top surface S1900 of the insulating encapsulation 1900 is substantially level with the surface Si of the semiconductor substrate 202 and the surface S1001 of the through vias 1001 included in the first tier T1 of the stacking unit 40A. In other words, the illustrated top surface S1900 of the insulating encapsulation 1900 is substantially coplanar to the surface Si of the semiconductor substrate 202 and the surface S1001 of the through vias 1001 included in the first tier T1 of the stacking unit 40A.

In some embodiments, after the planarization process, a cleaning step may be optionally performed to clean and remove the residue generated from the planarization process. However, the disclosure is not limited thereto, and the planarization process may be performed through any other suitable method. In addition, during the planarization process, a portion of each of the semiconductor substrate 202 and the through vias 1001 in the first tier T1 of the stacking unit 40A may also be slightly removed. The disclosure is not limited thereto. As shown in FIG. 41, the stacking unit 40A may be laterally encapsulated in the insulating encapsulation 1900.

Still referring to FIG. 41, in some embodiments, after the formation of the insulating encapsulation 1900, an interconnect 1500, a dielectric layer 1600, a dielectric layer 1700 and a plurality of conductive terminals 1800 are sequentially formed over the insulating encapsulation 1900 and the stacking unit 40A laterally encapsulated in the insulating encapsulation 1900. The details, formation and materials of the interconnect 1500, the dielectric layer 1600, the dielectric layer 1700 and the plurality of conductive terminals 1800 have been discussed in FIG. 15, and thus are not repeated herein for brevity.

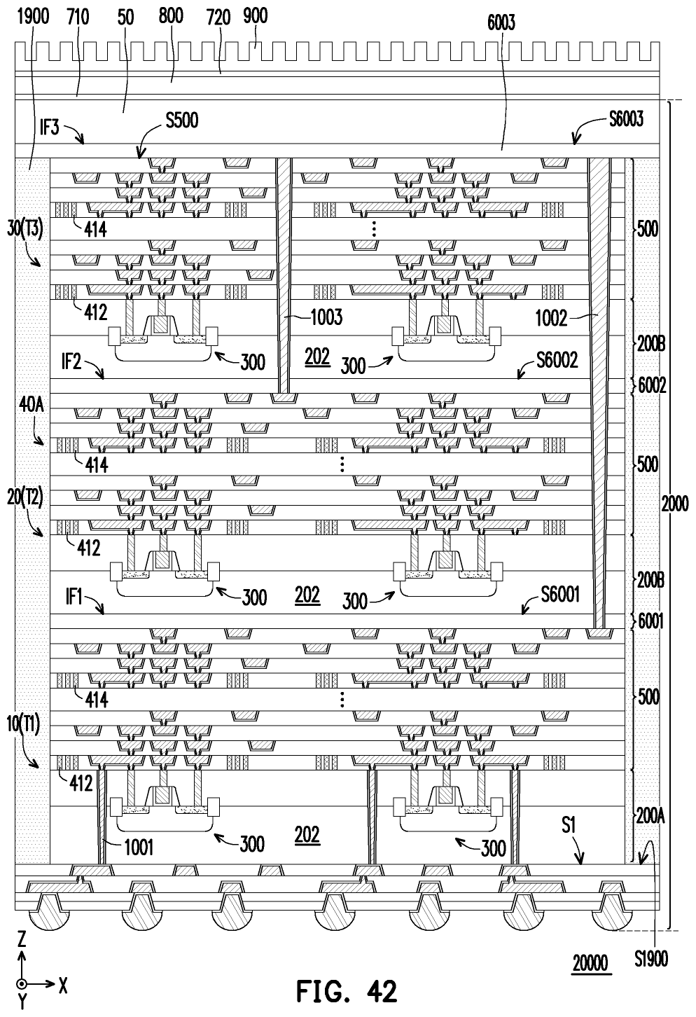

Referring to FIG. 42, in some embodiments, the carrier substrate 54 is removed. The carrier substrate 54 may be detached (or “de-bonded”) from the insulating encapsulation 1900 and the stacking unit 40A laterally encapsulated in the insulating encapsulation 1900. In some embodiments, the de-bonding includes projecting a light such as a laser light or an UV light on the release layer 56 so that the release layer 56 decomposes under the heat of the light and the carrier substrate 54 can be removed. The de-bonding accessibly exposes the insulating encapsulation 1900 and the stacking unit 40A (e.g., the surface S500 of the interconnect 500 included in the third tier T3) laterally encapsulated in the insulating encapsulation 1900, for example.

In some embodiments, after removing the carrier substrate 54 and release layer 56, a dielectric layer 6003 and a carrier 50 are sequentially formed over the insulating encapsulation 1900 and the stacking unit 40A laterally encapsulated in the insulating encapsulation 1900. The dielectric layer 6003 continuously extends from the stacking unit 40A to the insulating encapsulation 1900, and the carrier 50 completely covers the dielectric layer 6003, for example. As shown in FIG. 42, the carrier 50 may be bonded to the surface S6003 of the dielectric layer 6003 by the bonding interface IF3. The details, formation and materials of the dielectric layer 6003 and the carrier 50 have been discussed in FIG. 13, and thus are not repeated herein for brevity.

Still referring to FIG. 42, a dicing (singulation) process is performed to cut through the carrier 50, the dielectric layer 6003, the insulating encapsulation 1900, the redistribution circuit structure 1500, the dielectric layer 1600, the dielectric layer 1700 to form a plurality of stacking units 2000. In FIG. 42, only one stacking unit 2000 is shown for illustrative purposes and simplicity. The stacking units 2000 each may include the carrier 50, the stacking unit 40A (including a semiconductor die 30 in the third tier T3 disposed over and thermally coupled to the carrier 50, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2), the redistribution circuit structure 1500 disposed on and electrically coupled to the semiconductor die 10 in the first tier T1, the dielectric layer 1600 disposed on the redistribution circuit structure 1500, the dielectric layer 1700 disposed on the dielectric layer 1600, and the conductive terminals 1800 disposed over and electrically coupled to the redistribution circuit structure 1500 through the dielectric layers 1600 and 1700. For example, in the stacking unit 2000, a sidewall of the carrier 50, the sidewall of the dielectric layer 6003, a sidewall of the insulating encapsulation 1900, a sidewall of the redistribution circuit structure 1500, a sidewall of the dielectric layer 1600, and a sidewall of the dielectric layer 1700 are aligned to each other. That is, the sidewall of the carrier 50, the sidewall of the dielectric layer 6003, the sidewall of the insulating encapsulation 1900, the sidewall of the redistribution circuit structure 1500, the sidewall of the dielectric layer 1600, and the sidewall of the dielectric layer 1700 are together constitute a sidewall of the stacking unit 2000, as shown in FIG. 42. In one embodiment, the dicing (singulation) process is a wafer dicing process including mechanical blade sawing or laser cutting. The disclosure is not limited thereto.

Thereafter, a heat dissipating module may be sequentially formed onto the carrier 50. The lid 800 is disposed on (e.g., adhered to) the carrier 50 through a thermal adhesive 710 there-between, and the heat sink 900 is disposed on (e.g., adhered to) the lid 800 through a thermal adhesive 720 there-between, for example. The details, formation and materials of the thermal adhesive 710, the lid 800, the thermal adhesive 720 and the heat sink 900 are sequentially formed over the insulating encapsulation 1900 have been discussed in FIG. 16; and thus, are not repeated herein for brevity. Up to there, the semiconductor device 20000 is manufactured. For example, in the semiconductor device 20000, a sidewall of the heat sink 900, a sidewall of the thermal adhesive 720, a sidewall of the lid 800, a sidewall of the thermal adhesive 710, and a sidewall of the stacking unit 2000 are aligned to each other. That is, the sidewall of the heat sink 900, the sidewall of the thermal adhesive 720, the sidewall of the lid 800, the sidewall of the thermal adhesive 710, and the sidewall of the stacking unit 2000 are together constitute a sidewall of the semiconductor device 20000, as shown in FIG. 42. In one embodiment, the dicing (singulation) process is a wafer dicing process including mechanical blade sawing or laser cutting. The disclosure is not limited thereto. However, the disclosure is not limited thereto, in alternative embodiments, the sidewall of the heat sink 900, the sidewall of the thermal adhesive 720, the sidewall of the lid 800, and/or the sidewall of the thermal adhesive 710 are not aligned with the sidewall of the stacking unit 2000.

In some embodiments, the semiconductor device 30000 of FIG. 43 is similar to the semiconductor device 20000 of FIG. 42, and the difference is that the stacking unit 40A is replaced with a stacking unit 40B. As shown in FIG. 43, the stacking unit 40B may include a semiconductor die 30 in the third tier T3, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2, and an insulating encapsulation 1910 laterally encapsulating the semiconductor dies 10 and 20. For example, in the stacking unit 40B, a sidewall of the insulating encapsulation 1910 and a sidewall of the semiconductor die 30 are aligned to each other. That is, the sidewall of the insulating encapsulation 1910 and the sidewall of the semiconductor die 30 are together constitute a sidewall of the stacking unit 40B. In one non-limiting example, at least one through via 1002 penetrates through the semiconductor dies 20 and 30 to be in contact with the semiconductor dies 10, 20 and 30 for providing proper electrical connection between the semiconductor dies 10, 20 and 30, and at least one through via 1003 penetrates through the semiconductor die 30 to be in contact with the semiconductor die 20 for providing proper electrical connection between the semiconductor dies 20 and 30, as shown in FIG. 43.

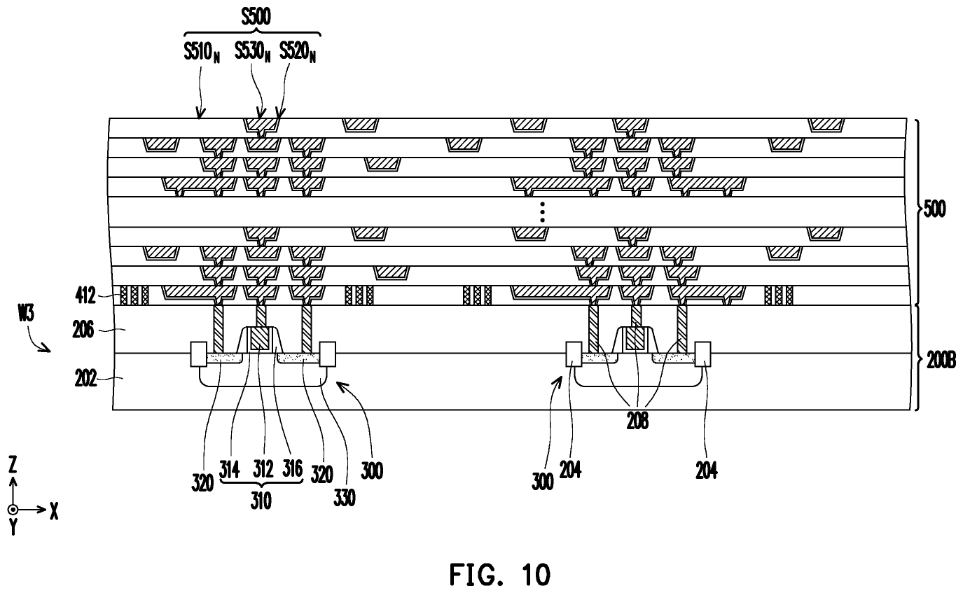

The stacking unit 40B may be formed by, but not limited to, providing a circuit wafer W1 and a circuit wafer W2 (similar to the processes of FIGS. 1-7 and FIG. 8, respectively); bonding the circuit wafer W1 and the circuit wafer W2 by WoW bonding (similar to the process of FIG. 9); performing a dicing process on the bonded structure of the circuit wafer W1 and the circuit wafer W2 to form a plurality of separate and individual bonded structures of semiconductor dies 10 and 20 (similar to the process of FIG. 16 or FIG. 39); providing a circuit wafer W3 (similar to the processes of FIG. 10); bonding the bonded structure of the semiconductor dies 10 and 20 to the circuit wafer W3 by a chip-on-wafer (CoW) process; laterally encapsulating the bonded structure of the semiconductor dies 10 and 20 in the insulating encapsulation 1910 (similar to the processes of FIG. 41); forming at least one through via 1002 and at least one through via 1003 (similar to the process of FIG. 12); and performing another dicing process on the insulating encapsulation 1910 and the circuit wafer W3 to form a plurality of separate and individual stacking units 40B (similar to the process of FIG. 16 or FIG. 39).

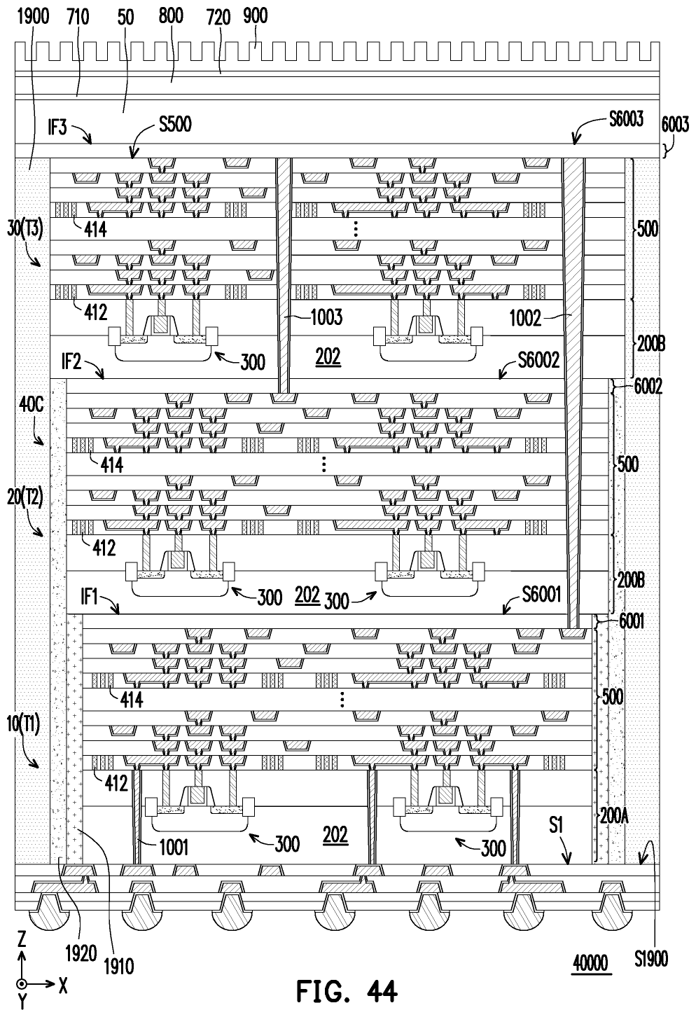

In some embodiments, the semiconductor device 40000 of FIG. 44 is similar to the semiconductor device 20000 of FIG. 42, and the difference is that the stacking unit 40A is replaced with a stacking unit 40C. As shown in FIG. 44, the stacking unit 40C may include a semiconductor die 30 in the third tier T3, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2, an insulating encapsulation 1910 laterally encapsulating the semiconductor die 10, and an insulating encapsulation 1920 laterally encapsulating the semiconductor die 20 and the insulating encapsulation 1910. For example, in the stacking unit 40C, a sidewall of the insulating encapsulation 1920 and a sidewall of the semiconductor die 30 are aligned to each other. That is, the sidewall of the insulating encapsulation 1920 and the sidewall of the semiconductor die 30 are together constitute a sidewall of the stacking unit 40C, as shown in FIG. 44. In one non-limiting example, at least one through via 1002 penetrates through the semiconductor dies 20 and 30 to be in contact with the semiconductor dies 10, 20 and 30 for providing proper electrical connection between the semiconductor dies 10, 20 and 30, and at least one through via 1003 penetrates through the semiconductor die 30 to be in contact with the semiconductor die 20 for providing proper electrical connection between the semiconductor dies 20 and 30, as shown in FIG. 44.

The stacking unit 40C may be formed by, but not limited to, providing a circuit wafer W1 (similar to the processes of FIGS. 1-7); performing a dicing process on the circuit wafer W1 to form a plurality of separate and individual semiconductor dies 10 (similar to the process of FIG. 16 or FIG. 39); bonding at least one semiconductor die 10 to the circuit wafer W2 by CoW bonding; laterally encapsulating the at least one semiconductor die 10 in the insulating encapsulation 1910 (similar to the processes of FIG. 41); performing a dicing process on the bonded structure of the at least one semiconductor die 10 and the circuit wafer W2 to cut through the insulating encapsulation 1910 and the circuit wafer W2 so to form a plurality of separate and individual bonded structures of the semiconductor dies 10 and 20 (similar to the process of FIG. 16 or FIG. 39); providing a circuit wafer W3 (similar to the processes of FIG. 10); bonding the bonded structure of the semiconductor dies 10 and 20 to the circuit wafer W3 by a CoW process; laterally encapsulating the bonded structure of the semiconductor dies 10 and 20 in the insulating encapsulation 1920 (similar to the processes of FIG. 41); forming at least one through via 1002 and at least one through via 1003 (similar to the process of FIG. 12); and performing another dicing process on the insulating encapsulation 1920 and the circuit wafer W3 to form a plurality of separate and individual stacking units 40C (similar to the process of FIG. 16 or FIG. 39). The formation and material of the insulating encapsulation 1920 is similar to or substantially identical to the formation and material of the insulating encapsulation 1910 as previously discussed, and thus are not repeated herein.

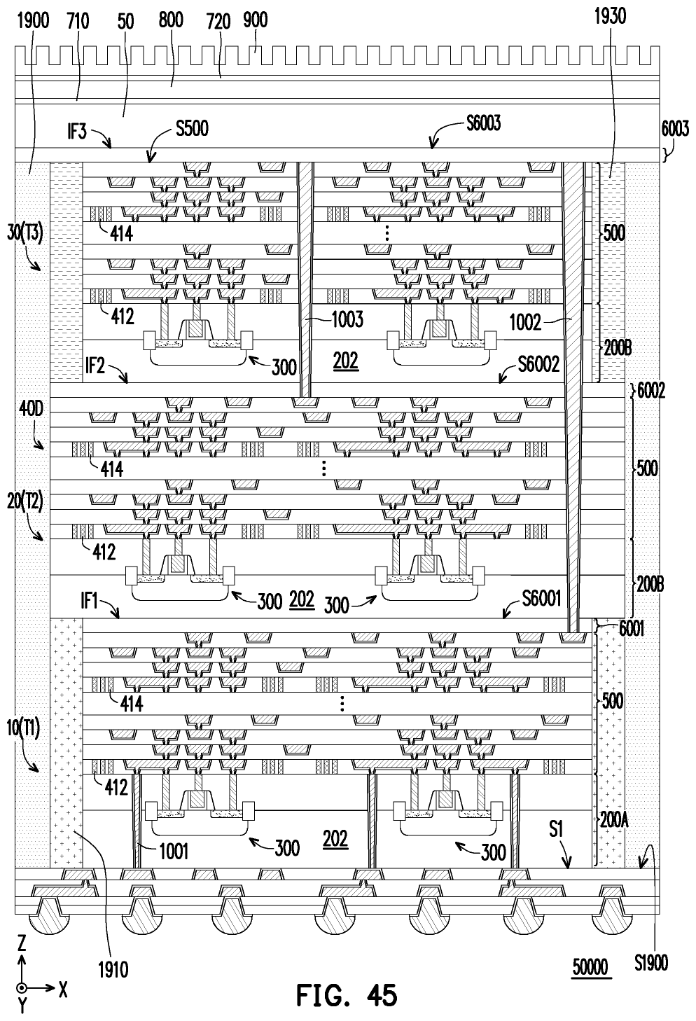

In some embodiments, the semiconductor device 50000 of FIG. 45 is similar to the semiconductor device 20000 of FIG. 42, and the difference is that the stacking unit 40A is replaced with a stacking unit 40D. As shown in FIG. 45, the stacking unit 40D may include a semiconductor die 30 in the third tier T3, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2, an insulating encapsulation 1910 laterally encapsulating the semiconductor die 10, and an insulating encapsulation 1930 laterally encapsulating the semiconductor die 30. For example, in the stacking unit 40D, a sidewall of the insulating encapsulation 1930, a sidewall of the insulating encapsulation 1910 and a sidewall of the semiconductor die 20 are aligned to each other. That is, the sidewall of the insulating encapsulation 1930, the sidewall of the insulating encapsulation 1910 and the sidewall of the semiconductor die 20 are together constitute a sidewall of the stacking unit 40D, as shown in FIG. 45. In one non-limiting example, at least one through via 1002 penetrates through the semiconductor dies 20 and 30 to be in contact with the semiconductor dies 10, 20 and 30 for providing proper electrical connection between the semiconductor dies 10, 20 and 30, and at least one through via 1003 penetrates through the semiconductor die 30 to be in contact with the semiconductor die 20 for providing proper electrical connection between the semiconductor dies 20 and 30, as shown in FIG. 45. In another non-limiting example, at least one through via 1002 penetrates through the insulating encapsulation 1930 and the semiconductor die 20 to be in contact with the semiconductor dies 10 and 20 for providing proper electrical connection between the semiconductor dies 10 and 20, and at least one through via 1003 penetrates through the semiconductor die 30 to be in contact with the semiconductor die 20 for providing proper electrical connection between the semiconductor dies 20 and 30, as shown in FIG. 45.

The stacking unit 40D may be formed by, but not limited to, providing a circuit wafer W1 (similar to the processes of FIGS. 1-7); performing a dicing process on the circuit wafer W1 to form a plurality of separate and individual semiconductor dies 10 (similar to the process of FIG. 16 or FIG. 39); bonding at least one semiconductor die 10 to the circuit wafer W2 by CoW bonding; laterally encapsulating the at least one semiconductor die 10 in the insulating encapsulation 1910 (similar to the processes of FIG. 41); providing a circuit wafer W3 (similar to the processes of FIG. 10); performing a dicing process on the circuit wafer W3 to form a plurality of separate and individual semiconductor dies 30 (similar to the process of FIG. 16 or FIG. 39); bonding at least one semiconductor die 30 to the bonded structure of the semiconductor die 10 and the circuit wafer W2 by CoW bonding; laterally encapsulating the at least one semiconductor die 30 in the insulating encapsulation 1930 (similar to the processes of FIG. 41); forming at least one through via 1002 and at least one through via 1003 (similar to the process of FIG. 12); and performing another dicing process on the insulating encapsulation 1930, the circuit wafer W2 and the insulating encapsulation 1910 to form a plurality of separate and individual stacking units 40D (similar to the process of FIG. 16 or FIG. 39). The formation and material of the insulating encapsulation 1930 is similar to or substantially identical to the formation and material of the insulating encapsulation 1910 as previously discussed, and thus are not repeated herein.

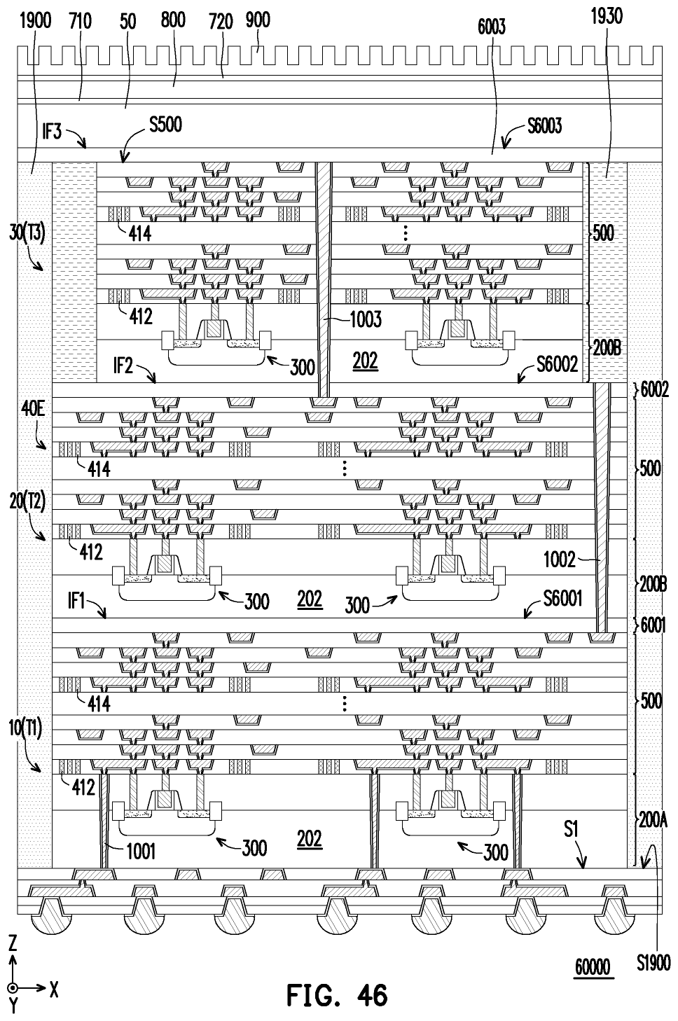

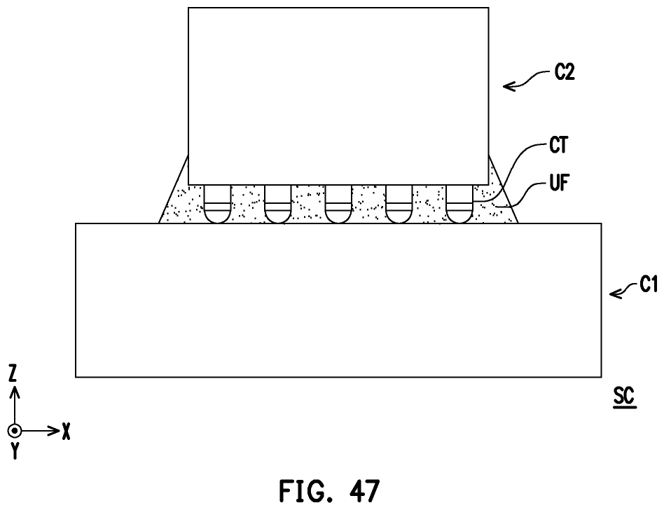

In some embodiments, the semiconductor device 60000 of FIG. 46 is similar to the semiconductor device 20000 of FIG. 42, and the difference is that the stacking unit 40A is replaced with a stacking unit 40E. As shown in FIG. 46, the stacking unit 40E may include a semiconductor die 30 in the third tier T3 encapsulated in an insulating encapsulation 1930, a semiconductor die 20 in the second tier T2 disposed over and electrically coupled to the semiconductor die 30 in the third tier T3 and over the insulating encapsulation 1930, and a semiconductor die 10 in the first tier T1 disposed over and electrically coupled to the semiconductor die 20 in the second tier T2. For example, in the stacking unit 40E, a sidewall of the insulating encapsulation 1930, a sidewall of the semiconductor die 20, and a sidewall of the semiconductor die 10 are aligned to each other. That is, the sidewall of the insulating encapsulation 1930, the sidewall of the semiconductor die 20, and the sidewall of the semiconductor die 10 are together constitute a sidewall of the stacking unit 40E, as shown in FIG. 46.

In one non-limiting example, at least one through via 1002 penetrates through the insulating encapsulation 1930 and the semiconductor die 20 to be in contact with the semiconductor dies 10 and 20 for providing proper electrical connection between the semiconductor dies 10 and 20, and at least one through via 1003 penetrates through the semiconductor die 30 to be in contact with the semiconductor die 20 for providing proper electrical connection between the semiconductor dies 20 and 30, as shown in FIG. 46. In another non-limiting example, at least one through via 1002 penetrates through the semiconductor dies 20 and 30 to be in contact with the semiconductor dies 10, 20 and 30 for providing proper electrical connection between the semiconductor dies 10, 20 and 30, and at least one through via 1003 penetrates through the semiconductor die 30 to be in contact with the semiconductor die 20 for providing proper electrical connection between the semiconductor dies 20 and 30, as shown in FIG. 46.

The stacking unit 40E may be formed by, but not limited to, providing a circuit wafer W1 and a circuit wafer W2 (similar to the processes of FIGS. 1-7 and FIG. 8, respectively); bonding the circuit wafer W1 and the circuit wafer W2 by WoW bonding (similar to the process of FIG. 9); providing a circuit wafer W3 (similar to the processes of FIG. 10); performing a dicing process on the circuit wafer W3 to form a plurality of separate and individual semiconductor dies 30 (similar to the process of FIG. 16 or FIG. 39); bonding at least one semiconductor die 30 to the bonded structure of the circuit wafer W1 and W2 by CoW bonding; laterally encapsulating the at least one semiconductor die 30 in the insulating encapsulation 1930 (similar to the processes of FIG. 41); forming at least one through via 1002 and at least one through via 1003 (similar to the process of FIG. 12); and performing another dicing process on the insulating encapsulation 1930 and the bonded structure of the circuit wafer W1 and W2 to form a plurality of separate and individual stacking units 40E (similar to the process of FIG. 16 or FIG. 39).

The semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof individually may be in a die-form or a chip-form. Although in the above embodiments, only three tiers are included in each semiconductor device of the disclosure, the number of the tiers included in each semiconductor device of the disclosure may be two or more than two based on the demand and/or product design requirements/layout.

In some embodiments, the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof are referred to as semiconductor chips or integrated circuits, which independently include a digital chip, an analog chip, or a mixed signal chip. In some embodiments, the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof are, independently, a logic die such as a central processing unit (CPU), a graphics processing unit (GPU), a neural network processing unit (NPU), a deep learning processing unit (DPU), a tensor processing unit (TPU), a system-on-a-chip (SoC), a system-on-integrated circuit (SoIC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O (WIO) memory; a pre-stacked memory cube such as a hybrid memory cube (HMC) module, a high bandwidth memory (HBM) module; a combination thereof; or the like. In further alternative embodiments, the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof are, independently, an artificial intelligence (AI) engine such as an AI accelerator; a computing system such as an AI server, a high-performance computing (HPC) system, a high power computing device, a cloud computing system, a networking system, an edge computing system, a immersive memory computing system (ImMC), a SoIC system, etc.; a combination thereof; or the like. In some other embodiments, the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof are, independently, an electrical and/or optical input/output (I/O) interface die, an integrated passives die (IPD), a voltage regulator die (VR), a local silicon interconnect die (LSI) with or without deep trench capacitor (DTC) features, a local silicon interconnect die with multi-tier functions such as electrical and/or optical network circuit interfaces, IPD, VR, DTC, or the like.

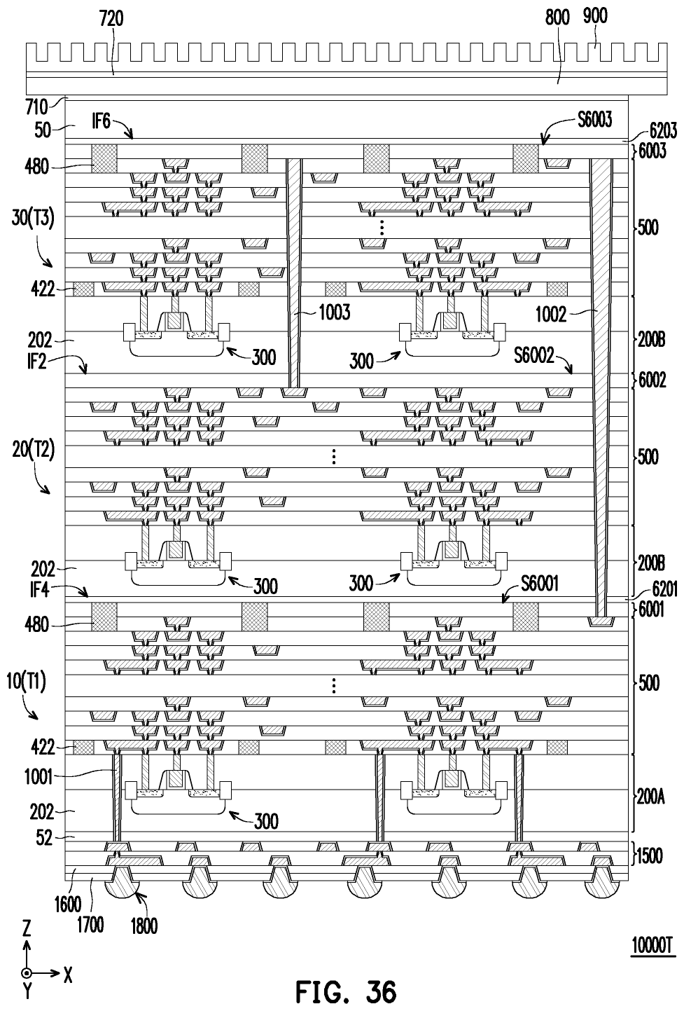

The types of the semiconductor dies (10, 20 and 30) included in the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof may be selected and designated based on the demand and/or product design requirements/layout, and thus are not specifically limited in the disclosure. In the disclosure, as long as hotspot(s) of the semiconductor device are thermally coupled to (e.g., physically near to) thermal control elements (e.g., 412, 414, 422, 424, 430, 440, 450, 470 and/or 480), the heat spikes in the semiconductor device of the disclosure can be alleviated, thereby improving the reliability of the semiconductor device of the disclosure. For example, in the semiconductor device 10000M of FIG. 29, the semiconductor dies 10 and 20 are or include memory dies or low-power logic dies and the semiconductor die 30 is or includes a high-power logic die, therefore the first tier T1 and the second tier T2 can be free of thermal control elements. For other examples, in the semiconductor device 10000Q of FIG. 33 and the semiconductor device 10000S of FIG. 35, the semiconductor dies 20 and 30 are or include memory dies or low-power logic dies and the semiconductor die 10 is or includes a high-power logic die, therefore the second tier T2 and the third tier T3 can be free of thermal control elements. For other examples, in the semiconductor device 10000R of FIG. 34 and the semiconductor device 10000T of FIG. 36, the semiconductor die 20 is or includes a memory die or a low-power logic die and the semiconductor dies 10 and 30 are or include high-power logic dies, therefore the second tier T2 can be free of thermal control elements.

The disclosure is not limited thereto. In the disclosure, thermal control elements (e.g., 412, 414, 422, 424, 430, 440, 450, 470 and/or 480), which may be in any combination(s) or taken alone, can be adopted to alleviate the heat spikes in the semiconductor device of the disclosure, thereby improving the reliability of the semiconductor device of the disclosure.

The semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof individually may be further mounted onto another electronical component or onto a circuit structure, such as a mother board, a package substrate, a printed circuit board (PCB), a printed wiring board, and/or other carrier that is capable of carrying integrated circuits. Or, the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof and/or modifications thereof may be or may be part of an integrated Fan-Out (InFO) package, an InFO package having a Package-on-Package (PoP) structure, a chip-on-wafer-on-substrate (CoWoS) package, a flip chip package of an InFO package, or the like. The disclosure is not limited thereto. The conductive terminals 1800 may be referred to as connectors or terminals of the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof and/or modifications thereof.

FIG. 34 is a schematic cross-sectional view showing an application of a semiconductor device (e.g., the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof) in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 34, in some embodiments, a component assembly SC including a first component C1 and a second component C2 disposed over the first component C1 is provided. The first component C1 may be or may include a circuit structure, such as a mother board, a package substrate, another printed circuit board (PCB), a printed wiring board, and/or other carrier that is capable of carrying integrated circuits. In some embodiments, the second component C2 mounted on the first component C1 is similar to one of the semiconductor devices 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof. For example, one or more second components C2 (e.g., 10000A, 10000B, 10000C, 10000D, 10000E, 10000F, 10000G, 10000H, 10000I, 10000J, 10000K, 10000L, 10000M, 10000N, 100000, 10000P, 10000Q, 10000R, 10000S, 10000T, 20000, 30000, 40000, 50000, 60000 and/or modifications thereof) may be electrically coupled to the first component C1 through a plurality of terminals CT. The terminals CT may be the conductive terminals 1800. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In accordance with some embodiments, a semiconductor device includes a semiconductor die. The semiconductor die includes a substrate including at least one active component, an interconnect disposed over and electrically coupled to the at least one active component, and at least one first thermal control element disposed inside the interconnect and thermally coupled to the at least one active component. The at least one active component is surrounded by the at least one first thermal control element in a vertical projection along a stacking direction of the substrate and the interconnect.

In accordance with some embodiments, a semiconductor device includes a redistribution circuit structure, a first die, a second die, and at least one through via. The first die is disposed over and electrically coupled to the redistribution circuit structure, and includes a first substrate including at least one first active component, a first interconnect disposed over and electrically coupled to the at least one first active component and at least one first thermal control element disposed inside the first interconnect and thermally coupled to the at least one first active component, where the at least one first active component is surrounded by the at least one first thermal control element in a vertical projection. The second die is disposed over and electrically coupled to the redistribution circuit structure, and includes a second substrate including at least one second active component and a second interconnect disposed over and electrically coupled to the at least one second active component. The at least one through via is disposed over and electrically coupled to the redistribution circuit structure and electrically couples the first die and the second die.

In accordance with some embodiments, a method of manufacturing a semiconductor device includes the following steps: providing a first wafer substrate including at least one first active component; forming a build-up layer of a first interconnect over the first wafer substrate to be electrically coupled to the at least one first active component, the build-up layer including a dielectric layer and a metallization layer laterally covered by the dielectric layer; patterning the dielectric layer to form at least one first opening next to the metallization layer; globally forming a first thermal energy storage material over the dielectric layer and extending into the at least one first opening; performing a planarizing process to remove a portion of the first thermal energy storage material above the dielectric layer to form at least one first thermal control element inside the at least one first opening, the at least one first thermal control element being thermally coupled to the at least one first active component, wherein the at least one first active component is surrounded by the at least one first thermal control element in a vertical projection along a stacking direction of the first wafer substrate and the first interconnect; forming a redistribution circuit structure over the first wafer substrate; disposing a plurality of conductive terminals over the redistribution circuit structure; and performing a dicing process to form the semiconductor device including a first semiconductor die.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a semiconductor die, comprising:
a substrate, comprising at least one active component;
an interconnect, disposed over and electrically coupled to the at least one active component; and
at least one first thermal control element, disposed inside the interconnect and thermally coupled to the at least one active component, wherein the at least one active component is surrounded by the at least one first thermal control element in a vertical projection along a stacking direction of the substrate and the interconnect.

2. The semiconductor device of claim 1, wherein the at least one first thermal control element comprises a plurality of first thermal control elements arranged into a matrix with an opening within the matrix,
wherein in the vertical projection, the at least one active component is surrounded by the plurality of first thermal control elements arranged into the matrix, and the opening is overlapped with the at least one active component.

3. The semiconductor device of claim 1, wherein the at least one first thermal control element comprises a first thermal control element of bulk form with an opening disposed therein or a first thermal control element of plate form with an opening disposed therein,
wherein in the vertical projection, the at least one active component is surrounded by the first thermal control element, and the opening is overlapped with the at least one active component.

4. The semiconductor device of claim 1, wherein the semiconductor die further comprises a second thermal control element of continuous plate form, and the interconnect is disposed between the second thermal control element and the substrate,
wherein in the vertical projection, the at least one active component is overlapped with the second thermal control element.

5. The semiconductor device of claim 1, wherein the at least one active component is separated from the at least one first thermal control element through a dielectric layer of the interconnect, and a thermal conductivity of the at least one first thermal control element is greater than a thermal conductivity of the dielectric layer of the interconnect,
wherein the at least one first thermal control element comprises a solid-solid phase change material.

6. A semiconductor device, comprising:
a redistribution circuit structure;
a first die, disposed over and electrically coupled to the redistribution circuit structure, and comprising:
a first substrate, comprising at least one first active component;
a first interconnect, disposed over and electrically coupled to the at least one first active component; and
at least one first thermal control element, disposed inside the first interconnect and thermally coupled to the at least one first active component, wherein the at least one first active component is surrounded by the at least one first thermal control element in a vertical projection;
a second die, disposed over and electrically coupled to the redistribution circuit structure, and comprising:
a second substrate, comprising at least one second active component; and
a second interconnect, disposed over and electrically coupled to the at least one second active component; and
at least one through via, disposed over and electrically coupled to the redistribution circuit structure and electrically coupling the first die and the second die.

7. The semiconductor device of claim 6, wherein the first die is disposed between the second die and the redistribution circuit structure, and the at least one through via penetrates through the second die to electrically couple the first die and the second die.

8. The semiconductor device of claim 6, wherein the second die is disposed between the first die and the redistribution circuit structure, and the at least one through via penetrates through the first die to electrically couple the first die and the second die.

9. The semiconductor device of claim 6, wherein the second die further comprises:
at least one second thermal control element, disposed inside the second interconnect and thermally coupled to the at least one second active component, wherein the at least one second active component is surrounded by the at least one second thermal control element in the vertical projection.

10. The semiconductor device of claim 6, further comprising:
a carrier, disposed over the redistribution circuit structure, wherein the first die, the second die and the at least one through via are disposed between the carrier and the redistribution circuit structure;
a heat dissipating module, disposed over and thermally coupled to the carrier, wherein the carrier is disposed between the heat dissipating module and the redistribution circuit structure; and
a plurality of conductive terminals, disposed over and electrically coupled to the redistribution circuit structure, wherein the redistribution circuit structure is disposed between the carrier and the plurality of conductive terminals.

11. The semiconductor device of claim 6, further comprising:
a third die, disposed over and electrically coupled to the redistribution circuit structure, and comprising:
a third substrate, comprising at least one third active component; and
a third interconnect, disposed over and electrically coupled to the at least one third active component,
wherein the at least one through via further penetrates through the third die.

12. The semiconductor device of claim 11, wherein the third die further comprises:
at least one third thermal control element, disposed inside the third interconnect and thermally coupled to the at least one third active component, wherein the at least one third active component is surrounded by the at least one third thermal control element in the vertical projection.

13. The semiconductor device of claim 11, further comprising:
at least one additional through via, disposed over the redistribution circuit structure, wherein the at least one additional through via penetrates through the third die to electrically couple the third die and the second die or to electrically couple the third die and the first die.

14. A method of manufacturing a semiconductor device, comprising:
providing a first wafer substrate comprising at least one first active component;
forming a build-up layer of a first interconnect over the first wafer substrate to be electrically coupled to the at least one first active component, the build-up layer comprising a dielectric layer and a metallization layer laterally covered by the dielectric layer;
patterning the dielectric layer to form at least one first opening next to the metallization layer;
globally forming a first thermal energy storage material over the dielectric layer and extending into the at least one first opening;
performing a planarizing process to remove a portion of the first thermal energy storage material above the dielectric layer to form at least one first thermal control element inside the at least one first opening, the at least one first thermal control element being thermally coupled to the at least one first active component, wherein the at least one first active component is surrounded by the at least one first thermal control element in a vertical projection along a stacking direction of the first wafer substrate and the first interconnect;
forming a redistribution circuit structure over the first wafer substrate;
disposing a plurality of conductive terminals over the redistribution circuit structure; and
performing a dicing process to form the semiconductor device comprising a first semiconductor die.

15. The method of claim 14, wherein prior to forming the redistribution circuit structure over the first wafer substrate, the method further comprises:
forming a first bonding layer over the first interconnect;
providing a circuit wafer, the circuit wafer comprising a second wafer substrate comprising at least one second active component and a second interconnect disposed over the second wafer substrate;
bonding the second wafer substrate to the first bonding layer through wafer-on-wafer bonding;
forming a second bonding layer over the second interconnect;
providing an additional circuit wafer, the additional circuit wafer comprising a third wafer substrate comprising at least one third active component and a third interconnect disposed over the third wafer substrate;
bonding the third wafer substrate to the second bonding layer through wafer-on-wafer bonding;
disposing at least one through via penetrating through the additional circuit wafer and the circuit wafer;
forming a third bonding layer over the third interconnect and the at least one through via; and
bonding a carrier to the third bonding layer through wafer-to-wafer bonding,
wherein performing the dicing process comprises performing a first dicing process to cut through the first wafer substrate, the first interconnect, the first bonding layer, the second wafer substrate, the second interconnect, the second bonding layer, the third wafer substrate, the third interconnect, the third bonding layer, the carrier, and the redistribution circuit structure to form the semiconductor device comprising a stacking structure of the first semiconductor die, a second semiconductor die, a third semiconductor die, the redistribution circuit structure, the plurality of conductive terminals and the carrier.

16. The method of claim 14,
wherein prior to forming the redistribution circuit structure over the first wafer substrate, the method further comprises:
forming a first bonding layer over the first interconnect;
providing a circuit wafer, the circuit wafer comprising a second wafer substrate comprising at least one second active component and a second interconnect disposed over the second wafer substrate;
bonding the second wafer substrate to the first bonding layer through wafer-on-wafer bonding;
forming a second bonding layer over the second interconnect;
providing an additional circuit wafer, the additional circuit wafer comprising a third wafer substrate comprising at least one third active component and a third interconnect disposed over the third wafer substrate;
bonding the third wafer substrate to the second bonding layer through wafer-on-wafer bonding;
disposing at least one through via penetrating through the additional circuit wafer and the circuit wafer;
performing a first dicing process to cut through the first wafer substrate, the first interconnect, the first bonding layer, the second wafer substrate, the second interconnect, the second bonding layer, the third wafer substrate and the third interconnect to form a first stacking structure of the first semiconductor die, a second semiconductor die and a third semiconductor die; and
encapsulating the first stacking structure in an insulating encapsulation,
wherein forming the redistribution circuit structure over the first wafer substrate comprises forming the redistribution circuit structure over the insulating encapsulation and the first semiconductor die exposed by the insulating encapsulation,
wherein prior to performing the dicing process and after disposing the plurality of conductive terminals, the method further comprises:
forming a third bonding layer over the insulating encapsulation, the third semiconductor die exposed by the insulating encapsulation and the at least one through via; and
bonding a carrier to the third bonding layer through wafer-to-wafer bonding,
wherein performing the dicing process comprises performing a second dicing process to cut through the carrier, the third bonding layer, the insulating encapsulation and the redistribution circuit structure to form the semiconductor device comprising a second stacking structure having the first stacking structure, the insulating encapsulation, the redistribution circuit structure, the plurality of conductive terminals and the carrier.

17. The method of claim 14,
wherein prior to forming the redistribution circuit structure over the first wafer substrate, the method further comprises:
forming a first bonding layer over the first interconnect;
providing a circuit wafer, the circuit wafer comprising a second wafer substrate comprising at least one second active component and a second interconnect disposed over the second wafer substrate;
bonding the second wafer substrate to the first bonding layer through wafer-on-wafer bonding;
forming a second bonding layer over the second interconnect;
performing a first dicing process to cut through the first wafer substrate, the first interconnect, the first bonding layer, the second wafer substrate, the second interconnect and the second bonding layer to form a first stacking structure of the first semiconductor die and a second semiconductor die;
providing an additional circuit wafer, the additional circuit wafer comprising a third wafer substrate comprising at least one third active component and a third interconnect disposed over the third wafer substrate;
bonding the second bonding layer of the first stacking structure to the third wafer substrate through chip-on-wafer bonding;
encapsulating the first stacking structure in a first insulating encapsulation;
disposing at least one through via penetrating through the additional circuit wafer and the second semiconductor die;
performing a second dicing process to cut through the first insulating encapsulation, the third wafer substrate and the third interconnect to form a second stacking structure having the first stacking structure, the first insulating encapsulation and a third semiconductor die; and
encapsulating the second stacking structure in a second insulating encapsulation,
wherein forming the redistribution circuit structure over the first wafer substrate comprises forming the redistribution circuit structure over the second insulating encapsulation and the first semiconductor die exposed by the second insulating encapsulation,
wherein prior to performing the dicing process and after disposing the plurality of conductive terminals, the method further comprises:
forming a third bonding layer over the second insulating encapsulation, the third semiconductor die exposed by the second insulating encapsulation and the at least one through via; and
bonding a carrier to the third bonding layer through wafer-to-wafer bonding,
wherein performing the dicing process comprises performing a third dicing process to cut through the carrier, the third bonding layer, the second insulating encapsulation and the redistribution circuit structure to form the semiconductor device comprising a third stacking structure having the second stacking structure, the second insulating encapsulation, the redistribution circuit structure, the plurality of conductive terminals and the carrier.

18. The method of claim 14,
wherein prior to forming the redistribution circuit structure over the first wafer substrate, the method further comprises:
forming a first bonding layer over the first interconnect;
performing a first dicing process to cut through the first wafer substrate, the first interconnect and the first bonding layer to form a first stacking structure of the first semiconductor die;
providing a circuit wafer, the circuit wafer comprising a second wafer substrate comprising at least one second active component and a second interconnect disposed over the second wafer substrate;
bonding the first bonding layer of the first stacking structure to the second wafer substrate through chip-on-wafer bonding;
encapsulating the first stacking structure in a first insulating encapsulation;
forming a second bonding layer over the second interconnect;
performing a second dicing process to cut through the first insulating encapsulation, the second wafer substrate, the second interconnect and the second bonding layer to form a second stacking structure having the first stacking structure, the first insulating encapsulation and a second semiconductor die;
providing an additional circuit wafer, the additional circuit wafer comprising a third wafer substrate comprising at least one third active component and a third interconnect disposed over the third wafer substrate;
bonding the second bonding layer of the second stacking structure to the third wafer substrate through chip-on-wafer bonding;
encapsulating the second stacking structure in a second insulating encapsulation;
disposing at least one through via penetrating through the additional circuit wafer and the second semiconductor die;
performing a third dicing process to cut through the second insulating encapsulation, the third wafer substrate and the third interconnect to form a third stacking structure having the second stacking structure, the second insulating encapsulation and a third semiconductor die; and
encapsulating the third stacking structure in a third insulating encapsulation,
wherein forming the redistribution circuit structure over the first wafer substrate comprises forming the redistribution circuit structure over the third insulating encapsulation and the first semiconductor die exposed by the third insulating encapsulation,
wherein prior to performing the dicing process and after disposing the plurality of conductive terminals, the method further comprises:
forming a third bonding layer over the third insulating encapsulation, the third semiconductor die exposed by the third insulating encapsulation and the at least one through via; and
bonding a carrier to the third bonding layer through wafer-to-wafer bonding,
wherein performing the dicing process comprises performing a fourth dicing process to cut through the carrier, the third bonding layer, the third insulating encapsulation and the redistribution circuit structure to form the semiconductor device comprising a fourth stacking structure having the third stacking structure, the third insulating encapsulation, the redistribution circuit structure, the plurality of conductive terminals and the carrier.

19. The method of claim 14,
wherein prior to forming the redistribution circuit structure over the first wafer substrate, the method further comprises:
forming a first bonding layer over the first interconnect;
performing a first dicing process to cut through the first wafer substrate, the first interconnect and the first bonding layer to form a first stacking structure of the first semiconductor die;
providing a circuit wafer, the circuit wafer comprising a second wafer substrate comprising at least one second active component and a second interconnect disposed over the second wafer substrate;
bonding the first bonding layer of the first stacking structure to the second wafer substrate through chip-on-wafer bonding;
encapsulating the first stacking structure in a first insulating encapsulation;
forming a second bonding layer over the second interconnect;
providing an additional circuit wafer, the additional circuit wafer comprising a third wafer substrate comprising at least one third active component and a third interconnect disposed over the third wafer substrate;
performing a second dicing process to cut through the third wafer substrate, the third interconnect and the third bonding layer to form a second stacking structure of a third semiconductor die;
bonding the third semiconductor die to the second bonding layer of the second stacking structure through chip-on-wafer bonding;
encapsulating the second stacking structure in a second insulating encapsulation;
disposing at least one through via penetrating through at least the third semiconductor die;
performing a third dicing process to cut through the second insulating encapsulation, the second wafer substrate, the second interconnect, the second bonding layer and the first insulating encapsulation to form a third stacking structure having the second stacking structure, the second insulating encapsulation, a second semiconductor die, the first stacking structure and the first insulating encapsulation; and
encapsulating the third stacking structure in a third insulating encapsulation,
wherein forming the redistribution circuit structure over the first wafer substrate comprises forming the redistribution circuit structure over the third insulating encapsulation and the first semiconductor die exposed by the third insulating encapsulation,
wherein prior to performing the dicing process and after disposing the plurality of conductive terminals, the method further comprises:
forming a third bonding layer over the third insulating encapsulation, the third semiconductor die exposed by the third insulating encapsulation and the at least one through via; and
bonding a carrier to the third bonding layer through wafer-to-wafer bonding,
wherein performing the dicing process comprises performing a fourth dicing process to cut through the carrier, the third bonding layer, the third insulating encapsulation and the redistribution circuit structure to form the semiconductor device comprising a fourth stacking structure having the third stacking structure, the third insulating encapsulation, the redistribution circuit structure, the plurality of conductive terminals and the carrier.

20. The method of claim 14,
wherein prior to forming the redistribution circuit structure over the first wafer substrate, the method further comprises:
forming a first bonding layer over the first interconnect;
providing a circuit wafer, the circuit wafer comprising a second wafer substrate comprising at least one second active component and a second interconnect disposed over the second wafer substrate;
bonding the second wafer substrate to the first bonding layer through wafer-on-wafer bonding;
forming a second bonding layer over the second interconnect;
providing an additional circuit wafer, the additional circuit wafer comprising a third wafer substrate comprising at least one third active component and a third interconnect disposed over the third wafer substrate;
performing a first dicing process to cut through the third wafer substrate, the third interconnect and the third bonding layer to form a first stacking structure of a third semiconductor die;
bonding the third wafer substrate to the second bonding layer through chip-on-wafer bonding;
encapsulating the first stacking structure in a first insulating encapsulation;
disposing at least one through via penetrating through at least the third semiconductor die;
performing a second dicing process to cut through the first insulating encapsulation, the second wafer substrate, the second interconnect, the second bonding layer, the first wafer substrate, the first interconnect, and the first bonding layer to form a second stacking structure having the first stacking structure, the first insulating encapsulation, a second semiconductor die and the first semiconductor die; and
encapsulating the second stacking structure in a second insulating encapsulation,
wherein forming the redistribution circuit structure over the first wafer substrate comprises forming the redistribution circuit structure over the second insulating encapsulation and the first semiconductor die exposed by the second insulating encapsulation,
wherein prior to performing the dicing process and after disposing the plurality of conductive terminals, the method further comprises:
forming a third bonding layer over the second insulating encapsulation, the third semiconductor die exposed by the second insulating encapsulation and the at least one through via; and
bonding a carrier to the third bonding layer through wafer-to-wafer bonding,
wherein performing the dicing process comprises performing a third dicing process to cut through the carrier, the third bonding layer, the second insulating encapsulation and the redistribution circuit structure to form the semiconductor device comprising a third stacking structure having the second stacking structure, the second insulating encapsulation, the redistribution circuit structure, the plurality of conductive terminals and the carrier.
